(19) United States
(12) Patent Application Publication
(10) Pub. No.: US 2023/0209720 A1
(43) Pub. Date: Jun. 29, 2023

(54) APPARATUS AND METHOD FOR PRINTING CIRCUITS USING PRINT PARAMETERS ADJUSTED FOR PRINTING CONDITIONS

(71) Applicant: BOTFACTORY, INC., Long Island City, NY (US)

(72) Inventors: Michael E. KNOX, Manhasset, NY (US); Andrew IPPOLITI, Sunnyside, NY (US); Georgios KYRIAKOU, New York, NY (US); Carlos OSPINA, New York, NY (US); Nicolas VANSNICK, Brooklyn, NY (US)

(21) Appl. No.: 18/114,940

(22) Filed: Feb. 27, 2023

Related U.S. Application Data
(63) Continuation-in-part of application No. 16/773,944, filed on Jan. 27, 2020, now Pat. No. 11,596,071.
Application No. 16/773,944 is a continuation-in-part of application No. 15/175,014, filed on Jun. 6, 2016, now Pat. No. 10,548,231.
Application No. 15/175,014 is a continuation-in-part of application No. 14/392,408, filed on Jun. 1, 2016, now Pat. No. 10,779,451.
(60) Provisional application No. 61/910,210, filed on Nov. 29, 2013.
(60) Provisional application No. 62/053,796, filed on Sep. 23, 2014.

(51) Int. Cl. H05K 3/12

(52) U.S. Cl. CPC H05K 3/1241; H05K 2203/163

(57) ABSTRACT

An apparatus is configured to print a circuit board using conductive and nonconductive printing materials in accordance with parameters. A database stores information correlating characteristics of printing materials with shelf life and/or age of the printing materials, and/or environmental conditions. The apparatus either prompts operator to make printing parameter adjustments or automatically optimizes printing parameters based on information stored in the database and the environmental conditions. The apparatus optionally further optimizes printing parameters based on age of a print head and positioning mechanisms.

### RELATED APPLICATIONS

This application is a continuation-in-part of and claims priority to application Ser. No. 16/773,944, filed Jan. 27, 2020, which is a continuation-in-part of application Ser. No. 15/175,014, filed Jun. 6, 2016, and now issued as U.S. Pat. No. 10,548,231, which is a continuation-in-part of application Ser. No. 14/392,408, which is a national stage application filed Jun. 1, 2016 of international patent application PCT/US2014/067986, filed Dec. 1, 2014, and claims priority to U.S. provisional patent application No. 62/053,796, filed Sep. 23, 2014, and U.S. provisional patent application No. 61/910,210, filed Nov. 29, 2013. This application incorporates by reference all materials of PCT/US2014/067986 and provisional applications Nos. 62/053,796, and 61/910,210 referenced above.

Material of the provisional, PCT, national stage and prior CIP filings is intended only to augment the present disclosure and wording in the provisional or PCT applications is not to be interpreted as limiting this disclosure or requiring any material in the provisional applications as critical, indispensable, or a requirement unless so stated herein.

### TECHNICAL FIELD

The present disclosure relates to fabrication and assembly of printed circuit boards including deposition of conductive traces and placement of components.

### BACKGROUND

Modern electrical devices are comprised of semiconductor circuits integrated into small packages, passive components, Printed Wiring Board (PWB) and solder. The complete assembly is often referred as a Printed Circuit Board (PCB) or Printed Circuit Assembly (PCA). The manufacture of a traditional PCA is a multistep process that may include several specialized and often expensive machines. These highly specialized machines are directed to one operation during the PCA manufacture. For example, a typical PWB, is manufactured using a thin sheet of copper foil that is laminated to a non-conductive substrate. The copper thickness may be 1.4 mils (1 ounce) and the substrate is typically FR-4 with a substrate thickness of 62 mils. Other thicknesses and substrates are also available.

Referring to FIG. 1A, conductive circuit elements or traces, such as lines, runs, pads and other wiring features, are created by removing copper from the laminated substrate by chemically etching or mechanically machining as illustrated in FIG. 1A. This subtractive process leaves behind conductive traces 50, 50a, and 50b, located on a top surface of substrate 52. Referring to FIG. 1B, it may be necessary to include a second set of conductive traces, 50c and 54, which are electrically isolated from other conductive traces. In this case, conductive traces 50, 50a, and 50b, are etched to the top surface of the substrate 52 and conductive traces 50c and 54, are etched on a bottom surface of the substrate 52. Referring to FIG. 1C, by placing conductive traces, 50c and 54, on an opposite side of the substrate 52, the conductive traces, 50 and 54, can cross each other, for example at crossover 58, without making electrical connection.

Referring to FIGS. 1C and 2, when electrical connection is optionally used between the conductive traces, 50c and 50a, a via 60a is placed through substrate 52. The via 60a, often referred to as a “plated-through hole,” is typically manufactured in a two-step process wherein a hole is first drilled through the conductive traces, 50c and 50a, and the substrate 52 and then the hole is plated with copper thus making connection between the two conductive traces.

When complex circuits are manufactured especially for a small dimensional footprint, the complete board may contain multiple printed wiring boards stacked to allow copper lines to cross over each other while maintaining electrical isolation. Referring to FIG. 3, a four-layer PWB comprises substrate 61a and substrate 6 lb glued together with prepreg 62. PWB substrate 61a, has conductive traces 64 etched on a top side and conductive traces 65 etched to a bottom side. PWB substrate 6 lb has conductive traces 66 etched on a top side and conductive traces 67 etched to a bottom side. A via 70 is capable of connecting traces to any combination of conductive traces on different layers. The prepeg 62 is an insulating material used to electrically isolate conductive traces 65 and 66.

Highly specialized equipment is used to manufacture printed wiring boards in order to rapidly fabricate the boards at an economical cost. The etching equipment only performs one of several tasks optionally used to assemble a complete PCA. Once the printed wiring board is etched and drilled, the exposed copper traces are typically coated with solder, silver, nickel/gold, or some other anti-corrosion coating. The finished printed wiring board is then typically sent to another facility for assembly of electronic components onto the PWB. The attachment of electronic components, e.g., semiconductor and passive components, are made using a solder reflow process. In one typical process, solder paste is applied to the PWB using screen printing techniques. Once the solder is printed onto the board, the electrical components are positioned onto the board. Positioning the components is often referred as “pick-and-place”. Components may be manually placed, often with tweezers, or in high volume production, components may be placed with a computer controlled machine. Once the components are all positioned on the solder paste, the PCA is placed in an oven to melt (reflow) the solder paste which will permanently attach the components to the board. Because of the multiple machines and technologies involved, this complete process can often take up to 4 weeks to complete.

The process of determining routing of the conductive traces is often performed using a Computer Aided Design (CAD) software tool. When using CAD, an operator enters a schematic of a desired circuit including electrical components and package sizes. The CAD tool generates a set of files used as a mask when chemically etching each layer of the PWB. The same file is optionally used to control a Computer Numerically Controlled (CNC) milling machine when mechanically etching the PWB. When mechanically etching the PWB, the CNC milling machine removes copper along an outside edge of a desired conductive trace leaving behind a copper line that is electrically isolated from other conductive traces. The CAD tool output is in a file format that is typically Gerber. Gerber is an industry standard in the PWB industry which allows multiple vendors to share the same data without loss of information. The file format is optionally native to the CAD tool such as Eagle, OrCAD and Altium to name a few. In all cases, there is information for each layer of the PWB. During the layout process, the CAD tool will attempt to route the conductive traces based on a set of design rules which include the number of layers used in the PWB. For example, an entry in the CAD tool may be the use of a four-layer board which implies that there will be four independent layers of conductive traces. The CAD tool will route conductive traces to cross over each other while not making electrical contact. When the CAD tool knows that insulating layers exist between the multiple conductive layers and knowing that the insulating layers extend to the edges of the PWB, cross-overs are easily created by dropping the line from one layer of conductive traces to a second layer of conductive traces and moving across the layer and finally returning to the original side of the PWB. As an example, referring to FIGS. 1A-1C, and 2, conductive traces 50, 50a and 50b, are etched on the top side of the substrate 52 and it is desired to have conductive trace 50a make an electrical connection to conductive trace 50b. The conductive trace 50c is routed between the other conductive traces, 50a and 50b, and connection is made through a pair of vias, 60a and 60b, as the electrical connection is dropped to a lower conductive layer and runs underneath the conductive trace 50 through the conductive line 50c. When using vias, 60a and 60b, conductive pads 72 are typically optionally used around the hole location to compensate for tolerances when drilling the via hole. In FIGS. 1B and 1C, conductive pads 72 are etched on the top of the substrate 52. Conductive pads, 73 and 72, are etched on the bottom of the substrate 52 or any other lower level of a multilayer PWB. In practice, conductive pads, 70 and 72, typically have the same diameter however, this is not required. Connecting conductive trace 50a to conductive trace 50b is made through conductive pads, 72 and 73, and plated-through vias 60a and 60b. When the conductive trace routing is complete, the CAD tool will produce a drill file which includes the location of via hole 60a and via hole 60b. The drill file is used to control a CNC machine for drilling holes in the PWB. The drill file is included as an output from the CAD tool.

The conventional multilayer PCB production method is expensive and requires multiple machines to produce a multilayer PCB. Thus, a need exist for a single apparatus and method which can produce a completed circuit board and optionally populate the circuit board with components.

Apparatuses and methods for printing circuit boards using conductive and nonconductive materials, such as inks and epoxies, printed using print heads are available. Printing using such devices can result in printed traces being defective. This increase time and cost associated with such printing. Materials used in such printing also degrade with age which increases the possibility of defects occurring. Furthermore, environmental conditions can also affect the quality of printing done. Additionally, available materials may vary over time which also affects the printing quality if methods employed are not varied to compensate for material variations.

### SUMMARY OF THE DISCLOSURE

Accordingly, it is an object of the disclosure to provide a PCB production apparatus and method which provides for producing PCB's using ink and/or epoxy printing and optionally component placement which can overcome the disadvantages presented by adverse effects of material aging, environmental conditions, and material variations.

Briefly stated an apparatus and method are configured to print a circuit board using conductive and nonconductive printing materials in accordance with parameters. A database stores information correlating characteristics of printing materials with shelf life and/or age of the printing materials, and/or environmental conditions. The apparatus either prompts operator to make printing parameter adjustments or automatically optimizes printing parameters based on information stored in the database and the environmental conditions. The apparatus optionally further optimizes printing parameters based on age of a print head and positioning mechanisms.

A further embodiment of the present disclosure provides an apparatus for producing a printed circuit board on a substrate, has a table for supporting the substrate, a function head configured to effect printing conductive and non-conductive materials on the substrate, a positioner configured to effect movement of the function head relative to the table, and a controller configured to operate the function head and the positioner to effect the printing of conductive and non-conductive materials on the substrate. The apparatus optionally has a layout translation module configured to accept PCB multilayer circuit board files and convert multilayer circuit board layout data of the PCB multilayer circuit board files to printing data files for controlling the function head to print conductive material and nonconductive material onto the substrate to produce a printed circuit effecting functionality of the multilayer circuit board layout data.

In accordance with these and other objects of the disclosure, there is further provided an embodiment of the above described apparatus further having a component feed device disposed to present components for placement on the substrate with the substrate disposed on the table. The function head includes a component placement device configured to pick up the components and release the components. The controller is further configured to operate the component placement device, the function head and the positioner to effect placement the components on the substrate.

In a further embodiment of the present disclosure, an apparatus as described above is provided wherein the layout translation module is configured to accept the PCB multilayer circuit board files and convert component placement data of the PCB multilayer circuit board files to placement data files configured for controlling the function head and the component placement device to accept the components from the component feed device and place the components onto the substrate in accordance with the placement data files.

In yet a further embodiment of the present disclosure, an apparatus according to any of the above described embodiments is provided further comprising at least one heat source disposed to effect heating of the substrate with the substrate disposed on the table.

In another embodiment of the present disclosure there is provided a kit for printing a circuit on a substrate to produce a printed circuit board on a substrate. The kit comprises a conductive material print head containing a conductive material to be printed on the substrate, a nonconductive material print head containing a nonconductive material to be printed on the substrate, and a printing apparatus. The printing apparatus includes a table for supporting the substrate, a function head configured to accept installation, either simultaneously or one at a time, of the conductive material print head, or the nonconductive material printhead, and a positioner configured to effect movement of the function head and the table relative to one another. Further included is a controller configured to accept PWB data to operate the function head and the positioner to effect: printing on the substrate the nonconductive material when the function head has the nonconductive material print head installed; printing on the substrate of the conductive material to form printed conductors when the function head has the conductive material print head installed; and reprinting one or more of the printed conductors in response to test input indicating the one or more printed conductors fail testing.

A feature of the above embodiments includes the controller being configured to prompt an operator for the test input reflecting a status of a printed conductor. Another feature includes the controller operating a display of one or more of the printed conductors which is configured to prompt the operator for the test input corresponding to one or more of the printed conductors. Another optional feature provides for display presenting a diagram of the printed conductors.

Yet another feature of the above embodiments includes an electrical testing device having testing probe for test printed conductors at at least one point. The function head is configured to accept installation, either simultaneously or one at a time, of the conductive material print head, the nonconductive material printhead, or the testing probe. When the testing probe is installed in the function head, the controller operates the positioner and the function head to effect testing of the printed conductors to produce the test input indicating the one or more printed conductors fail testing and effect the reprinting of the one or more printed conductors in response to the test input. In an embodiment the testing probe and the conductive material printhead are simultaneously installed in the function head. In another embodiment the testing probe is integrated into the conductive material print head. A possible configuration includes the conductive material print head being an ink j et print head and the testing probe protruding from a bottom surface of the ink jet print head. In a further arrangement of the present disclosure the testing probe includes two probe contacts and the testing device effects a resistance measurement.

Still another embodiment of the present disclosure provides a kit for printing a circuit on a substrate to produce a printed circuit board on a substrate, wherein the kit comprises a conductive material print head containing a conductive material to be printed on the substrate, a nonconductive material print head containing a nonconductive material to be printed on the substrate, and a printing apparatus. The printing apparatus has a table for supporting the substrate, a function head configured to accept installation, either simultaneously or one at a time, of the conductive material print head, or the nonconductive material printhead. A positioner is configured to effect movement of the function head and the table relative to one another. A controller is configured to accept PWB data to operate the function head and the positioner to effect printing on the substrate the nonconductive material when the function head has the nonconductive material print head installed, printing on the substrate of the conductive material to form printed conductors and conductor pads when the function head has the conductive material print head installed; and generation of alignment structure data, based on the PWB data, which defines nonconductive alignment structures configured to align electrical components with the conductive pads when the components are installed on the conductive pads.

Further features of the above embodiment provide the nonconductive alignment structures including a nonconductive wall configured to surround the electrical components, or the nonconductive alignment structures including a nonconductive bosses configured to align the electrical components with the conductive pads. Aspects of this feature further provide that the nonconductive bosses are L-shaped, or crescent shaped, or round dots.

Still further aspects of the above embodiments of the present disclosure provide a controller is configured to accept data identifying areas of the substrate requiring stiffening and generate stiffening structure data for directing printing of the nonconductive material to form a stiffening support, and to operate the function head and the positioner to effect printing on the substrate the nonconductive material to form the stiffening structure when the function head has the nonconductive material print head installed.

Yet another embodiment of the present disclosure provides a kit for printing a circuit on a substrate to produce a printed circuit board on a substrate, with the kit comprising a conductive material print head containing a conductive material to be printed on the substrate, a nonconductive material print head containing a nonconductive material to be printed on the substrate, and a printing apparatus. The printing apparatus comprises a table for supporting the substrate, a function head configured to accept installation, either simultaneously or one at a time, of the conductive material print head, or the nonconductive material printhead, a positioner configured to effect movement of the function head and the table relative to one another, and a controller. The controller is configured to accept PWB data to operate the function head and the positioner to effect printing on the substrate the nonconductive material when the function head has the nonconductive material print head installed, and printing on the substrate of the conductive material to form printed conductors and conductor pads when the function head has the conductive material print head installed. The controller is further configured to accept data identifying areas of the substrate requiring stiffening and generate stiffening structure data for directing printing of the nonconductive material to form a stiffening support, and to operate the function head and the positioner to effect printing on the substrate the nonconductive material to form the stiffening structure when the function head has the nonconductive material print head installed.

In a further embodiment of the present disclosure there is provided a kit for printing a circuit to produce a printed circuit board which comprises print heads for printing materials. The print heads comprise a conductive material print head containing a conductive material as a conductive material to be printed, and a nonconductive material print head containing a nonconductive material as a nonconductive material to be printed. Further provided is a printing apparatus comprising a table for supporting the substrate, a function head configured to accept installations of the conductive material print head and the nonconductive material print head such that either one of the nonconductive material print head or the conductive material print head is carried on the function head at a given time, or both of the nonconductive material print head and the conductive material print head are simultaneously carried on the function head. Still further provided is a positioner configured to effect a movement of the function head and the table relative to one another. The kit includes a controller configured to accept circuit board parameter data defining a printed circuit board and to operate the function head and the positioner to effect: printing the nonconductive material when the function head has the nonconductive material print head installed to form printed conductive items; printing the conductive material when the function head has the conductive material print head installed to form printed nonconductive items, wherein the printed nonconductive items and the printed conductive items are defined by the circuit board parameter data. The controller also includes a parameter database storing data points comprising parameter data and being further configured to: produce a predicted performance of the printed conductive items for operator evaluation, prior to actual printing, by processing the stored parameter data based on the circuit board parameter data; accept operator input to provide revised circuit board parameter data and produce another predicted performance of the printed conductive items; and effect actual printing of the printed conductive items based on the revised circuit board parameter data.

In a still further embodiment of the above the parameter data base includes stored material quality parameters and material identifying data for available print materials, and the controller is configured to accept conductive material parameters of the conductive material to be printed including material identifying data of the conductive material to be printed.

Another feature of the above embodiment is provided wherein the circuit board parameter data includes design parameters defining the printed conductive items, the stored material quality parameters include past measured conductive parameters of past printed conductive items, and the controller is configured to provide the predicted performance of the printed conductive items based on the past measured conductive parameters.

Still further the above embodiment is optionally provided wherein the controller is configured to filter the past measured conductive parameters using the material identifying data of the conductive material to be printed and use resultant filtered past measured conductive parameters to provide the predicted performance of the printed conductive items. In a further variation the stored material quality parameters include material age parameters of available material used to print the past printed conductive items, the controller is configured to further filter the filtered past measured conductive parameters using the material identifying data included in the conductive material parameters of the conductive material to be printed and use resultant further filtered past measured conductive parameters to provide the predicted performance of the printed conductive items.

Yet another embodiment includes a variation of the above kit wherein the parameter data of the data points comprises fabrication slice parameters, material quality parameters of conductive materials used, and past measured design parameters of past printed conductive items, the circuit board parameters comprise design parameters and material quality parameters of the conductive material to be printed, and the controller is configured to process the process parameter data of the data points based on the design parameters of the circuit board parameters to produce optimized fabrication slice parameters.

Another embodiment of the above kit is provided wherein the material quality parameters of the data points include an material age parameter, the material quality parameters of the conductive material to be printed include a material to be printed age parameter, and the controller is further configured to process parameter data of the data points based on the design parameters of the circuit board parameters and the material to be printed age parameter to produce optimized fabrication slice parameters.

The above, and other objects, features and advantages of the present disclosure will become apparent from the following description read in conjunction with the accompanying drawings, in which like reference numerals designate the same elements. The present disclosure is considered to include all functional combinations ofthe above described features and corresponding descriptions contained herein, and all combinations of further features described herein, and is not limited to the particular structural embodiments shown in the figures as examples. The scope and spirit of the present disclosure is considered to include modifications as may be made by those skilled in the art having the benefit of the present disclosure which substitute, for elements presented in the claims, devices or structures upon which the claim language reads or which are equivalent thereto, and which produce substantially the same results associated with those corresponding examples identified in this disclosure for purposes of the operation of this disclosure. Additionally, the scope and spirit of the present disclosure is intended to be defined by the scope of the claim language itself and equivalents thereto without incorporation of structural or functional limitations discussed in the specification which are not referred to in the claim language itself.

The foregoing is a summary and thus contains, by necessity, simplifications, generalizations, and omissions of detail; consequently, those skilled in the art will appreciate that the summary is illustrative only and is not intended to be in any way limiting. Additional features and advantages of various embodiments of the present disclosure will be set forth in part in the non-limiting description that follows, and in part, will be apparent from the non-limiting drawings, or may be learned by practice of various embodiments. The objectives and other advantages of various embodiments will be realized and attained by means of the elements and combinations particularly pointed out in the description and appended claims.

### BRIEF DESCRIPTION OF THE DRAWINGS

In part, other aspects, features, benefits and advantages of embodiments of the present disclosure will be apparent with regard to the following description, appended claims and accompanying drawings wherein:

FIG. 1A is a top plan view of a PCB;

FIG. 1B is a bottom view of the PCB of FIG. 1a;

FIG. 1C is a top plan view of the PCB of FIG. 1a showing the bottom view of FIG. 1B in dashed lines;

FIG. 2 is a side elevation view of a cross section of the PCB of FIG. 1C;

FIG. 3 is a side elevation view of a cross section of multilayer PCB;

FIG. 4 is a block diagram of an embodiment of a PCB production apparatus 100 of the present disclosure;

FIG. 5A is a schematic representation of the PCB production apparatus 100 of FIG. 4;

FIG. 5B is a side elevation view the PCB production apparatus 100 of FIG. 5A taken along line VB-VB;

FIG. 6a is a partial schematic view of a function head of the present disclosure;

FIG. 6b is a partial schematic view of another function head of the present disclosure;

FIG. 6c is a partial schematic view of another function head of the present disclosure;

FIG. 6d is a partial schematic view of another function head of the present disclosure;

FIG. 6e is a partial schematic view of another function head of the present disclosure;

FIG. 7 is a block diagram of functional modules of a controller of the present disclosure;

FIG. 8 is a flowchart of an embodiment of operations of a layout translation module of the present disclosure;

FIG. 9a is a diagram of a PCB trace defining method;

FIG. 9b is a diagram of a circuit trace defined by the PCB trace defining method shown in FIG. 9a;

FIG. 9c is a diagram of a PCB traces;

FIG. 9d is a diagram of PCB traces and an insulating patch of the present disclosure;

FIG. 10a is a plan view of a PCB including the insulating patch of the present disclosure;

FIG. 10b is a plan view of a PCB including another insulating patch of the present disclosure;

FIG. 11 is a flowchart of a circuit printing method of the present disclosure;

FIG. 12a is a plan view of a PCB including a trace connection of the present disclosure;

FIG. 12b is a plan view of a PCB including another trace connection of the present disclosure;

FIG. 13 is a plan view of a PCB including another trace connection of the present disclosure, and PCB file syntax for effecting PCB fabrication of circuit traces;

FIG. 14a is a plan view of a PCB including a circuit plane embodiment of the present disclosure;

FIG. 14b is a plan view of a PCB including another circuit plane embodiment of the present disclosure;

FIG. 14c is a plan view of a PCB including another circuit plane embodiment of the present disclosure;

FIG. 15 is a plan view of a PCB having conductive traces thereon;

FIG. 16a is perspective view of a component tray of the present disclosure;

FIG. 16b is side elevation view of another component tray and a holding frame of the present disclosure;

FIG. 16c is a top plan view of the component tray and the holding frame of FIG. 16b;

FIG. 16d is a top plan view of another component tray and the holding frame of FIG. 16b;

FIG. 16e is a perspective view of another component tray of the present disclosure;

FIG. 16f is a perspective view of another component tray of the present disclosure;

FIG. 16g is a perspective view of another component tray of the present disclosure;

FIG. 16h is a perspective view of a standard component;

FIG. 16i is a perspective view of another component tray of the present disclosure;

FIG. 17a is a cross-sectional view of a substrate with conductive and non-conductive traces produced in accordance with a method of the present disclosure;

FIG. 17b is a cross-sectional view of another substrate with conductive and non-conductive traces produced in accordance with another method of the present disclosure;

FIG. 18a is a view of exemplary circuit traces;

FIG. 18b is a view of the exemplary circuit traces of FIG. 18a with indicia indicating a method of the present disclosure;

FIG. 18c is a view of the exemplary circuit traces of FIG. 18a with further indicia indicating the method of the present disclosure discussed with reference to FIG. 18b;

FIG. 19a is an illustration of circuit traces in relation to an embodiment of a print head;

FIG. 19b is an illustration of circuit traces in relation to current flow;

FIG. 19c is an illustration of a diagonal circuit trace;

FIG. 20a is an illustration of circuit traces;

FIG. 20b is an illustration of the circuit traces of FIG. 20a modified by a method of the present disclosure;

FIG. 20c is an illustration of the circuit traces of FIG. 20 b modified by a further method of the present disclosure;

FIG. 20d is an illustration of the circuit traces of FIG. 20 b modified by a still further method of the present disclosure;

FIG. 21 is an illustration of standard component pad arrangements;

FIG. 22A is an illustration of a portion of a printed wiring board 599 wherein a conductive layer 601 is printed on top of a base nonconductive layer 600 and nonconductive layers 602 are printed adjacent the conductive layer 601 in order maintain a relatively flat surface across the printed wiring board 599;

FIG. 22B is an illustration of a portion of a printed wiring board wherein first and second nonconductive layers 604 and 605 are printed to maintain electrical isolation between conductive layers of a converted multilayer circuit board layout data, which conductive layers include conductive layers 603 and 604 which are interconnected by two conductive layers 609 and 610 disposed in a via opening defined in the two nonconductive layer 604 and 605 in a stacked arrangement to maintain a relatively flat surface across the printed wiring board at via interconnects;

FIG. 23 is an illustration of a portion of a printed wiring board 619 wherein first and second conductive traces, 621 and 622, are printed on nonconductive layer 620 and differing thickness so as to provide different current carrying capacity or resistance;

FIG. 24 is an illustration of a PWB 624 having two conductive lines 625 and 626 printed on substrate 627. which could be conductive or non-conductive, having a conductive line 625 is printed on top ofnon-conductive layer 628 with a height that places a top of conductive line 625 at approximately a same position as a top of conductive line 626;

FIG. 25 is an illustration of a PWB having a previously cut optionally provided non-conductive substrate 635 with a printed non-conductive layer 636 and a conductive layer 637;

FIG. 26A is an illustration of a test pattern 650 created by printing a pattern using a function head with five nozzles; and

FIG. 26B is an illustration of a test pattern 656 having a non-functioning nozzle creating a gap.

FIG. 27A is a side elevation partial cross section view of a traditional etched PWB showing an electrical component positioned on conductor pads and a solder mask applied to the PWB;

FIG. 27B is a side elevation partial cross section view an embodiment of a PWB produced by an apparatus and method of the present disclosure wherein nonconductive areas are optionally printed leveling a board surface, and further nonconductive areas are printed and configured to align an electrical component on conductor pads;

FIG. 27C is a side elevation partial cross section view another embodiment of a PWB produced by an apparatus and method of the present disclosure wherein nonconductive areas are printed leveling a board surface and further nonconductive areas are printed and configured to align an electrical component on conductor pads by operation of inclined sides positioned adjacent the component;

FIG. 27C is a side elevation partial cross section view a further embodiment of a PWB produced by an apparatus and method of the present disclosure wherein nonconductive areas are printed and configured to align an electrical component on conductor pads by operation of inclined sides positioned adjacent the component;

FIG. 27D is a side elevation partial cross section view a still further embodiment of a PWB produced by an apparatus and method of the present disclosure wherein nonconductive areas are printed and configured as dikes to align an electrical component on conductor pads:

FIG. 28A is a plan view of a conductive trace having portions identified and the conductive trace containing a flaw;

FIG. 28B is a plan view of a conductive trace having printing coordinates identified and the conductive trace containing a flaw;

FIG. 29A is flowchart of an embodiment of a semi-automated conductor printing and testing process;

FIG. 29b is flowchart of an embodiment of a semi-automated conductor layer printing and testing process;

FIG. 29C is a depiction of an embodiment of a display screen for displaying conductor layer data and inputting test results;

FIG. 30A is a schematic diagram of an embodiment of an electrical measurement unit comprising an electrical test instrument, an optional probe rotation mechanism, and a probe holder mechanism;

FIG. 30B is a side elevation partial cross section view of an embodiment of a function head comprising an optional probe rotation mechanism, an optional head module rotation mechanism, and a probe holder mechanism;

FIG. 30C is a side elevation partial cross section view of an embodiment of a function head comprising optional an optional head module rotation mechanism, and a printhead configured with probes for electrical testing;

FIG. 30D is a side elevation partial cross section view of an embodiment of a dual function head comprising a printhead and a probe holder mechanism with an optional probe holder rotation mechanism;

FIG. 31A is flowchart of an embodiment of a sub-process for automated conductor printing and testing wherein conductors are printed and then tested;

FIG. 31B is flowchart of an embodiment of a process for producing a PWB including the sub-process of FIG. 31A;

FIG. 32A is flowchart of an embodiment of a sub-process for automated conductor layer or group printing and testing wherein conductors of the layer or group are printed and then the printed conductors of the layer or group are tested;

FIG. 32B is flowchart of an embodiment of a process for producing a PWB including the sub-process of FIG. 32A

FIG. 33A is a side elevation view of a flexible printed circuit having a conductor flaw;

FIG. 33B is a side elevation view of an embodiment of flexible printed circuit having a conductor and a nonconductive stiffener;

FIG. 34 is a table of showing an embodiment of a parameter set used in defining a PWB and characterization of printed items;

FIG. 35a is a sample graph of conductive trace resistance vs sintering temperature;

FIG. 35b is a graph of cure profile for an exemplary design;

FIG. 35c is a table of cure profile data for an exemplary circuit board;

FIG. 35d is a schematic diagram of an embodiment of a thermoelectric print head with embedded material reservoir and embedded temperature sensor;

FIG. 35e is a schematic diagram of an embodiment of a piezoelectric print head with embedded material reservoir and embedded temperature sensor;

FIG. 35f is a schematic diagram of an embodiment of a thermoelectric print head with external material reservoir and embedded temperature sensor;

FIG. 35g is a schematic diagram of an embodiment of a piezoelectric print head with external material reservoir and embedded temperature sensor;

FIG. 35h is a schematic diagram of an embodiment of a syringe extruder with embedded pressure sensor;

FIG. 35i is a schematic diagram of an embodiment of a syringe extruder with a plunger travel sensor;

FIG. 36a is a high level flow chart of an embodiment of apparatus operation for building a PWB and recording material performance;

FIG. 36b is a flow chart of an embodiment of operation 950-4 of FIG. 36a showing operations for project setup and configuration;

FIG. 36b-1 is a flow chart of an embodiment of operation 960-4′ of FIG. 36a showing operations for project setup and configuration;

FIG. 36c is a flow chart of an embodiment of operation 952-1 of FIG. 36b or operation 953-1 of FIG. 36b-1 for predicting and/or optimizing parameters;

FIG. 36d is a flow chart of an embodiment of operation 950-6 of FIG. 36a for building a PWB, measuring results, and repairing;

FIG. 37 is an embodiment of an interface display showing parameters, predicted characteristics, and options for adjusting parameters; and

FIG. 38 is an embodiment of a display table of measurement results from building two resistors.

### DETAILED DESCRIPTION

For the purposes of this specification and appended claims, unless otherwise indicated, all numbers expressing quantities of ingredients, percentages or proportions ofmaterials, reaction conditions, and other numerical values used in the specification and claims, are to be understood as being modified in all instances by the term “about.” Accordingly, unless indicated to the contrary, the numerical parameters set forth in the following specification and attached claims are approximations that may vary depending upon the desired properties sought to be obtained by the embodiments of the present disclosure. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all subranges subsumed therein. For example, a range of “1 to 10” includes any and all subranges between (and including) the minimum value of 1 and the maximum value of 10, that is, any and all subranges having a minimum value of equal to or greater than 1 and a maximum value of equal to or less than 10, e.g., 5.5 to 10.

It is noted that, as used in this specification and the appended claims, the singular forms “a,” “an,” and “the,” include plural referents unless expressly and unequivocally limited to one referent. Thus, for example, reference to “a member” includes one, two, three or more members.

Reference will now be made in detail to various embodiments of the present disclosure, examples of which are illustrated in the accompanying drawings. While the embodiments of the present disclosure will be described in conjunction with the illustrated embodiments, it will be understood that they are not intended to limit the disclosure to those embodiments. On the contrary, the disclosure is intended to cover all alternatives, modifications, and equivalents, which may be included within the disclosure as defined by the appended claims.

The headings below are not meant to limit the disclosure in any way; embodiments under any one heading may be used in conjunction with embodiments under any other heading.

### Overview

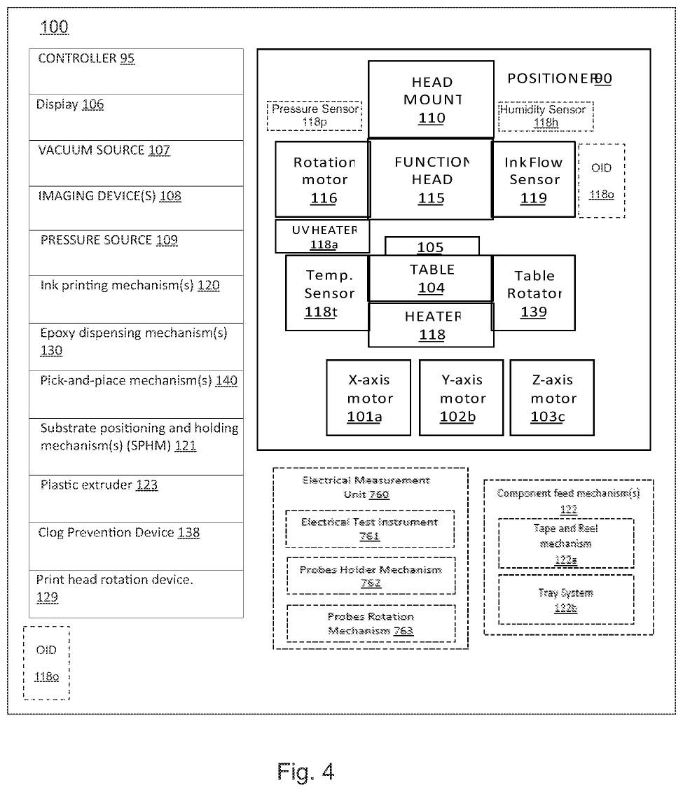

Referring to FIG. 4, an embodiment of the present disclosure includes a printed circuit board (PCB) production apparatus 100 comprising a positioner 90, a controller 95, a display 106, a vacuum source 107, and an imaging device 108. The positioner 90 further comprises a head mount 110, a function head 115, and a table 104. The positioner operates to effect three axis movement of the function head 115 relative to the table 104 as directed by the controller 101. The table 104 is configured to support a substrate 105 which is a workpiece to be fabricated into a PCB. A component feed mechanism 122 and a component mounting head 140 are optionally provided. The component feed mechanism 122 may be embodied as a tape and reel mechanism 122a or a tray system 122b, or both either simultaneously or interchangeably. Details of the controller 95 are depicted in FIG. 7 and include a component mounting control module (CMCM) 127 which controls operations of the component mounting head 140 and the component feed mechanism 122 when the PCB production apparatus 100 is so equipped.

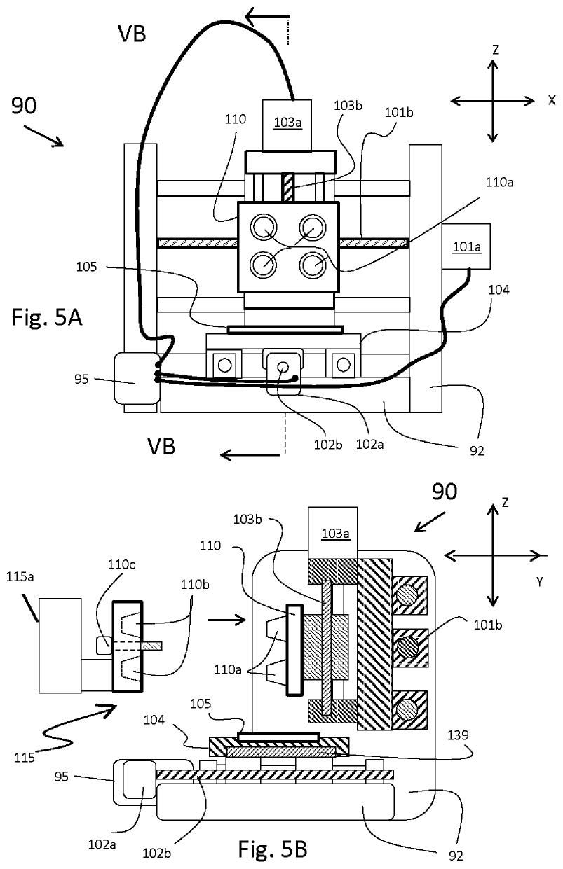

Referring to FIGS. 5A and 5B, a simplified, schematic in part, depiction of an embodiment of the positioner 90 illustrates a basic configuration of a positioner. The present disclosure is not restricted to the configuration illustrated, and it will be understood by those skilled in the art that other positioner configurations are optionally adaptable for use in the PCB production apparatus 100 provided the configurations are capable of positioning the function head relative to the substrate 105 in x, y, and z axis directions. Motion along each axis is optionally implemented by a motor and a lead screw. Other optionally employable actuation mechanisms include, for example and not limitation, linear motors and motors operating, inter alia, belts and pulleys, and rack and pinions. In the embodiment of FIGS. 5A and 5B, an x-axis motor 101a drives an x-axis lead screw 101b, a y-axis motor 102a drives an x-axis lead screw 102b, and a z-axis motor 103a drives an z-axis lead screw 103b. The head mount 110 is vertically moved by the z-axis lead screw 103b and is horizontally moved in the x-axis by the x-axis lead screw 101b. The table 104, which supports the substrate 105, is horizontally moved in the y-axis direction by the y-axis lead screw 102b. The table 104 is optionally mounted to permit rotation in an embodiment including table rotator 139 which may be embodied as a motor, solenoid, field coil, or other actuator.

The function head 115 optionally mounts to the head mount 110 by mount screw 110c and is aligned by virtue of alignment cones 110a mating with alignment cavities 110b. Other mounting configurations may be adapted without departing from the scope of the present disclosure. The function head 115 has a function module 115a which is optionally configured to effect any or all of ink dispensing, epoxy dispensing, or component placement as is discussed below. The PCB production apparatus 100 is capable of printing circuit traces and/or performing pick-and-place attachment of electrical components. The PCB production apparatus 100 is optionally used for low-cost rapid prototyping and rapid manufacture of complete printed circuit assemblies.

As is elaborated upon below, an embodiment of the PCB production apparatus 100 comprises a function module 115a configured as a printing device for printing conductive material onto the substrate 105. The PCB production apparatus 100 is also optionally capable of positioning circuit components onto the substrate 105 in electrical connection to the conductive material with the function module 115a configured for component mounting as discussed below. In some applications, attachment of circuit components to the substrate 105 and conductive material may include application of a conductive epoxy and the function module 115a is optionally configured with the epoxy dispenser 130. An embodiment of the PCB production apparatus 100 is also capable of applying non-conductive epoxy at specific locations on the substrate 105. If heat curing is optionally used for proper operation of the conductive material and epoxy, an embodiment of the PCB production apparatus 100 optionally includes heater 118 which is a source of heat which is applied under the control of the controller 95. For lightweight and/or flexible substrates, an embodiment of the PCB production apparatus 100 optionally includes a substrate positioning/holding mechanism 121 for temporarily holding substrate 105 to table 104 which, in one embodiment, includes the vacuum source 107. The PCB production apparatus 100 optionally includes the imaging device 108 for implementing a scanning, or digitizing, function for creating a digital model of an arbitrary three dimensional structure for aiding in the positioning of the ink printing and component placement. A further embodiment of the PCB production apparatus 100 optionally includes a material printing function for printing plastic and/or metal structures for supporting and/or enclosing the PCA.

### Controller.

The controller 95 controls functions of the PCB production apparatus 100, including the movement of the head mount 110 relative to substrate 105, and is implemented by software and/or firmware which resides internal to the PCB production apparatus 100, external to the PCB production apparatus 100, or split between the two, where some functions reside external to the PCB production apparatus 100 and some functions reside internal to the PCB production apparatus 100. To aid in the readability of this document, all software and/or firmware references related to the operation of the PCB production apparatus 100 will be referred to as firmware. In some cases, firmware will be referring to an application module that is part of the complete the PCB production apparatus system software or the firmware will be referring to application modules that are optionally operated as stand-alone software applications. Firmware will reside in the controller 95 which is integrated into the PCB production apparatus 100. The controller 95 may be any of a microcontroller, a single board computer capable of producing signals to control the movement of head mount 110, or a standalone computer, such as but not limited to a PC, which has an I/O unit configured to control components of the PCB production apparatus 100 such as any one or combination of the x-axis motor 101a, the y-axis motor 102a, the z-axis motor 103a, the function head 115, the imaging device 108, and the pressure source 109.

It will be understood by those skilled in the art that the controller 95, although depicted as a module within the PCB production apparatus 100 in FIG. 4, is optionally implemented in a distributed fashion wherein a control module is internal to the PCB production apparatus and a computer, separate from but in electronic communication with the internal control module, operate in conjunction with each other to effect control of the PCB production apparatus 100. For the purposes of this disclosure, the term “controller” is intended to include such an arrangement as well as an arrangement wherein a computer is external to the PCB production apparatus 100 but controls operation of components of the PCB production apparatus 100 as discussed above via an I/O unit. In such an embodiment, the computer is to be considered a portion of the PCB production apparatus 100.

### Function Head.

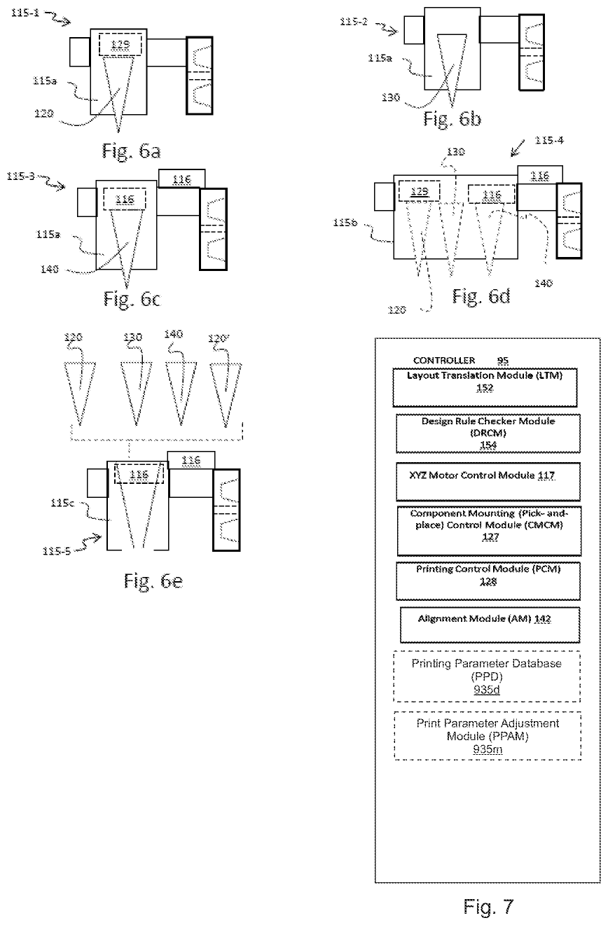

Referring to FIGS. 6a-6f, in an embodiment, the function head 115 includes an ink printing mechanism 120 for printing conductive traces by dispensing of conductive inks onto the substrate 105. The ink printing mechanism 120 is attached to the PCB production apparatus 100 at head mount 110. Dispensing conductive ink using the ink-printing mechanism 120 includes, but is not limited to, processes such as syringe printing, piezoelectric-based printing, ink-jet printing and ink spray. Some printing techniques, such as syringe printing, require the application of air pressure provided by optional pressure source 109, shown in FIG. 4, or mechanical pressure applied by an electric motor or other actuator to push the ink through the ink nozzle.

Conductive inks are typically silver and copper-based but could be of any ink that would provide reasonable conductivity for transfer of electrical signals across the conductive traces. An example of a commercially available silver-based conductive ink is Metalon HPS-021LV from Novacentrix. The HPS-021LV has a resistivity of 6.74 E-5 ohm-cm when the ink is cured at 125° C. There are several other manufacturers of conductive inks that are optionally used when printing conductive traces using the ink-printing mechanism 120 described in this disclosure.

The ink-printing mechanism 120 may include a nozzle or tip with an opening for the ink to flow through. The ink-printing mechanism 120 may be capable of having the tip replaced should a larger or smaller width line be required by the circuit.

Other commercially available conductive inks are capable of being printed using standard ink-jet printing techniques. These types of inks are typically based on nano-particles which allow the ink to be ejected from small holes characteristic of a standard ink-jet cartridge or piezeoelectric nozzle. Here the conductive ink is optionally filled in an ink-jet cartridge and the PCB production apparatus 100 controls the release of conductive ink onto the substrate 105.

Movement of the head mount 110 relative to the table 104, is controlled by the controller 95 based on information contained in a digital model or image of a desired conductive trace geometry or circuit layout. Details of the circuit layout is often contained in an industry-standard Gerber file or any other type of file which supports the desired geometry of the conductive traces. File types may include electronic image files including bitmaps (BMP), JPEGs, GIFs and TIFFs to name a few. The position of the head mount 110 is optionally manually controlled by the operator via the controller 95.

At any one time, embodiments of the function head 115 will contain at least one of the following PCB production mechanisms: the ink-printing mechanism 120 in a function head 115-1 of FIG. 6a, an epoxy-printing mechanism 130 in a function head 115-2 of FIG. 6b, and/or a pick-and-place mechanism 140 in a function head 115-3 of FIG. 6c. Alternatively, an embodiment of a function head 115-4 optionally has a function head module 115b which includes all or any combination of functions as shown in FIG. 6d. The function head module 115b is also optionally configured to include two functions instead of three. Alternatively, as shown in FIG. 6e, an embodiment of the present disclosure includes a function head 115-5 having a function head module 115c configured to be automatically or manually loaded with any of the PCB production mechanisms 120, 130, or 140 based on a desired operation and optionally under firmware control.

The function head 115 optionally has a rotation motor 116 (dashed line representation) to rotate the pick-and-place mechanism 140 or the pick-and-place mechanism 140 includes the rotation motor 116 (dashed line representation) to implement a rotation feature to properly position the electrical component onto the substrate 105. Another embodiment has the rotation motor 116 (solid line representation) mounted outside of the function head module 115a, 115b, or 115c so as rotate the whole function head module 115a, 115b, or 115c. Alternatively, the rotation motor 116 (dashed line representation) may be mounted on the function head module 115a, 115b, or 115c so as to rotate the function head module 115a or 115b relative to the function head 115-3, 115-4, or 115-5.

In an embodiment, the function head 115b includes the ink-printing mechanism 120 and the pick-and-place mechanism 140. The function head module 115b optionally has a print mechanism rotation device 129 (dashed line representation) to rotate the printing mechanism 120 or the printing mechanism 120 includes the rotation device 129 (dashed line representation) to implement a rotation feature to orient a print head as discussed below with regard to circuit trace printing. The print head rotation device 129 is optionally embodied as motor but other actuating devices such as solenoids, voice coils or pneumatic actuators operating off the vacuum source may be used. The embodiment of the function head module 115b having the rotation motor 116 (solid line representation) mounted outside of the function head module 115a, 115b, or 115c so as rotate the whole function head module 115a, 115b, or 115c, is also optionally adapted to print head orientation.

The function head module 115b may include several ink-printing mechanisms, one for each printing type, including mechanisms for conductive ink printing, insulator ink printing and epoxy deposition to name a few. The individual printing and deposition mechanisms may share common parts such as a syringe motor or pressure sensor to name a few. In one configuration, the function head module 115b allows substitution of one ink type for another, such as a case when a syringe that contains the conductive ink is replaced with a syringe containing the insulating ink. Having the flexibility to replace ink containers may reduce the total cost of the PCB production apparatus 100.

In some applications, it may be beneficial to have a complete inking mechanism for each type of ink and epoxy. For example, some ink and epoxy products are two-part systems containing a base material and a catalyst. In this case, a separate mechanism is optionally used to apply the two parts to substrate 105. The epoxy may include conductive and non-conductive forms. Conductive epoxy is optionally used for making an electrical contact between the component and the conductive traces. Non-conductive epoxy is optionally used for holding components and devices to the surface of substrate 105 and the conductive traces.

The epoxy is optionally thermally conductive for applications requiring the dissipation of heat. The epoxy will be dispensed using an epoxy-printing mechanism. The epoxy-printing mechanism may be of the same type as the ink-printing mechanism. The epoxy-printing mechanism may be of a different type than the ink-printing mechanism. For example, the ink-printing mechanism may include an ink-jet technology while the epoxy-printing mechanism may include a syringe printing process. Another example may have the ink-printing mechanism using a single tip dispensing process while the epoxy-printing mechanism optionally uses a dual tip dispensing system when a two-part epoxy is optionally used. These are not the only combinations of dispensing types but are used here to describe some possible variations in dispensing techniques.

### Substrate.

The substrate 105 is optionally of any type of non-conductive material to which the conductive traces may be firmly attached and cured. The substrate material may be rigid or flexible, for example and not limitation, fiberglass boards, paper, plastic, wood, glass, cloth, or skin. Referring to FIGS. 5A and 5B, the substrate 105 is supported within the PCB production apparatus 100 using the table 104. The table 104 is typically a flat rigid plate which is attached to the PCB production apparatus 100. The table 104 is optionally made from a variety of materials including, but not limited to, plastics, metals and fiberglass board. The table 104 is optionally removable.

### Table.

The table 104 optionally also includes a three-dimensional form onto which substrate 104 will be held. The form is optionally a shape that is cylindrical, hemispherical, conical or rectangular to name a few, other shapes are also possible. The limitation in the shape form is only dictated by the flexibility of the PCB production apparatus 100 to printing ink onto a complex structure.

The table 104 may be fixed in location relative to an apparatus frame 92 or may physically move in one or more dimensions under the control of the firmware in order to aid in the printing of inks and insulators. The PCB production apparatus 100 as shown in FIGS. 5A and 5B, is configured with table 104 movement along the y-axis relative to the apparatus frame 92. The y-axis motor 102a is attached to the lead screw 102b which moves table 104 when motor 102a is turned. When the y-axis motor 102a moves the table 104, the relative position to the head mount 110 to the table 104 is changed. The x-axis motor 101a is connected to the lead screw 101b and moves the head mount 110 along with the z-axis motor 103a and lead screw 103b relative to the frame 92 and the table 104 along the x-axis. The z-axis motor 103a drives another lead screw 103b to move the head mount 110 in the vertical direction along the z-axis relative to the table 104 and the frame 92. Having three axis of motion allows the head mount 110 to be positioned anywhere across table 104 and the substrate 105. An alternative embodiment of the PCB production apparatus 100 movably supports the table 104 to move in both in the x-axis and y-axis directions relative to the frame 92 and the head mount 110 to move in the z-axis relative to the frame 92. One skilled in the art will understand that there are numerous other combinations for three dimensional movement of the table 104 relative to head mount 110 and will appreciate that such configurations are within the scope of this disclosure.

### PCB Production Files.

PCB production techniques produce conductive traces that follow a circuit pattern required for an electronic circuit with details defining the circuit pattern saved in an electronic file. The information contained in the pattern, also called the layout, may be recalled through the firmware from an electronic database and transferred to the apparatus controller 95 by the operator. In typical applications, the layout would be designed and saved using a separate Computer Aided Design (CAD) tool such as Cadence OrCAD, CadSoft Eagle and Mentor Graphics PADS to name a few. In an embodiment of the present disclosure, the CAD tool is optionally integrated as part of the PCB production apparatus firmware. The CAD tools may output the circuit layout in the form ofnative file types, Gerber, or some other standardized file type. For example, a Gerber file is a data file describing the physical layout of a single layer of a printed wiring board. These layout file types may also include Bitmaps (BMP), JPEGs, GIFs and TIFFs to name a few. The Gerber file is an industry standard used in the fabrication of chemically etched and mechanically etched printed wiring boards. To improve the readability of this document, the term Gerber will be used to describe any type of electronic file that describes the layout of a single layer of printed wiring board including vector and image based electronic files. However, it will be understood that the present disclosure includes any other file type defining a circuit layout when using the name Gerber unless explicitly limited to a Gerber file.

To completely describe a PCB, a set of Gerber files is often required including files that may define conductive and non-conductive features of the printed wiring board. These files may also include the physical location of individual components. In a multilayer printed wiring board, several Gerber files are required to describe each layer in the complete board. In general, the generic term “PCB file” will be used hereinafter to refer to a file describing circuit layout features directed to single or multilayer PCB to be manufactured using conventional methods, such as a Gerber file. The term “printed PCB file” will be used to refer to a file configured to control the PCB production apparatus 100 for producing a PCB using the method of the present disclosure for printing circuitry incorporating multiple layers using printing techniques.

### Layout Translation Module.

Firmware of the controller 95 will optionally include a layout translation module (LTM) 152 to translate the PCB files into instructions for controlling a location of head mount 110 and each of the associated operations of the PCB production apparatus 100 including the ink-printing mechanism 120, epoxy-printing mechanism 130 and the pick-and-place mechanism 140. The LTM 152, implemented by PCB file translation-software, may reside external to the PCB production apparatus 100 or included as part of the firmware. When the translation-software is external to the PCB production apparatus 100, it may reside in a local personal computer, reside in a web-based tool or any other computing device capable of inputting electronic data files and performing the translation from layout of conventional PCB files to files for controlling the PCB production apparatus 100, hereinafter referred to as apparatus layout files (ALFs), which define the conductive and nonconductive geometries and traces to be produced by the PCB production apparatus 100. Taken a further step, the ALFs may subsequently be translated into apparatus control files (ACFs) which are commands for controlling the PCB production apparatus 100 to produce the PCB. The ACFs may be created “on the fly” from the ALFs to control the PCB production apparatus 100 in the manner that interpreters accept source code and effect program functions without first compiling source code.

In an alternative embodiment of the PCB production apparatus 100, the LTM 152 of FIG. 7 is included within a CAD tool that examines the conductive layers and creates a separate PCB file that includes the insulating geometries to separate at least two conductive layers. The generation of a PCB file containing the insulating geometries is optionally independent of the firmware of the PCB production apparatus 100 in this embodiment. In the embodiment of FIG. 7, firmware of the PCB production apparatus 100 includes the LTM 152 and imports PCB files, inter alia, Gerber files, for two or more conductive layers and determines the insulating geometries for the non-conductive ink. While the aforesaid embodiment of the present invention optionally includes firmware of the LTM152 that interprets PCB files, inter alia, Gerber files, for two or more conductive layers, the firmware optionally further includes a module recognizing direct commands for the PCB production apparatus 100 to effect PCB creation based on files not requiring a translations and, instead, directly controlling the PCB production apparatus 100.

### Design Rule Checker.

A Design Rule Checker module (DRCM) 154 is optionally employed to verify that the CAD file and/or printing instructions is compatible with control of the PCB production apparatus 100 and also within limits for printing conductive and non-conductive traces defined by limits of the PCB production apparatus 100, for example and not limitation, line width, line spacing and overlap. The DRCM 154 may also check the capability for printing conductive epoxy. In an embodiment, the DRCM 154 is included as an option in the CAD software tool. In another embodiment the DRCM 154 is included as part of the firmware so that the PCB production apparatus 100 can check files from CAD tools not specifically equipped to provide files for the PCB production apparatus 100.

### Intersection Determination and Isolating Layers.

In producing two-layer and multi-layer PWBs using the PCB production apparatus 100, it may be necessary to print insulating inks when two or more conductive lines must cross over each without making electrical contact. The insulating ink replaces the function of the built-in isolation achieved with substrate 52 shown in FIG. 2. In this case, there are at least two PCB files to describe each layer in the complete PCB. The LTM 152 has a function that will process the PCB files to identify the need for an insulating layer by locating a position of circuit traces of different layers that intersect when the PCB is viewed from the z-axis direction in order to generate an insulator geometry for electrically isolating intersecting conductive traces when producing the PCB using the PCB production apparatus 100.

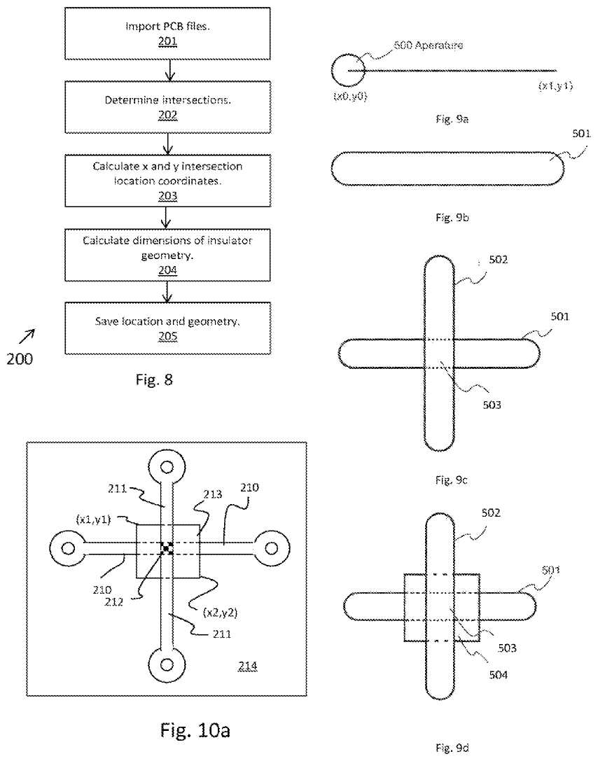

The LTM 152 optionally creates a list oflocations where insulating ink is to be deposited onto the substrate 105 covering a first circuit feature and preventing electrical connection between the first circuit feature and those that cross over the first circuit feature. The list may include a width and length of the insulator geometry formed by printed insulating ink. Referring to FIG. 8, an insulator generation process (IGP) 200 is a multistep process which includes importing the PCB files 201, examining the PCB files for intersections 202, calculating x, y location coordinates for each intersection 203, calculating length and width of insulating geometry 204, saving location and geometry information 205 for later use by the PCB production apparatus 100 to print non-conductive ink.

When examining conventional PCB files which contain layout geometry for two or more different conductive layers in a PWB, it is important to identify lines from separate layers that would cross over, intersect or overlay is some way when printed with conductive ink absent intervening board layer(s) of conventional PWBs. A standard Gerber file includes information contained in the header followed by a description of the geometry. For example, a single trace would have the following text-based file stored in the format of a Gerber file.
% FSLAX25Y25*%
% MOIN*%
% IPPOS*%
% ADD10C, 0.05*%
% LPD*%
X0Y0D2*D10*G1X84464Y145472D2*X113885D1*X0Y0D2*M02*
   The file begins with % FSLAX25Y25*% which describes the coordinate format of Leading Zero's omitted, Absolute Coordinates, 2 Digits in the Integer Part and 5 Digits in the Fractional Part. The % MOIN*% represents the units set to inches. % IPPOS*% sets the image to have positive polarity. The % ADD10C, 0.05*% defines an aperture with D-code 10 as a 0.05-inch circle. The % LPD*% Start a new level with dark polarity. The X0Y0D2*D10* commands a move to (0,0) and select aperture D10. G1 command is for linear interpolation. The Command X84464Y145472D2 is a move to (0.84464″, 1.45472″). Command X113885D1 is draw to (1.13885″, 1.45472″). The X0Y0D2 commands a move to (0,0). The M02 is the end of file.

Referring to FIG. 9a, an example of a line defined by a Gerber file with two end points of a line are shown as (x0,y0) and (x1,y1). An aperture 500 is defined using the aperture definition in the Gerber file. The final geometry is created by moving the aperture 500 from endpoint (x0,y0) to (x1,y1). It should be noted that circular apertures are not the only types available in Gerber formats, squares, rectangles and almost any shape is optionally assigned to an aperture according to the 274X specification. Referring to FIG. 9b, the geometry of the first conductive trace 501 based on the information shown in FIG. 9a is shown. The first conductive trace 501 is the geometry that will be printed using either the PCB production apparatus 100 or conventional PCB manufacturing equipment. When Gerber files from two or more conductive layers are to be printed on a substrate, it is assumed that there will be overlap between portions of at least one pair of conductive traces.

There a several ways to determine overlap between traces from two or more layers. An imaging method is optionally used to convert the conductive trace 501 to a graphics or image file and compare the information contained in this image file to the information contain in another image file. Another method optionally employed is to mathematically determine the location of the overlap using mathematical techniques known in the industry which compare line segments for overlap or touching. Mathematical techniques must also include aperture inclusion wherein the width of the aperture that runs along the centerline of the trace including the extension beyond the endpoints of the line created by the radius of the aperture at each end.

Referring to FIG. 9c, in using the imaging method, the first conductive trace 501 is converted to an image file and the second conductive trace 502 is converted to an image file. In the operation 202 of FIG. 8, the imaging technique may be used wherein the images are aligned and a pixel by pixel comparison is made until first overlap 503 is determined. Alternatively, the mathematical technique may used wherein a conductive intersection is optionally determined by examining a vector representation of the first conductive trace 501 and the second conductive trace 502. In an embodiment of the mathematical technique, matrix calculating methods are optionally employed using determinants. It will be understood that other techniques for calculating the conductive intersection 503 are optionally developed including when conductive intersection 503 includes shapes such as square, rectangular and other complex geometries.

In operation 203, the coordinates of the intersection are determined based on the technique used to find the intersection. In an embodiment of operation 203, the area of the first overlap 503 is stored as another image file based on the total number of pixels and layout of the pixels. Another embodiment of operation 203 includes a technique to store the first overlap 503 in terms of a centroid, length and width. As not all overlaps are rectangular, as in the case when diagonal lines are present, the geometry of a complex overlap may be stored.

### Insulating Geometry.

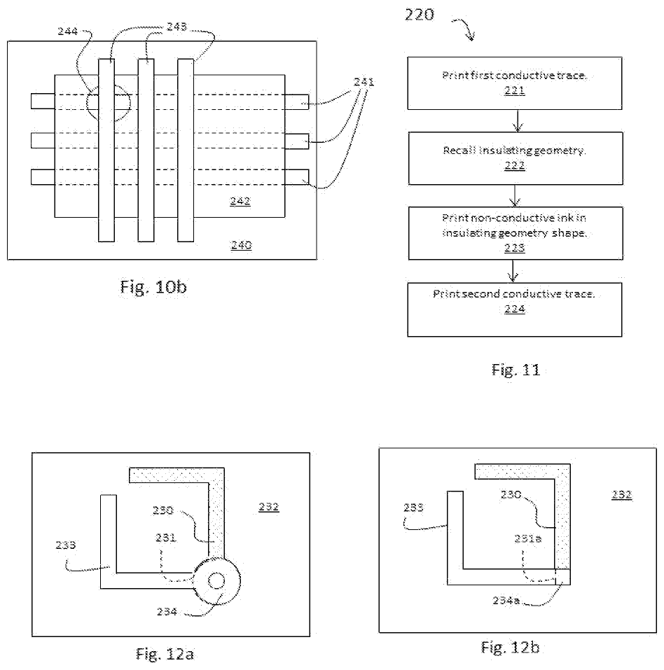

Once the overlap, i.e., intersection, is determined, operation 204 is effected wherein a new geometry for an insulator is created that matches or is slightly larger than the geometry of the overlap 503. When printing two conductive traces that should be electrically isolated, it is advantageous to oversize the overlap geometry to prevent the possibility that the two conductive traces will short together. Referring to FIG. 9c, an insulating patch 504 is designed to be slightly larger than first overlap 503. When printing conductive traces 501 and 502, insulating patch 504 will be printed between them to create a layer of insulation. This is likewise shown in FIG. 10a wherein the insulating patch 213 is depicted.

Referring to FIG. 10a, it is optionally provided that an approximate area and location for the overlap be determined in order to calculate an appropriate size of the insulating geometry 213. As shown in FIG. 10a, the insulating geometry 213 is shown as a square with center xc, yc and associated width (x2−x1) and length (y2−y1). Insulating geometry 213 can also be represented by corner points (x1,y1) and (x2,y2). The insulating geometry 213 is not limited to square geometries and is optionally of any shape large enough to electrically isolate the conductive trace 210 from the conductive trace 211.

### Creating Isolated Insulated Intersecting Traces.

Returning to FIG. 9d, the process to create insulating patch 504 starts with the geometry of first conductive trace 501 and geometry of second conductor 502. These geometries are optionally stored as part of a software tool that routes conductive traces onto separate layers. These routing tools create the layout geometries that will be converted to commands used by apparatus to print conductive ink. Another option would be to recall two Gerber files that contain the appropriate layout information for first conductive trace 501 and second conductive trace 502.

The insulator geometry operation 204 uses the overlap geometry determined using image-based techniques or mathematically techniques in operations 202 and 203. An example of the insulator geometry is the insulator patch 504 of FIG. 9d. In an advantageous configuration, the insulating patch 504 is configured using an oversize dimension that, in one embodiment, is at least 0.005-inch larger than the overlap geometry 503 however this is not a requirement as other oversize dimensions may be used. The actual size of the insulating patch is a function of the printing capability of the apparatus including print resolution for both the conductive and non-conductive inks. The sizing of the insulating patch is optionally automatically determined or input by the operator such as a manually introduced setting that the insulating patch to be 0.005-inch beyond the nearest point to the overlap geometry 503.

The creation of the insulator geometry of the insulating patch 504 is performed by the LTM 152 in operation 204 or is optionally performed in a software tool that routes the layout. Once the layout information for the insulating patch is determined, it is stored as an image file or as a Gerber file, for example purposes only as other known commercial standards for files defining multilayer circuit boards are optionally used by the PCB production apparatus 100 during the multilayer printing process. If the layout information is determined by the LTM 152, it is optionally used to directly control the printing-mechanisms in apparatus.

### Creating Insulated Regions of Intersecting Traces.

Another form of insulating two conductive layers is to print an entire region of insulating ink between the two conductive layers. Referring to FIG. 10b, a first conductive layer 241 is first printed on a substrate 240. Insulating layer 242 is then printed on top of first conductive layer 241 to cover at least a portion of the conductive traces of first conductive layer 241. Second conductive trace layer 243 is printed on top of insulating layer 242. The geometry of insulating layer 242 is determined by examining the Gerber files of first conductive layer 241 and second conductive layer 242. In some cases, the geometry of insulating layer 242 may be optimized to reduce ink usage and time printing the non-conductive ink, or the insulating patch technique discussed above may be employed. In some cases, it is preferred to completely cover the substrate 240 with insulating layer 242.

### Printing Insulated Intersecting Traces.

Referring to FIG. 11, a multilayer printing process 220 is shown for printing two conductive traces separated by an insulating layer shaped with a geometry that electrically isolates the two conductive lines. The multilayer printing process 220 starts with printing a 1st conductive trace in operation 221, followed by recalling the insulating geometry 222 which has been defined in operation 222, followed by operation 223 printing non-conductive ink in the shape of the insulating geometry 223 and lastly, printing 2nd conductive trace 224. The function head module 115b of FIG. 6d optionally includes two of the ink-printing mechanisms 120 respectively containing conductive and non-conductive inks in the same subsystem. Alternatively, the function head module 115a has a single one of the ink-printing mechanisms 120 with the conductive ink and non-conductive ink being exchanged during the printing process. In yet another alternative, the PCB production apparatus 100 will include the function head module 115c of FIG. 6e wherein two separate ink-printing mechanisms 120 may be automatically loaded and unloaded.

Referring to FIG. 9d, an embodiment of a process to print a PWB using the PCB production apparatus 100 starts with the first conductive trace operation 221 wherein the function head 115 is controlled to print the first conductive trace 501 on the substrate using conductive ink. Next, operation 222 controls the PCB production apparatus 100 to print insulating patch 504 using a non-conductive ink. Lastly, second conductive trace 502 is printed using a conductive ink in operation 224.

Referring to FIG. 10a, a first conductive trace 210 is representative of a first conductive layer as an output from a CAD tool, Gerber file or image file. The first conductive trace 210 is printed first on a substrate 214. A second conductive trace 211 is representative of a second conductive layer. The first conductive trace 210 and the second conductive trace 211 intersect, or overlap, at a conductive trace intersection 212. The conductive trace intersection 212 is calculated by the LTM 152, or if so configured, an external circuit layout tool. The PCB production apparatus 100 alternates printing of conductive ink for the conductive traces, 210 and 211 and non-conductive inks for the insulating geometry 213.

### Creating Layer Connections.

Referring to FIG. 10b, when electrical connection between a portion of first conductive layer 241 and second conductive layer 242, typically at a location where a via hole is found using the drill file and/or the Gerber files, an opening in insulating layer 242 is optionally printed by not printing insulating ink in this region as discussed below. In this way, when second conducting layer 243 is printed on top of insulating layer 242, electrical connection is optionally made between first conductive layer 241 and second conductive layer 242.

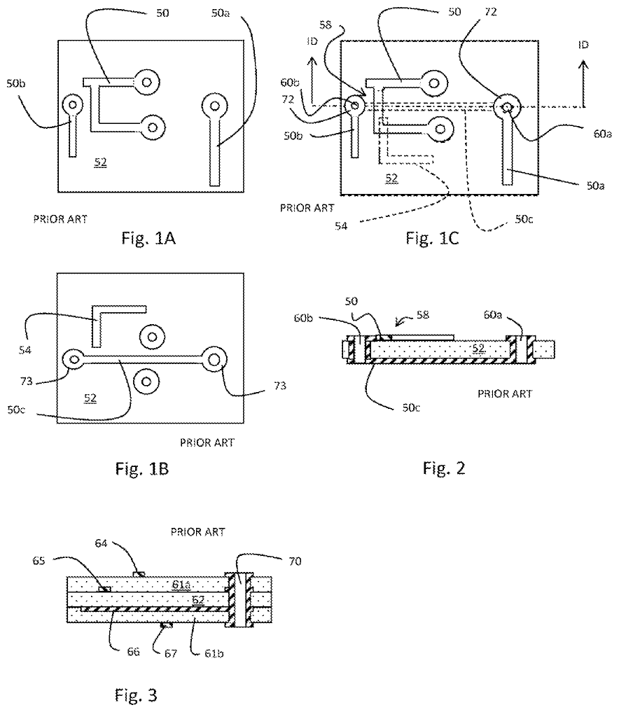

In printing two-layer and multi-layer PWBs using the PCB production apparatus 100, the need to print conductive connections between conductive traces arises. These connections replace the drilled vias, 60a and 60b, in a traditional PWB as described above in relation to FIG. 1c. In processing PCB files, the LTM 152 optionally creates a list of locations where conductive ink would overlap creating an electric connection between conductive traces of two or more conductive layers. CAD tools for layout of PCB's typically output a data file, referred as a drill file or Excellon drill file, that includes the two dimensional locations of holes that are used by the PCB manufacturer to create plated-through via holes. As shown in FIG. 1c, these vias are used to connect circuit features between multiple layers in a multilayer PCB. The LTM 152 optionally uses the data stored in the drill file to aid in the location of circuit connections where conductive ink is placed by the PCB production apparatus 100.

Typically optionally used by traditional PCB vendors, drilled via holes are often located at a center of a circular pad similar to the pads 72 of FIG. 1c. The individual pad information is contained in the PCB file for each conductive layer. For example, in the text file for Gerber extended 274X, a 0.1 inch diameter pad would be described using the following statements:
% ADD10C, 0.1*%
X0Y0D2*D10*G1X58333Y155833D3*X0Y0D2*M02*.
   For the first statement, AD is an aperture description, D10 is a circular aperture, C is a circle macro, 0.1 is a diameter of 0.1 inches. The second line lists a center of the pad at x=0.5833 inches and y=1.55833 inches. The information contained in this Gerber file is optionally compared to a second Gerber file and is optionally used to determine if two pads overlap and therefore should be connected in the final circuit without the need to examine the drill file. In addition, as drilled via holes are no longer required when printing conductive ink on a substrate using the PCB production apparatus 100, pad features are optionally eliminated or at least their diameters are optionally reduced during the layout process or after the layout process.

Referring to FIGS. 12a and 12b, a first conductive trace 230 which is included in a PCB file for one layer of a multilayered PWB is printed onto substrate 232. First conductive trace 230 includes a first conductive pad 231 (portion of outline shown in dashes). A second conductive trace 233 is from another PCB file for another conductive layer of the multilayered PWB. The second conductive trace 233 includes a second conductive pad 234. When examining the PCB files associated with these conductive layouts or when examining an electrical schematic for the intended circuit, or when examining the drill file, the LTM 152 first determines that the first conductive pad 231 is to make electrical contact to the second conductive pad 234, then the second conductive pad 234 is printed directly on top of the first conductive pad 231 as represented by the partial dashed outline of the first conductive pad 231.

Another method optionally effected by the LTM 152 is to combine the layouts of first conductive trace 230 and first conductive pad 231 and second conductive trace 233 and second conductive pad 234 into a combined conductive trace and print both sets of conductive geometries at the same time in which the layout would not need the conductive pads and a continuous configuration having the outline shown in FIG. 12b is produced.

Yet another method where there is no drill file but there is an image or a Gerber (or analogous type file) that shows the hole locations and the hole size the LTM is programmed to identify the location for the overlap between the two conductive layers. Another alternative operation includes the use of the pad geometries to not print the overlap area but instead print the diameter of the drill listed in the drill file. Although the total surface area printed between the two conductors is less using the drill file dimension, it suffices to provide and interconnection between layers.

In traditional multilayer PWB, a via hole is drilled through the entire stackup of conductive layers and substrates. To ensure the plating process adheres within the drilled hole, conductive circular pads are typically located on each conductive layer for each plated through hole to be drilled through thus allowing tolerance for the drilling alignment. In some traditional PWB applications, the via hole is only drilled through the layers that require direct electrical connection(s). These types of vias are called “blind-hole vias” and are typically more expensive to manufacture using traditional methods. Using the PCB production apparatus 100, printing the equivalent of a blind-hole via is easily created by only printing the electrical connection between those conductive traces. Using the PCB production apparatus 100, printing the equivalent of a blind-via would not add any additional cost to the printed PWB and is advantageous as it will reduce an amount of conductive ink that is to be printed by eliminating the typical circular pads, 231 and 234, from those layers that would have been used in a standard chemically etched PCB process. Instead, a configuration, as shown in FIG. 12b, results wherein the ends of the conductive traces, 231a and 234a, overlap to make a connection when the conductive traces, 230 and 233, cannot be printed in the same operation because of other overlapping contingencies which require the insulating geometry 213 of FIG. 10a.

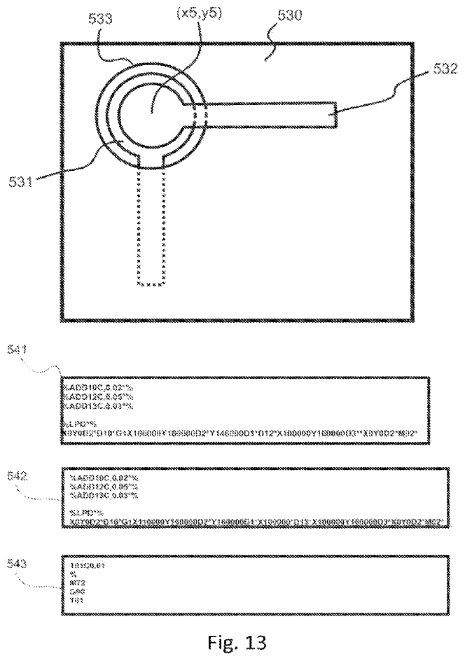

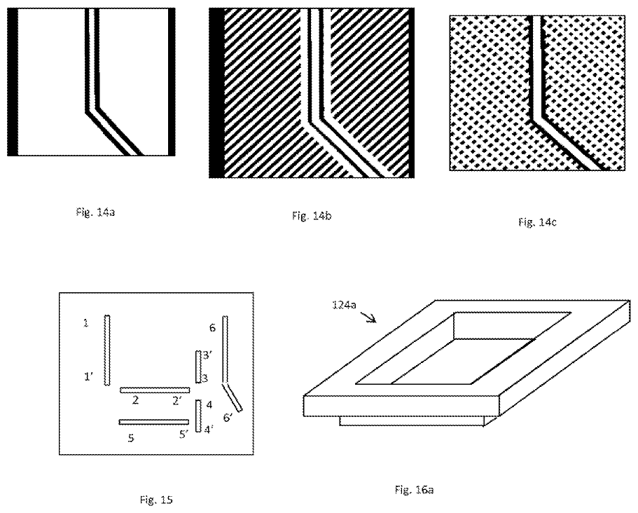

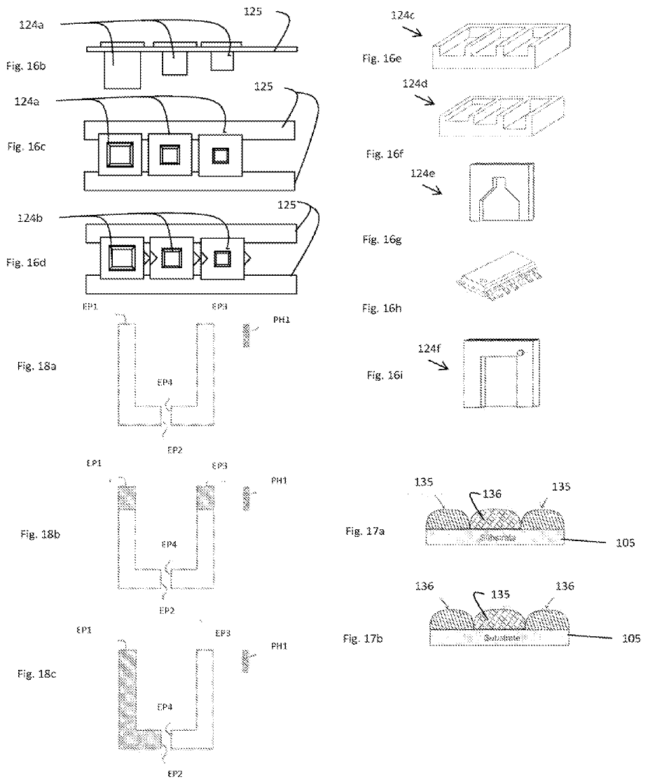

Software layout tools that generate Gerber files will also generate a drill file that contains information regarding plated-through-hole via connections between layers. Apparatus may use information in the drill file to determine the (x,y) locations where electrical connections are to be made and also where to create clearance holes in a non-conductive layer to allow these connections. Referring to FIG. 13, first conductive trace 531 is to connect to second conductive trace 532. The layout information of first conductive trace 531 is contained in a first Gerber file 541. The layout information for second conductive trace 532 is contained in second Gerber file 542. The via hole information, including center location (x5,y5), is contained in Drill File 543.

When printing conductive and non-conductive inks in order to connect first conductive trace 531 to second conductive trace 532 only on the area of via hole center (x5,y5), the process begins by identifying the (x5,y5) location of via hole using the drill file associated with the PWB. The second operation is to print first conductive trace 531.

The third operation in the process is to print insulating patch 530. Insulating patch 530 includes first clearance hole 533 which exposes a portion of first conductive trace 531 in the area of via hole center (x5,y5). Insulating patch 530 is optionally designed to cover all other conductive traces associated with the layer containing first conductive trace 531 or only a portion of other conductive traces associated with the layer containing first conductive traces. Alternatively, insulating patch 530 may contain other clearance holes associated with other connections between two conductive layers. Alternatively, insulating patch 530 can completely cover the substrate and all remaining conductive traces associated with the layer containing first conductive trace 531 with the exception of first clearance hole 533 which exposes a portion of first conductive trace 531 and any other clearance holes used to connect two layers.

The fourth operation in the process is to print second conductive trace 532 on top of insulating patch 530. As second conductive trace 532 overlaps first conductive trace 531 in the area of (x5, y5), there will be an electrical connection between first conductive trace 531 and second conductive trace 532. The diameter of first clearance hole 533 is optionally set to a nominal value determined automatically or entered by the operator. Alternatively, the diameter of first clearance hole 533 is optionally determined using pad diameter information contained in Gerber file 541 and/or Gerber file 542. In one case, the diameter of first clearance hole 533 will be set to the largest diameter of pad connected to first conductive trace 531 or second conductive trace 532. In another case, the diameter of first clearance hole 533 will be set to a diameter larger than the largest pad connected to first conductive trace 531 or second conductive trace 532. In this case, the diameter of first clearance hole 533 is optionally oversized to take up printing tolerances while still exposing the conductive ink associated with first conductive trace 531 and second conductive trace 532. Typically oversize diameters will be 10 mils larger than the largest pad connected to first conductive trace 531 or second conductive trace 532.

In an alternative embodiment of the PCB production apparatus 100, the LTM 152 of FIG. 7 is included within a CAD tool that produces the insulating patch with the required clearance hole. The CAD tool will output the geometry of the insulating patch as a data file including Gerber.

### Ink Conservation.

To conserve ink, the GERBER file information may be used to create a framework of the original circuit trace. In this case, the translation software may find the center line or an edge line to print the conductive ink. By examining the GERBER file, the start and end points of a conductive line are optionally determined and the printed line width is optionally optimized to reduce the overall cost of the printed circuit.

Another way to conserve ink it to create a mesh in areas that were originally specified as solid conductive regions. For example FIG. 14a shows a original GERBER file having two large areas of solid conductor on either side of the conductive line. When using a chemically etched or mechanically machined printed wiring board, it is relatively easy to leave these large conductive areas in place as the original printed wiring boards are completely clad in copper. When printing conductive inks onto a substrate, it is faster and more economical to reduce the amount of ink printed onto the substrate. In this case, the LTM 152 will identify these large conductive regions and create a mesh that will be printed as a substitute. FIGS. 14b and 14c show two mesh equivalents that will be printed with conductive ink. It is important to note the configurations shown in FIGS. 14b and 14c, are not the only possible mesh configurations as there are numerous configurations that will provide the electrical equivalent to a solid conductor. In an alternative embodiment of the PCB production apparatus 100, the LTM 152 of FIG. 7 is included within a CAD tool that produces the mesh. The CAD tool will output the geometry of the mesh as a data file including Gerber.

### Printing Order.

When printing inks, the function head 115 including the ink-printing mechanism 120 must move around the substrate under the control of the apparatus firmware. The LTM 152 analyzes the PCB file to create a configuration which is effective to move the function head with the minimum travel path. For example, FIG. 15 shows a typical circuit layout have 6 individual lines that need to be printed. The original PCB file may include the physical locations for endpoints of these lines but may not have listed the lines in an optimized order for printing using the ink-printing mechanism 120. The LTM 152 re-orders the lines to increase printing speed and decrease the total travel path for two or more lines. In one optional configuration, the LTM 152 will group endpoints with the nearest proximity. For example, FIG. 15 shows the six lines with endpoints labeled. For example, line 1 has endpoints 1 and F. The LTM 152 groups 1′ and 2 as being physically near each other. This group may also include endpoint 5. Another grouping may include endpoints 2′, 3 and 4. Another group may include 4′ and 5′. Movement of the ink-printing mechanism 120 will be controlled by an optimized ordering of the endpoints. For example, assume that the last position of the ink-printing 120 is near endpoint 1. One solution is to begin by printing line 1-1′, then 2-2′, then 3-3′, then 4-4′ then 5′-5. The LTM 152 optionally uses the length and angle of the individual lines to minimize the total path traveled. The LTM 152 optionally optimizes the traveled path with relation to acceleration of the ink-printing mechanism 120 that is optionally used. The optimized travel path is not limited to the ones discussed here as there are other algorithm that is optionally used to optimize the travel path. For example, the optimization may include the starting point or “home” location of the ink-printing mechanism 120. A similar optimization process may be used for the epoxy-printing mechanism 130, pick-and-place mechanism 140 and protective-ink mechanism 120. A different ordering and path optimization is optionally used for each mechanism, 120, 130, or 140. For example, the pick-and-place mechanism 140 requires that the mechanism 140 moves to a known location to pick up the components to be placed. In this case, the optimized travel path may be different than the other mechanisms as the mechanism 140 will need to be returned to the component feed mechanism 122 for picking up the individual components.

### Component Placement Order.

In the PCB production apparatus 100 that optionally includes a pick and place function, the function head 115 would include the pick-and-place mechanism 140. In one configuration, the pick-and-place mechanism 140 includes a vacuum pickup, vacuum tip, and/or suction cup, for temporarily holding an electrical component while the component is positioned onto the substrate. The pick-and-place mechanism 140, either in part or whole, may be detachable from the function head 115 in order to share common components with the ink-printing mechanism(s) 120. In the preferred configuration, the pick-and-place mechanism 140 is located adjacent to the printing mechanism(s). The function head 115 optionally has a rotation motor 116 to rotate the pick-and-place mechanism 140 or the pick-and-place mechanism 140 includes the rotation motor 116 to implement a rotation feature to properly position the electrical component onto the substrate 105. The minimum rotation capability would be 0-degrees and 90-degrees but other rotation angles may be possible. In one embodiment, or the function head 115 has the rotation motor 116 arranged to rotate the electrical component prior to placement on the substrate. Another embodiment has the rotation motor 116 arranged to rotate the entire function head module 115a.

The function head module 115b optionally includes a motor, a solenoid, field coil or other controllable actuator, or multiples thereof, set a distance between a selected one of the mechanisms 120, 130, or 140, and the table 104. For example, a solenoid may be used to lower a height of the ink-printing-mechanism 120 such that the insulator-printing mechanism 120′, pick-and-place mechanism 140 and epoxy-printing mechanism 130, will maintain a larger distance to the surface of the table 104.

### Heater.

The printing table 104 optionally includes the heater 118 embodied as a heating element to elevate the temperature of the substrate 105 in order to accelerate curing of inks and epoxies. For example, the Novacentrix HPS-021LV has a cure time of 30 minutes when the ink is held at 125 degrees-C. The apparatus-firmware would control the heating element in the printing table. The temperature control optionally employs a temperature sensor 118s which is monitored by the controller 95 for effecting correct curing of epoxies and inks

### Ink-Flow Sensor.

An ink-flow sensor 119 is optionally used to measure when the ink has begun to flow and has reached the substrate. The sensor 119 is optionally optically-based or measurement based. In an embodiment, a measurement based sensor 119 measures a resistance and/or capacitance between an ink dispensing tip and the substrate 105. For example, the dispensing tip is optionally metallic and with a sensor connected between the tip and the substrate, a relative change in the resistance and/or capacitance is measured with and without ink flowing between the tip and the substrate.

### Component Placement.

The pick-and-place mechanism 140 is optionally integrated in the PCB production apparatus 100 and operates in conjunction with a component feed mechanism 122. Referring to FIG. 4, the component feed system optionally includes a “tape and reel” strip mechanism 122a. The strips often contain a set of equally-spaced holes along the side of the tape for locating the components and pulling, or pushing, the tape into the apparatus.

Referring to FIGS. 16a-16h, an alternate configuration for the component feed mechanism 122 is a tray system 122b wherein electrical components are held in a component tray and components are manually loaded into a tray or slot and the components are picked up by the pick-and-place mechanism 140 for placement onto the substrate 105. When using a tray system, the components are optionally ejected or dropped from a hole or slot located at the bottom or side of the tray. The hole or slot location is pre-determined so the pick-and-place mechanism 140 has knowledge of the component location for picking up the component. The tray system 122b may include individual trays containing a cavity or hole that is sized to the electrical component. The individual trays have an outer dimension that is common.

Referring to FIG. 16a, an example of a component tray 124a is shown. The tray material is optionally plastic, metal or any other suitable material that can support holding the component in place. It is expected that the tray has a bottom for holding the components. The bottom could be closed or have an opening that could aid in locating the tray within the apparatus. The depth of the component tray 124a is approximately equal to the height of the component. This would allow the top of all the components to be located at approximately the same position when placed within the apparatus making it easier for the pick-and-place mechanism 140 to pick up the component. The top hole opening in the component tray 124a would correspond to the size of the component. The individual component trays 124a would be inserted into the apparatus along a tray support frame 125 as shown in FIGS. 16b-16d. The spacing between rails of the tray support frame 125 is approximately equal to the tray width. A lip or edge may be included as part of the tray support to properly position the tray along the center of the tray support frame 125. The centers of the trays 124a will be known to the apparatus so that the pick-and-place mechanism 140 can pick up a component. The tray or trays 124a may be fed into the apparatus as part of the feed-mechanism.

In another configuration, a tray or trays 124a have a location that is fixed once the trays are inserted into the apparatus. In another configuration, a tray 124a may be ejected from the component feed mechanism 122 once the component is removed from the tray 124a. In this configuration a next tray 124a is optionally moved into the location of the tray 124a that was previously ejected. This configuration allows the pick-and-place mechanism 140 the option to pick up components in the same location. FIG. 16d shows a configuration for trays 124b which include a key arrangement. The key is an interlocking mechanism for aligning the trays 124b along the tray support 125. The trays, 124a or 124b, are optionally interconnected prior to placement into the apparatus.

Referring to FIGS. 16e and 16f, in an alternative configuration may have the trays be assembled as one part as a multi-cavity tray, 124c and 124d. This allows the components of a specific circuit to be pre-assembled and inserted as one common unit into the component feed mechanism 122. The trays are optionally held in place with a spring loaded mechanism similar to a desk stapler wherein a spring loaded mechanism pushes the trays to the front of the component feed mechanism 122, for example, a front of the tray support frame.

Referring to FIG. 16e, the multi-cavity tray 124c includes several elevated walls creating separate compartments to place individual components or groups of components. The example of the multi-cavity tray 124c shown has three compartments but may include more or fewer compartments. The compartments may be of equal size or are optionally sized to accommodate the variety of different package sizes of modern electronic components including resistors, capacitors, diodes, transistors and integrated circuits to name a few. FIG. 16f shows a multi-cavity tray 124d wherein heights are made unequal to accommodate differences in heights of various parts. For example, the height of a 0603 surface mount resistor would be 0.45 mm and the height of a 1206 resistor would be 0.6 mm. The compartment height may be optimized for manual insertion of the components by sizing the heights to fit the component height relative to the operator's finger sliding the part into the compartment. In one example, it may be easier to slide the component into a corner when the compartment height is slightly lower than a top surface of the multi-cavity tray, 124c or 124d.

In contrast to tray 124a, the multi-cavity tray, 124c or 124d, optionally has one or more sides open to aid the operator in placing the parts into the multi-cavity trays, 124c or 124d, which are shown as having one open side for exemplary purposes and are not so limited. The operator may manually place a part into the multi-cavity trays, 124c or 124d, and slide the component into a corner of the multi-cavity trays, 124c or 124d. Based on a location of a corner of tray 124a, or if more than one compartment, corners of the tray, 124c or 124d, the CMCM 127 is able to position the pick-and-place mechanism 140 near an appropriate corner in order to pick up the component. The operator may enter a location of each component into a table displayed on a computer screen or other visual interface device. The preferred location of the component on the tray is optionally determined by the CMCM 127. In this case, the CMCM 127 will display one or more of component identification, the associated compartment location, component orientation, and compartment corner for positioning the component. When guided by CMCM 127, there may be an ideal tray location for each part which improves the speed of the pick-and-place operation. For example, if the printed circuit includes a resistor located in the bottom region of the circuit and a capacitor in the upper region of the circuit, the ideal location for the resistor would be at the lower portion of the tray and the capacitor at the upper region of the tray. In this way, the movement of the pick-and-place mechanism 140 is controlled to reduce a total length of movement.

Referring to FIG. 16f, a tray 124e may also include a guide that allows a more accurate alignment of the component as it is pushed into the compartment. An example of the tray 124e is shown and has a channelized compartment that becomes narrower near the top. If a component is placed into the compartment at the bottom and then pushed up, either by a finger or other automated device, as the part moves up into the compartment, the component will be properly positioned at the top of the compartment. It is noted that an actual orientation of the tray 124e is in the horizontal plane, the discussion of compartment and tray configuration is relative to the figures of this document. It is understood that components come in a variety of sizes and shapes so it is expected that this channelized approach would not be able to accommodate all components. In this case, more than one channel is provided for the tray system.

In most integrated circuits having multiple pins, the package includes a marked feature to highlight the location of one of the pins, typically pin 1. FIG. 16h shows a typical package of an integrated circuit having 14 pins. Pin 1 is clearly marked with the “dot” located near pin designated as pin 1 for this package. Referring to FIG. 16i, an embodiment of a tray 124f includes a mark that indicates how the component should be loaded into the tray. For example and not limitation, the tray 124f includes a “dot” to be used to properly locate the associated “dot” on the package of the integrated circuit. The operator is optionally guided by the CMCM 127 as to how the component should be positioned in the tray. This is optionally provided by the aid of a graphical image or a text based description of the component location on the display.

For components with two terminals, such as diodes, the “dot” convention is typically not used. In this case, components manufacturers rely on a variety of different marking schemes to describe the direction of current flow from anode to cathode. When placing this type of device onto a tray, an identifiable mark is optionally placed on the tray to aid the operator as to the proper orientation for the component. One such mark is optionally a typical schematic symbol for a diode. The CMCM 127 may also provide a graphical image or text based description of the proper orientation for the component when placed in the tray.

To eliminate the need for accurately placing a component into a tray for pickup by the pick-and-place mechanism 140, or when improved accuracy is needed when placing a component onto a substrate, optionally provided is the imaging device 108, such as a camera, for providing the CMCM 127 with a method to “visually” identify a components orientation and offset in order to rotate the component prior to placement onto the substrate 105 or to offset the component when placing the component on the substrate 105. The imaging device 108 is optionally located above, below or to the side of the component in the tray. The imaging device 108 is optionally located separate from the tray and the pick-and-place mechanism 140 will pick up the component from the tray and then move the component into the visual field of the imaging device 108. In this case, the imaging device 108 is optionally located above, below or to the side of the component as the pick-and-place mechanism 140 moves the component into the field of view of the imaging device 108.

An embodiment of PCB production apparatus 100 has a camera system as the imaging device 108 placed adjacent to the tray pointing upward. The pick-and-place mechanism 140 picks up the component from the tray and move the component over a camera lens. The camera image is passed to an algorithm to detect edges and/or a center of the component. Any rotation of the component relative to a desired position on the substrate 105 is corrected to within a given tolerance by the PCB production apparatus 100 prior to placement on the substrate 105. The pick-and-place mechanism 140 is optionally capable of rotating the component as discussed herein with regard to the rotation motor 116. In an advantageous embodiment, the pick-and-place mechanism 140 can rotate the part by at least 90 degrees. More preferably the pick-and-place mechanism 140 can rotate the part by at least 180 degrees. Even more preferably the pick-and-place mechanism 140 can rotate the component over a 360 degree angle. The camera is optionally any relatively low cost camera such as the LinkSprite JPEG 2MP Color Camera. As most cameras have a long focal point, a macro lens is optionally placed over the lens of the camera system in order to be able to focus the camera on the component which can be fairly close to the imaging system.

In another embodiment of the present disclosure, the operator manually places components onto the tray and then the pick-and-place mechanism 140 picks up the components and moves them to a separate location or “holding area” for temporary storage until they can be placed on the substrate 105 at a later time. One benefit to this action is that the operator may place all the necessary components into the apparatus during one step in the total print and assembly process. For example, by placing all the components into the PCB production apparatus 100 during the initial phase of the operation, all printing and component assembly can occur without any further intervention by the operator. Another benefit for the implementation of a holding area is to reduce the complexity of the tray system which optionally allows for a tray with a single compartment. Another benefit to the holding location is that a tape-and-reel system is optionally added to PCB production apparatus 100 where the tape and reel system only requires a single reel handling mechanism.

For the pick-and-place mechanism 140, the LTM 152 may also create a list of an order for which the components would be placed onto the substrate. The list may be provided to the operator prior to inserting the components into the PCB production apparatus 100. In this way the components may be inserted in the optimized order for facilitating the pick and place process. As another option would allow the operator to enter a list of components in an order in which the operator inserted the components into the PCB production apparatus 100. The component mounting control module (CMCM) 127, implemented by the controller 95 and shown in FIG. 7, uses this list and the information provided by the LTM 152 to pick up the components. The CMCM 127, based on the location and order of the components loaded into the apparatus, optionally optimizes an order in which to pick up the components to improve throughput of the pick-and-place process. Another option is to provide an electronic file that contains an order of the components based on a pre-determined order. For example, if the components are assembled into a tray or other holding mechanism, the order of the components in the tray is optionally contained in a electronic file which is optionally used by the CMCM 127. The optimization algorithm of the pick-and-place process is optionally embodied in the LTM 152 or the CMCM 127.

### One Layer Component Positioning.

In a standard PCB process using two or more conductive layers, it is possible to place and solder components to the outermost two layers on the PWB. As there is at least one insulating layer between these conductive layers, components are placed at or near the same (x,y) coordinates so there could be a some amount of overlap between the components without interfering with each other. When using PCB production apparatus 100, all components are placed on one layer of the substrate. For PCB production apparatus 100, the components are on one side and must be properly positioned so there is not overlap between the components and their respective pads.

Referring to FIG. 21, first component 520 having at least one first connection pad 521 and second component 522 having at least one second connection pad 523 and third component 524 having at least one third connection pad 525 are positioned so there is no overlap between components and pads. Not shown in FIG. 21 are leads coming from first component 520 and second component 522 that lay on top of the pads. In one method embodiment, the LTM 152 locates the connection pads of all components on the conductor layer that is printed directly on the substrate as this will guarantee the component leads will have a flat and uniform surface during the pick-and-place operation of PCB production apparatus 100. The LTM 152 functions to avoid other conductive traces and insulating layers interfering with properly positioning the component leads on the connection pads during the pick-and-place operation.

In an embodiment of the LTM 152, conductive traces are positioned to run under the components and these conductive traces will be printed on the same conductive layer as the connection pads. In cases where it is expected that the PWB will exposed to the environment, the LTM 152 will automatically create a PCB file, for example and not limitation, a Gerber file, that will include a non-conductive pad to completely cover the conductive line that is printed under the component so that the conductive line will not oxidize when exposed to the environment. The components and associated connection pads are spaced far enough apart so there is no overlap while also providing space for connecting conductive traces. For example, spacing connection pads by at least 30 mils will allow at least one conductive trace to be routed between two components assuming that a printed conductive trace has a minimum width of 10 mils and the spacing between conductive elements is a minimum of 10 mils on either side of a conductive line. The LTM 152 follows guidelines set for component spacing which may include using a default or operator-generated value for the component spacing.

In an alternative embodiment of the PCB production apparatus 100, the LTM 152 of FIG. 7 is included within a CAD tool that produces the layout with the required spacing for the conductive traces and pads. The CAD tool will output the geometry of the conductive layer as a data file including Gerber.

### Extruder.

PCB production apparatus 100 optionally includes a plastic-extruder 123 for printing a plastic housing over the substrate. In one configuration, the plastic-extruder 123 is part of the function head 115. The plastic-extruder 123 is similar to 3-D printers available on the commercial market. The plastic-extruder 123 is optionally used to fabricate the substrate on which the conductive traces and components are placed. Printing the substrate allows for a variety of complex three dimensional shapes to be fabricated and also provides a more accurate placement of the components and printing the conductive and non-conductive traces as the same apparatus head is used for all types of material printing.

The outer surface of a complex three dimensional shape or form can be modeled and included as part of the printing and assembly process. The surface model would be used to position the ink-printing mechanism over the substrate. The surface model can be an electronic file that is used by the LTM for the printing and assembly process. The PCB production apparatus 100 may include an integrated surface scanner or digitizer, referred here as the surface-scanner, used to measure the three dimensional substrate and/or three dimensional substrate-form in order to create a model of the surface contour for any three dimensional object.

### Protective Coating.

PCB production apparatus 100 may also have a mechanism for printing a protective coating over the surface of the circuit. In some applications, it may be important to protect the surface from scratches. In this case, a protective-ink mechanism 120 is included in PCB production apparatus 100, and may be part of the function head 115. Some protective coatings, such as the commercially available “Humiseal”, can provide a conformal coating and shield against moisture, humidity and chemicals. These coating materials may be of type acrylic, polyurethane, silicone to name a few.

### Camera.

PCB production apparatus 100 optionally includes the imaging device 108 embodied as a camera for identifying to orientation of components used during the pick-and-place process. For example, there may be a slight rotation of the parts in the component holder and when the pick-and-place mechanism 140 picks up the component, the camera is optionally used by the CMCM 127 to identify if the component is properly positioned for placement onto the substrate.

### Conductive Substrate.

In addition to non-conductive substrates, the substrate material is optionally electrically conductive, semiconductive or metallic. When using these types of conductive or partially conductive substrates, the PCM 128 would first print a layer of insulating ink prior to printing the electrically conductive circuit traces using conductive ink. Substrates that are metallic and electrically conductive are optionally used to improve the thermal dissipation of high power electrical components and assemblies such as high power transistors and light emitting diode (LEDs). Printing a thin insulating layer between the electrically conductive circuit traces and the substrate may substantially improve the thermal performance of the circuit where excessive heat generated by the electrical components is transmitted through the thin layer of insulating material to the metallic substrate and dissipated away from the components. The technique of printing a thin layer of insulation ink over a metallic substrate would also be useful in applications that do not require high thermal dissipation but optionally uses a high strength substrate.

### Substrate Positioning.

As discussed above, the PCB production apparatus 100 optionally includes a substrate-positioning/holding mechanism (SPHM) 121 to aid the operator in properly positioning the substrate 105 onto the printing table. The SPHM 121 may be a simple cross hair or grid located across the surface of the printing table. The SPHM 121 may be a raised edge or a combination of raised edges in which the operator can push the substrate 105 into the proper location known to the PCB production apparatus 100. The SPHM 121 may be useful to identify a common point for the PCB production apparatus 100 to use as an absolute reference to the circuit geometries that will be printed. The SPHM 121 is optionally removable and placed within the PCB production apparatus 100 once the substrate 105 is properly positioned. The SPHM 121 is optionally an optical-based or sensor-based sub-system to automatically locate edges of the substrate 105 once the substrate 105 is placed on the printing table. In this case, the position of the substrate 105 is optionally arbitrary and the PCB production apparatus 100 will automatically locate the substrate 105 on the printing table.

The PCB production apparatus 100 may include the SPHM 121 to temporarily hold the substrate 105 in place during the printing and assembly process. The substrate-holding mechanism 121 is optionally clips, weights or any object capable of temporarily holding the substrate 105 in position. The substrate-holding mechanism 121 may be a vacuum based sub-system which is optionally activated once the substrate 105 is properly positioned onto the printing table.

Substrates are not limited to planar, or flat, geometries. The substrate 105 can also be any three dimensional object which would support the conductive ink and/or associated circuit components. Any complex surface geometry is modeled and included as part of the printing and assembly process. The surface model would be used to position the ink-printing 120 over the substrate 105. PCB production apparatus 100 may include an integrated scanner or digitizer, referred to herein as the surface-scanner as one of the imaging devices 108, which is used to measure the three dimensional substrate 105 and/or three dimensional substrate-form in order to create a model of the surface contour for any three dimensional object.

### Conductive Ink Printing Using Channels.

When printing conductive inks using the ink printing mechanism 120 embodied as a syringe, inkjet, piezoelectric or other means of dispensing conductive inks onto a substrate 105, it may be desired to layer the ink in order to build up enough cross section for use in circuit applications requiring high electrical current. In order to constrain conductive traces to a narrow width while providing a thickness to the total cross section of the printed conductive line, an initial printing process using non-conductive inks provide support during the layering of the conductive ink. Referring to FIG. 17a, the support process begins with the PCM 128 printing non-conductive material 135 on one (not shown) or both sides of a conductive circuit line 136 which is next printed. The non-conductive material 135 creates a channel for conductive ink 136. Referring to FIG. 17b, printing non-conductive material 135 is useful when two conductive lines 136 are in close proximity and the non-conductive material 135 prevents an electrical connection, or “bridge”, from occurring between the two conductive lines 136. The process for FIGS. 17b implemented by the PCM 128 optionally starts with printing one conductive line 136, then the non-conductive material 135, then the second conductive line 136. The process in FIG. 17b could also start with printing the non-conductive material 135 first, and then by printing the two conductive lines 136.

Conductive Ink Printing without Drying the Print Surface.

When printing conductive inks using techniques such as syringe printing, inkjet printing, piezoelectric printing and others, it is important that the ink is not allowed to dry at or near the interface where the ink leaves the printing mechanism and the air. Often, a printing process pf the PCM 128 moves enough material to prevent clogging of the printing mechanism 120 or epoxy printing mechanism 130 but in applications where the printing mechanisms, 120 or 130, must move across a large distance, it is possible that the ink may dry at the air interface. One way to prevent drying would be to temporarily cover or cap the printing mechanism, 120 or 130 until the mechanism is at or near the desired printing site. Another technique would be to have a wiping mechanism that wipes a surface of the printing mechanism, 120 or 130, and removes dried ink from the printing mechanism, 120 or 130. The wiping action could include a moist surface to wet the dried ink enough to become fluid. It is known that many conductive inks, including silver nanoparticle inks, are water based. In this case wiping the printing mechanism, 120 or 130, with a damp sponge, cloth or other material prevents the printing mechanism, 120 or 130, from becoming permanently clogged. Thus, an embodiment of the PCB production apparatus 100 optionally has a clog prevention device 138 including one, or both, of a wiping mechanism or capping mechanism, which is controlled by the PCM 128.

Another embodiment of a method optionally employed to prevent the printing mechanism 120 from becoming clogged and implemented by the PCM 128 is to reduce the time between printing and not printing. In this case, the conductive traces are optionally printed in a preferred sequence in order to minimize the time when the printing mechanism is not printing. In a typical application, the printing mechanism's printing surface may have a dimension less than the circuit line dimension thus requiring the printing mechanism 120 to make several passes over the circuit in order to complete the circuit. For example, FIG. 18a shows a circuit with two lines having vertical and horizontal sections of lines. The left line has end points EP1 and EP2. The right line has end points EP3 and EP4. For this example, assume that the printing mechanism 120 is an inkjet cartridge with a set of holes arranged in a linear column. The holes eject droplets of ink under the control of the PCM 128. FIG. 18a shows an example of the set of holes PH1. There are numerous options for printing the lines including printing across the horizontal or printing in the vertical. FIG. 18b shows an example of horizontal printing where the printing mechanism 120 is moved horizontally across the substrate 105 and prints ink only where conductive traces are desired. In this case, the shaded areas near end points EP1 and EP3 show the ink deposited from the first pass of the printing mechanism 120 across the substrate 105. In this example, the printing mechanism 120 is moving from left to right, a top portion of line EP1-EP2 would be printed first and as the printing mechanism continues along the horizontal path, the top portion of line EP3-EP4 would be printed next. To continue the printing process, the printing mechanism would be moved down the line and the process would repeat either moving the printing mechanism from right to left, reversing the printing direction, or returning the printing mechanism 120 to the left side and repeating the printing process as before.

If the horizontal spacing between the upper ends of lines EP1-EP2 and EP4-EP4 are too far enough apart, it may be possible that the ink would dry on the surface of the printing mechanism 120 creating a condition of clogging the holes in the printing. It would then be difficult to print the top of line EP3-EP4. In this case it may be optionally used to wipe the surface of the printing mechanism 120 prior to printing line EP3-EP4 or cover the printing mechanism 120 between the printing of line EP1-EP2 and line EP3-EP4 using the clog prevention device 138.

An embodiment of a method of printing directed to address ink drying examines the circuit and prints the circuit in a path that minimizes dead time between activating the printing mechanism 120. For example, FIG. 18c shows a shaded area of completely printing line EP1-EP2 before moving to line EP3-EP4. In this case, the spacing between end points EP2 and EP4 is much closer in distance than the spacing between end points EP land EP3 which would result in a less likely chance that ink on a surface of the printing mechanism 120 dries and clogs the printing mechanism 120. Optimal line spacing is very dependent on a speed of the printing mechanism 120 as it moves across the substrate 105. This spacing is dependent on an amount of ink that is ejected from the printing mechanism 120. This line spacing is dependent on the time it takes for the ink to dry at the printing mechanism 120. In a typical application using a commercially available C6602A inkjet printer cartridge filled with a silver conductive nanoparticle ink, it was determined that the distance between circuit features should be less than 0.25 inches. However, depending on the ink type and temperature, this distance is nominally in the range of 1.0 to 0.2 inches.

If the holes in the inkjet cartridge are spaced such that the deposited ink from one hole does not make contact to the deposited ink from an adjacent hole, one solution is an overlap process to offset the printing mechanism 120 equal to a distance less than a diameter of the hole in order to overlap the deposited ink between passes of the printing mechanism 120. This overlap process is optionally used in printing conductive ink, non-conductive ink and protective coatings. The overlap process is optionally used for printing processes requiring the deposition of an ink onto a substrate 105 using a syringe, inkjet, piezoelectric, spray or other inking process where the ink leaving a printing mechanism has a smaller dimension than a circuit feature.

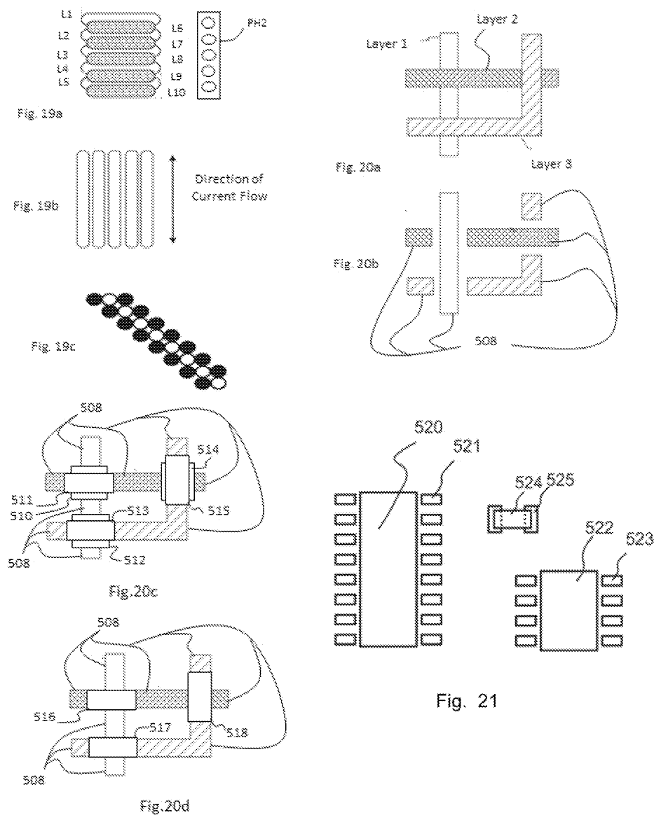

Referring to FIG. 19a, an printed ink pattern using an inkjet cartridge PH2 is illustrated. The unshaded lines L1-L5 depict the first pass of the printing mechanism 120 as it moves from left to right. In this case, the inkjet cartridge PH2 is activated by the PCM 128 as the printing mechanism 120 is moved across the substrate 105 releasing ink onto the substrate 105 producing five thin lines of ink labeled L1-L5. In this example, the inkjet cartridge PH2 includes five separate nozzles which are independently controlled. As the nozzles are spaced a distance apart, there are in this example gaps between the printed lines L1-L5 and gaps between lines L6-L10. The gaps must be filled in order to make connections between adjacent lines. In this process, the printing mechanism 120 is offset by a distance that is less than one diameter of the nozzles of the print head PH2. Lines L6-L10 (stippled) are printed using a second pass of the printing mechanism 120. This process is repeated until a complete circuit feature is produced. This process is optionally used by the PCM 128 for printing conductive traces when the print head PH2 would otherwise leave gaps. This process is optionally used by the PCM 128 for printing non-conductive regions when producing multi layered circuit boards or when a protective coating is optionally used to prevent surface damage to the printed lines or reduce the effects of environmental conditions such as moisture or heat.

In an one embodiment of the PCM 128, printing conductive traces in the direction of current flow in the final circuit is addressed. Following the discussion of FIG. 19a, the PCM 128 printing direction for lines EP1-EP5 and lines EP6-EP10 is in the direction of the current flow in the final circuit. This process reduces the amount of resistance of the circuit line. This process also improves the performance of high frequency RF circuits. FIG. 19b shows a line printed with a single pass of the printing mechanism having five nozzles in the inkjet cartridge PH2. This line is printed along the direction of current flow. In this example, a second pass of the printing mechanism 120 is optionally used to fill in the gaps left by the nozzles.

To provide the flexibility to print along the direction of current flow, the printing mechanism 120 is rotated by the print head rotation device 129, or the rotation motor 116 rotating the function head 115, in order to align a nozzle plane to be perpendicular to the direction of current by the PCM 128. Alternatively, the printing mechanism 120 remains fixed and the substrate 105 is rotated by the table 104 being rotated by the table rotator 139, shown in FIGS. 4 and 5B, under control of the PCM 128. Rotation of the printing mechanism 120 would not be required in this scenario. Furthermore, using a printing mechanism 120 with a single nozzle, such as in syringe printing or other piezoelectric systems, would obviate the need for gap filling needed in the case of the print head PH2.

### Diagonal Lines.

The PCM 128 controls printing diagonal conductive traces optionally uses a process to ensure that the resistance of the line is below an acceptable level. Printing diagonal conductive traces using any process that ejects ink from a small diameter hole or nozzle, may create limited connections or gaps between the printed dots on the substrate 105. For example, FIG. 19c shows a diagonal line created with a set of printed dots. The unshaded dots are the results of printing a line based on parameters entered by operator or from a conventional PCB file or equivalent database. If the requested line is fairly thin, the dots may not make adequate connection between the adjacent neighbors, as shown by the unshaded dots in FIG. 19c. In this case, the LTM 152 optionally determines that extra dots are required and the PCM 128 prints the dots during the printing process as shown by the shaded dots. Additionally, rotating the printing mechanism 120 or the substrate 105 may lower the resistance when printing diagonal conductive traces as the line may be printed in the direction of the current flow in the final circuit.

### Epoxy.

In an embodiment of the present disclosure, component attachment uses deposition of an electrically conductive epoxy or other electrically conductive glue by the PCM 128. Types of conductive epoxy used, for example and not limitation, are MG Chemicals 8331S and Creative Materials 111-29. The printing of epoxy may be performed with a variety techniques including syringe printing, piezoelectric or other types of printing mechanisms. The location for epoxy deposition requires the identification of component pads by the LTM 152. One technique for locating the epoxy deposition is for the LTM 152 to use information contained in a standard PCB file (GERBER file) for a solder mask. The solder mask file provides the location and pad size used when performing a standard soldering operation for the components. This same file is optionally used for the epoxy printing.

Another method for obtaining the location for epoxy deposition may be accomplished by the LTM 152 using information about the components including the size and orientation of the component. For example, if a resistor of size 1206 is placed in a horizontal orientation, the package size and orientation is optionally used to determine the location of the epoxy deposition. This also includes an amount of epoxy optionally used for proper attachment. Additionally, the location for epoxy deposition is optionally determined by the LTM 152 using circuit features contained in the circuit file provided to the LTM 152. For example, conductive traces that end without connection typically require a connection to a component. These features are optionally used by the LTM 152 to produce instructions controlling the PCM 128 during the epoxy deposition process. As some epoxies are rated for a heat cure which often accelerates the curing process, the PCB production apparatus 100 is optionally equipped with a heater in the form of table heater 118. As some epoxies are rated for a UV cure, the PCB production apparatus 100 is optionally equipped with a UV heater 118a, shown in FIG. 4. The heaters are optionally controlled by the PCM 128 to automatically operate after deposition of the epoxy.

### Solder Paste.

The PCM 128 optionally implements deposition of solder paste by the techniques mentioned above for conductive epoxy. In one embodiment of the PCB production apparatus 100, solder paste is applied by the epoxy dispenser 130 to the printed circuit conductive traces prior to placement of the components. The solder paste would be applied using a syringe, piezoelectric or other printing mechanism. The application of solder paste to the substrate 105 uses either the ink printing mechanism 120 or the epoxy dispenser 130, developed for printing inks and epoxy. In another embodiment of the present disclosure, the PCB production apparatus 100 optionally uses a separate sub-system. As mentioned above, the PCB production apparatus 100 optionally includes an integrated heat source such as the UV heater 118a for effecting solder reflow.

It is optionally possible to apply the solder paste using a silk screen process where a solder mask is placed over the substrate 105, which includes the previously printed circuit features, and the solder is pulled across the solder mask to place the solder paste onto the conductive line. This process is fairly standard in the industry but is unique to a system that includes all the printing and attachment processes. The solder paste would be reflowed during a separate heating process of the substrate 105. As mentioned above, the PCB production apparatus 100 optionally includes an integrated heat source such as the UV heater 118a.

### Non-Conductive Epoxy.

The PCM 128 optionally implements a process for deposition of non-conductive epoxy. For example, when attaching large components or with applications requiring a flexible substrate 105, attachment of components using a non-conductive epoxy aids the component attachment to the substrate 105. In an embodiment of the process, the deposition of non-conductive epoxy is done before the deposition of conductive epoxy or solder paste. Alternately, the non-conductive epoxy is deposited after the deposition of the conductive material. In either case, the deposition of conductive and non-conductive epoxies and/solder onto the substrate 105 occurs prior to the placement of the one or more components onto the substrate 105.

### Multilayer Circuit Boards.

When printing a multilayered circuit, the process begins with two or more files containing the individual circuit conductive traces and features. These files are typical of a GERBER format but may be of any PCB file type that properly describes circuit features in each of the layers. In one embodiment of the LTM 152, the files are examined and the locations of the circuit crossovers are determined as discussed above. This identification process may be performed internal to the LTM 152 or external to the PCB production apparatus 100. Once locations of crossovers are identified, the LTM 152 optionally creates a new single layer circuit layout which combines all the circuit conductive traces and features from the layers with the exception of breaks or discontinuities at the location of the crossovers. This process may accelerate the printing process by producing a single layer board that is optionally printed in one pass of the printing mechanism. To produce the completed board, a secondary process of layering non-conductive and conductive layers only in the areas of the crossovers of cross-overs is implemented.

In a standard printed wiring board process, each layer is etched onto the surface of a laminated substrate. In this case the crossovers are electrically isolated by the non-conductive substrate material between the various layers. When creating a printed wiring board using a printing process as part of this disclosure, the various layers are compared and crossovers are identified. Once crossovers are identified, different layers are optionally combined into a single layer for printing. In this case, the crossover information is preserved and used during the secondary process.

Referring to FIGS. 20a-20d, an example of a layout for a three layer PCB circuit board is shown with each layer being depicted in different shading. For this example, the information for the three layers are optionally contained in three separate files or all contained in one or two files. The process involves the LTM 152 identifying the crossovers and creating a combined single layer equivalent for printing. In this case, FIG. 20b shows the combined circuit layout of the combined single layer 508 with three crossovers locations identified. This combined layout includes breaks in the circuit conductive traces where crossovers will be placed in a secondary process after printing the combined single layer 508. For this example, the line on PCB layer 1 is not changed. For this example, the line on PCB layer 2 is produced with break in an area of an intersection between layer 1 but remains continuous in an area of intersection with the line of PCB layer 3. For this example, the line on PCB layer 3 includes two breaks at intersections between the conductive traces in PCB layer 1 and PCB layer 2. The example shown on FIG. 20b is only one possible configuration out of many possible combinations for determining which conductive traces are to be implemented with breaks.

The next step is to reconnect the printed conductive traces that have a break. In one embodiment shown in FIG. 20c, an area of non-conductive ink 510, 512, or 514 is printed over each one of the conductive traces followed by a layer of conductive ink, embodied in connections 511, 513, or 515, connecting the conductive traces (formerly of layers 1, 2 and 3 of the multilayer PCB) across the breaks in the combined trace layer now printed. In another embodiment shown in FIG. 20d, a connecting component, 516, 517, or 518, is optionally glued or soldered across each break. The connection component includes a lower insulating layer and an optional upper conducting layer. In the former embodiment, the connection conductor layer shown in FIG. 20c is determined by the LTM 152 and printed by the PCM 128 connecting to the conducting lines of the combined single layer 508 printed on the board as shown in FIG. 20b. In the later embodiment, the connecting component, 516, 517, or 518, is optionally a standard commercially available component such as a resistor, capacitor, inductor or wire. In one embodiment, the connecting component is a 0.1 ohm surface mount resistor. In this case, the gap in the break is slightly smaller than the length of the resistor so terminals of the resistor will overlap the desired conductive traces and complete the connection between two segments. In one embodiment, a custom connecting component is optionally used to connect the two conductive traces. In one embodiment, the connecting component is designed with geometry suitable for the pick-and-place mechanism 140. In one case, the connecting component has two electrically conducting terminals for connecting the printed conductive traces to the connecting component. In one embodiment, the connecting component may have a low resistance path between its two terminals. In one embodiment, the connecting component may be an electrical element which provides a means of connecting the two segments of the printed line and also provides an optionally used circuit function such as resistance, capacitance, and inductance.

### Printing Resistors Using Conductive Ink.

The process of printing conductive inks is optionally optimized to produce a line with a specified resistance. This technique not only produces an electrical connection between two points but also eliminates need to add a separate resistor to the printed circuit.

### Multiple Function Head Registration/Calibration

The function head 115 is optionally used during a calibration process to set to location of an absolute substrate or system position, i.e., table position. This location may be considered the (X, Y, Z)=(0, 0, 0) location or “home” location. Using a common function head 115, the calibration process may only need to be performed once for all inking, deposition, and pick-and-place functions. A Z-axis or vertical calibration is optionally performed periodically before and/or during the printing process or may be performed continuously by means of a sensor which monitors the top of the substrate and printed wiring board. The sensor may include a mechanical “feeler” or by optical means.

Referring to FIGS. 6a-6e, various embodiments of the function head 115 include function heads 115-1 through 115-3 which are directed to specific operations of ink printing, epoxy printing, and component placement. While function head 115-4 combines the aforesaid operation into one function head, use of function heads 115-1 through 115-3 involves interchange of the function heads in the process of producing a PCB. The interchange of function heads may introduce alignment offsets of point of operation of the various heads, the points of operation being where on the substrate ink, epoxy, solder paste or a component is deposited on the substrate 105. Additionally, the function head 115-4 having multiple functions incorporated therein may also require alignment of the points of operation. This may be necessitated by the function head 115-4 accepting replacements of the printing mechanism 120, the epoxy mechanism 130, or the component placement mechanism 140. While precision manufacturing of mechanisms 120, 130, and 140, optimally reduces changes in alignment, an alignment operation is optionally used to compensate for differences in the alignment of function heads.

Predefined built-in offsets for function heads are based on ideal mechanical dimensions of the printing mechanism 120, the epoxy mechanism 130, or the component placement mechanism. For example, the table 104 has an inherent zero position with relation to which operation points of the function heads are to be coordinated. The positioner 90 is optionally zeroed with respect to the inherent zero position such that the motors are operated to position the head mount 110 at a predetermined spatial relationship to the inherent zero position of the table 104. At this position, operating positions in each of the three axes of the positioner 90 are set to zero meaning that, when the controller 95 commands the positioner 95 to move to position 0, 0, 0, for example, it returns to the inherent zero position. This may be done either in the controller 95 as a final adjustment to commands or within the positioner 90.

Each of the function heads has an inherent built-in offset such that when the positioner actually moves the operation point of a given function head to the inherent origin, positions recognized by the positioner 90 and controller 95 will reflect the built-in offsets of the particular function head which will be called for clarity purposes, F1X, F1Y, and F1Z, wherein the designation F1 indicates the particular function head, i.e., function head “F1.” When the positioner 90 moves the operation point of the function head to the inherent origin, the controller 95 has directed the positioner to −F1X, −F1Y, and −F1Z. In operation, the controller 95 will make these adjustments in the final commands sent to the positioner 90 and the adjustments will be based on which function head is in use. Optionally, the function heads will include indicia which may be electronically or manually communicated to the controller 95 so that the controller 95 associates the particular function head with stored built-in offsets. This is optionally done by optically reading indicia on the function head using the imaging device 108, or electronically reading the indicia via any of hardwired, RF, such as for example and not limitation, an RFID tag, or infrared.

In practice, the actual built-in offsets will vary based on machining tolerances. If tolerances are wide enough in the particular application to producing a circuit board, use of the built-in offsets may be suffice an no further alignment is necessary. When tolerances are tighter, a calibration is done to effect accurate registration of the function heads with relation to either the substrate or the table.

An embodiment of an alignment method implemented by an alignment module (AM) 142 of the controller 95, shown in FIG. 7, includes operation of the printing mechanism 120 to print a registration mark on the substrate 105 which may be the object of production or may be a test substrate used for alignment. The location on the substrate will have some predefined offsets to the aforesaid zero position of the table which will be called “substrate offsets.” The registration mark marks what will be termed a “substrate zero position.” The substrate zero position is optionally the inherent origin or a substrate origin defined by substrate origin offsets from the inherent origin. For simplicity purposes in the following discussion, it is taken that the inherent origin and the substrate zero position are the same. It is to be understood that this need not be case and that substrate origin offsets are optionally used to compensate alignment when the inherent origin and the substrate origin are not the same in the following discussion in a manner as will be appreciated by those skilled in the art in light of this disclosure.

Once the registration mark is made by the printing mechanism 120, the epoxy mechanism 130 is next operated to print an epoxy dot at the registration mark made by the ink printing mechanism 120 based on predefined built-in relative offsets between the printing mechanism 120 and the epoxy mechanism 130 and the substrate offsets. However, variations of function head dimensions, and the various mechanism included in the function head, will invariably result in a misalignment of the epoxy dot with the registration mark. In an embodiment of the PCB production apparatus 100, the imaging device 108 is mounted so as to view the registration mark and is read by the alignment module 142 of the controller 95. The X and Y offsets are then determined from the image and stored as head component offsets which are added to the built-in relative offsets of the mechanisms 120, 130, or 140. Alternatively, the offsets may be manually entered and confirmed. In subsequent operations the head component offsets and built-in offsets are used to effect operations.

The component placement mechanism 140 is also calibrated in a similar procedure wherein a standard component or a dummy component is placed by the component placement mechanism 140 so a predefined point of the standard or dummy component is to align with the registration. Head component offsets of the predefined point from the registration mark are then determined and entered, either automatically or manually.

Another embodiment of the above registration mark does not require printing an initial registration mark using the printing mechanism. Instead, a feature on the substrate 105, for example a corner or an indicia on the substrate is used in place of the registration mark. Each of the printing mechanism 120, the epoxy mechanism 130, and the component placement mechanism 140 will have the operation point thereof positioned aligned with the feature. The operation point is optionally, for example and not limitation, a tip of a syringe of the epoxy printing mechanism 130, a tip of a suction nozzle of the component placement device 140, or a print jet orifice or an alignment mark or protrusion of the ink printing mechanism 120. When each of the operations points are aligned with the feature, a position reading of the positioner is taken. If alignment is perfect, all the position readings will be same. However, variations in alignment will result in the readings being different. Several calibration option exist.

A first option is to use a relative offset correction that corrects align of the function head module operation points with respect to each other. One of the readings taken when the operation point of a selected function head is aligned with the feature is taken as a base line with the head component offset being the raw position readings from the positioner 90. The reading selected functions as a baseline taken as 0, 0, 0, i.e., a base origin, and then store differences between the position readings of the other function head components and that of the selected baseline component as head component offsets to be applied in future operations. Operations are then conducted with the selected function head using 0, 0, 0, as a head component offset, and the differences are stored as the head component offsets of the other function head components. Thus, the relative positions of the function head components are compensated for variations in mechanical dimensions.

Another approach is to store the position readings taken when the alignment with the feature is in place as the head component offsets with respect to the zeroed head mount position. These readings are then used as the head component offsets for each head components. In this method, the head component offsets subsume the built-in offsets of the various head components.

When printing a multilayer PWB using conductive and non-conductive inks, it may be necessary to maintain a relatively flat surface across the entire top of the PWB. For example, FIG. 22a shows a cross section of a PWB 599 having a first non-conductive layer 600 printed across an area of the PWB 599, and first conductive layer 601 printed on top of a portion top of first non-conductive layer 600. To maintain a flat surface across this area of the PWB 599, a second non-conductive layer 602 is placed adjacent to conductive layer 601. The approximate height of the first conductive layer 601 and second non-conductive layer 602 would be predetermined in order to know if any of these layers were need to be overprinted to maintain and equal height between first conductive layer 601 and second non-conductive layer 602. If the apparatus 100 uses a similar process for printing conductive layers and non-conductive layers, such both using piezoelectric printing, it would be expected that printing these layers would require the same number of layers to maintain the same height. If the apparatus 100 uses a different process for printing conductive layers and non-conductive layers, such as one using piezoelectric printing and one using syringe printing, it would be expected that printing these layers would require a different number of layers to maintain the same height.

When printing a non-conductive layer between two conductive layers in order to isolate the two conductive layers from making electrical contact, it may be necessary to over print non-conductive layer to guarantee that the non-conductive layer completely covers the first conductive layer or to increase the non-conductive layer height to a functional height required by the circuit. Keeping a count of the number of non-conductive layers printed would be necessary to calculate the approximate thickness of the total non-conductive layer. For example, FIG. 22b shows a cross section the first conductive layer 603 which has printed two non-conductive layers 604 and 605 which includes a gap that allows two conductive layers 609 and 610 to be printed in the gap. For this example, the approximate height of non-conductive layers 604 and 605 and conductive layers 609 and 610 are similar so only two layers for each material is required to maintain a flat surface for printing the next layer. In FIG. 22b, the top layer is conductive layer 608 but could also be another type of material such as a non-conductive layer, epoxy, solder paste, protective coating or electrical component. For example, if the layer thickness for non-conductive layers 604 and 605 is 4 microns, then printing conductive layer 609 and 610 with an approximate 4 microns would create a relatively flat surface across the top. In the preferred method, intermediate curing of each printed layer and layer type improves the accuracies of the printed feature characteristics. Curing of the printed conductive and non-conductive inks can be accomplished with air-drying, applied heat and/or applied UV light depending on the requirements for processing the ink. In one case, both conductive and non-conductive would require heat curing. In another combination, the conductive ink would require air-drying and the non-conductive ink would require UV curing. Other combinations are possible and all combinations will not be listed here but knowing that the ink properties determine the type of curing and different combinations are possible with the apparatus 100. Also noting, that it would be possible to apply at least two types of curing methods simultaneously to facilitate rapid curing of combinations of conductive and non-conductive inks, epoxies and protective coatings.

In FIG. 22b, is was described that non-conductive layers 604 and 605 were printed prior to printing conductive layers 609 and 610 but it is possible to reverse the order and print the conductive layers first. Is it also expected that non-conductive layer 604 and conductive layer 609 would be printed before printing non-conductive layer 605 and conductive layer 610.

When creating circuits that require a high current capacity, the selection of a traditional PWB using chemical or mechanical etching processes is usually limited to selecting the thickness of the copper cladding on the FR4 board. Generally, copper clad boards are specified in ½ ounce, 1 ounce and 2 ounce copper thickness. For example, a 1 ounce copper clad board has a copper thickness of 1.4 mils. For the highest current capacity, the more expensive 2 ounce copper cladding is usually selected. The thicker cladding also requires more processing time and cost to chemically etch the PWB. In general, not all the wiring on the PWB requires high current capacity as circuits usually contain a mix of low and high current requirements. For example, a PWB designed for a motor control, would contain high current wiring for the motor drive and lower current wiring for the embedded microcontroller.

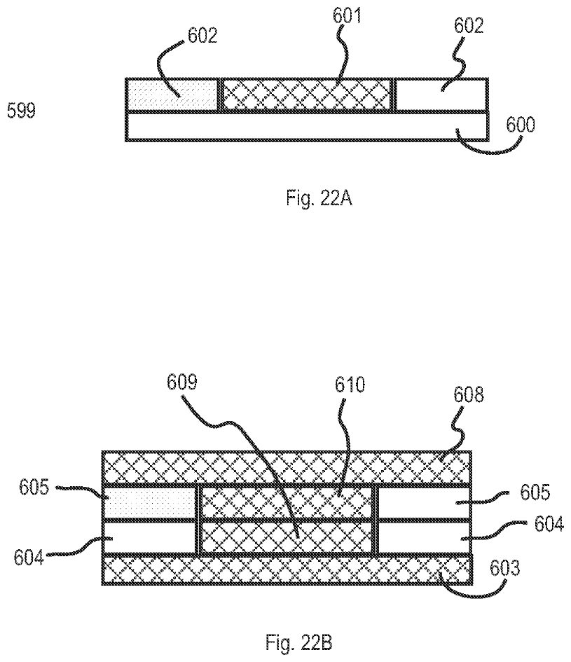

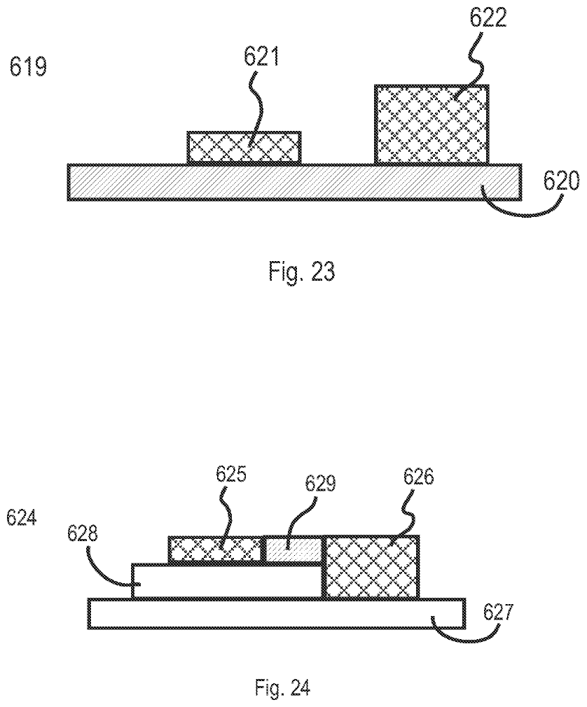

In order to reduce the cost of the PWB using printed method, apparatus 100 can print conductive layers with different amount of thicknesses. FIG. 23 shows a cross section of PWB 619 having two conductive lines 621 and 622 printed on a non-conductive substrate 620. Conductive line 621 has less height than conductive line 622. It is expected that conductive line 622 would be capable of carrying a higher amount of current when compared to conductive line 620. It is expected that conductive line 622 would have less resistance that conductive line 621. Apparatus 100 can be configured for the operator to enter the conductive thickness, the required current capacity or the required line resistance. If the input to apparatus 100 is either the required current capacity or the required line resistance, then apparatus 100 would automatically calculate the height of the printed conductor to meet that specification. The determination of the conductor height may be performed in LTM 152, PCM 128, external to apparatus 100 or any electronic means that allows an operator input to be translated to the required height for each printed conductor. If two conductive lines require different current capacity or resistance requirements, and also require that their upper surfaces lie within a common horizontal plane, then a non-conductive layer may be printed under the conductive line with the small height. FIG. 24 shows PWB 624 having two conductive lines 625 and 626 printed on substrate 627. Substrate 627 could be conductive or non-conductive. Conductive line 625 is printed on top of non-conductive layer 628 with a height that places the top of conductive line 625 at approximately the same position as the top of conductive line 626. Additionally, non-conductive layer 629 may be placed between conductive lines 625 and 626 though not required for operation having different current capacities or resistance values.

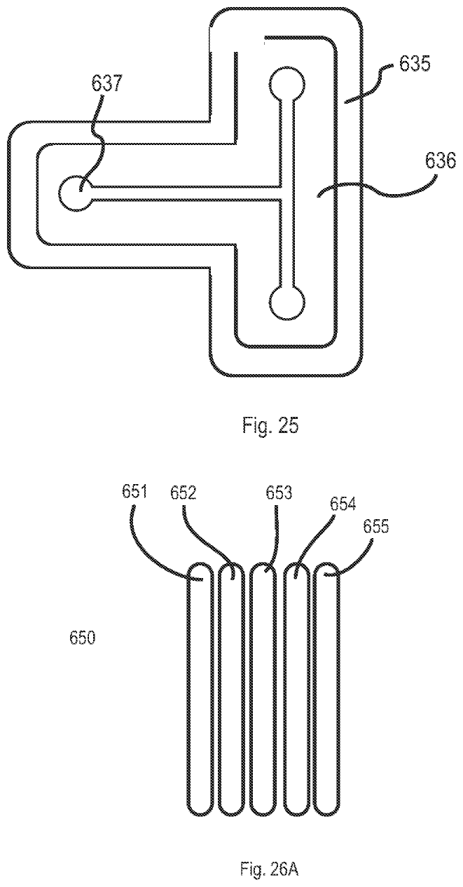

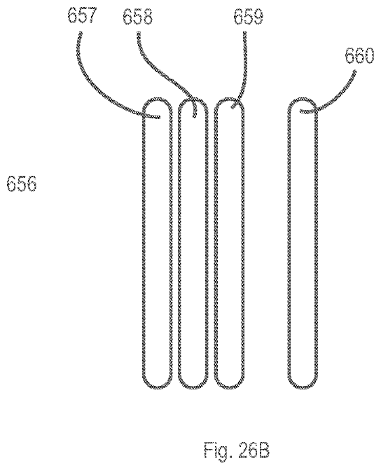

In some cases, the outline of the finished PWB is not rectangular. When processing a PWB using traditional methods of chemically or mechanically etching the traces, the copper clad board starts as a square or rectangular form and then the finished PWB is mechanically cut to the desired shape. The shape, or outline, is either specified as another file included in the set of Gerber files, as an image file or can also be determined by examining the geometries of the conductive traces and moving some pre-determined distance from the outmost traces. This process often leads to some material waste especially when the final outline is irregularly shaped. Apparatus 100 can begin with the substrate previously cut to form or apparatus 100 can directly create the substrate by printing a layer of conductive or non-conductive material to the desired outline. Printing the substrate to the desired outline saves time and material by eliminating the need to cut the outline from the rectangular board and discard the waste. FIG. 25 shows a PWB with a previously cut substrate 635 having a printed non-conductive layer 636 and a conductive layer 637. Substrate 635 can be made of a conductive or non-conductive material including, but not limited to, fiberglass, glass, aluminum, Kapton, paper and polyester film. In some cases, non-conductive layer 636 may not be required if substrate 635 is non-conductive. In another application, substrate 635 is used as a temporary support for building the PWB. Examining FIG. 25, non-conductive layer 636 and conductive layer 637 would be printed on substrate 635. When the PWB is complete and the inks have cured, substrate 635 would be removed. Substrate 635 could then be re-used on another PWB or discarded. It is also possible that a conductive layer is the first material to be printed onto substrate 635. It is also possible that a combination of non-conductive and conductive inks be printed over portions of substrate 635 and later the combination, functioning as a complete PWB, is removed from substrate 635 as part of the complete PWB. In another embodiment, substrate 635 is not required at all. In this case, non-conductive layer 636 would be printed directly onto table 104 and later removed as a functional PWB. It is also possible that a conductive layer is the first material to be printed onto table 104 and later removed as a functional PWB. It is also possible that a combination of non-conductive and conductive inks be printed over portions of table 104 and later the combination, functioning as a complete PWB, is removed from table 104. It may be necessary to apply a coating onto table 104 so that the non-conductive and conductive inks will not stick to table 104 surface. The coating may be permanent attached to table 104 or can be painted or sprayed onto the surface of table 104 as a temporary coating to prevent the non-conductive and conductive inks from sticking to the surface.

Function heads for printing inks, epoxies and solder paste may include multiple nozzles for producing small dots. It is possible, especially in low-cost piezoelectric print heads and cartridges, that one or more of nozzles become clogged or stop functioning. It is necessary to identify non-functioning nozzle before printing a PWB. In one embodiment, a test pattern is printed on a substrate in order to identify if a nozzle is not functioning properly. The test pattern can be created by individually activating a nozzle and printing a small amount of material. In one embodiment, the operator examines the test pattern and determines which nozzle or nozzles are not functioning and enters the nozzle into the apparatus 100 interface. In another embodiment, apparatus 100 is configured with an optical system that automatically identifies nozzles that do not function. If a nozzle is identified as not working, apparatus 100 may notify the operator on a procedure to correct the problem. FIG. 26a shows a proper test pattern 650 created by printing a pattern having a function head with five nozzles. Test pattern 650 includes individual lines 651 652, 653, 654 and 655. FIG. 26b shows test pattern 656 having a non-functioning nozzle creating a gap. For this case, only lines 657, 658, 659, 660 are observable. Once non-functioning nozzles have been identified, the apparatus can compensate for gaps in the printed conductive, non-conductive, epoxy or solder paste areas. Gaps will be filled using functioning nozzles.

### Laser Trimming

When using integrated circuits with very close lead spacing or when printing two lines very close together, the functional print head may not be able to adequate separation between printed geometries and it may be possible that two printed geometries are not electrically isolated as intended. In this case, a laser or other optical means will be used to burn away portions of a printed geometry to improve the electrical isolation between these geometries. In certain high frequency application, it is important to maintain a controlled impedance of the printed conductive line. The impedance is determined by the line width and several characteristics of the non-conductive material around the printed line. If the conductive line is not the correct width or the width was intentionally printed wider than required, the laser can trim the line to the desired width. Another important property when transmitting high frequency signals along a printed transmission line, is that the majority of the signal current flows on the outside edges of the printed line. Having line edges that are uneven will increase the signal loss as the signal is transmitted through the line. In this case, the laser can be used to clean up the edges of the printed line in order to reduce the signal loss.

A low-cost laser system can use the laser contained in a Bluray disc read/write system though any laser system capable of removing the conductive material would work. In certain low-cost laser units, a focusing lens may be required to obtain a dot size small enough to create the required geometries. In one embodiment, the laser system is a functional head that can be detached from apparatus 100. In another embodiment, the laser is attached to apparatus 100 or may be part of the printing head. The alignment of the laser spot on the PWB may also be included as part of the calibration process mentioned earlier. In this case, a geometry is printed with some identifiable geometry and the laser burns a portion of the geometry to guarantee alignment between the printed geometry and the burned portion. If there is misalignment, the offset can be manually corrected by the operator or automatically corrected by optical means such as a camera mounted to apparatus 100.

### Rectangular Holes for Through Holes

In most PCA applications, it is necessary to connect the functional circuit to a battery. It is also often required to epoxy or solder some type of wire, connector or other interface to the PWB to complete the PCA. It is possible to use components based on surface mount technology for these connections but to improve the reliability of these connections, it may be important to utilize components based on “through-hole” technology. In this case, the printed conductive and non-conductive geometries must include a hole through at least a portion of the printed layers. When the PWB is complete, the metallic and possibly non-metallic, wire, tab or other protruding geometry would be pushed into the printed hole and epoxied or soldered into place. Another key feature of this process, is that many of the wires, tabs or other protruding geometries are not necessarily circular and using the printing process of apparatus 100, it is possible to create a hole that is conformal to the geometry of the connection point of the through-hole component. For example, a card edge connector, such as Sullins RBB10DHHN in a 20 pin through-hole connector where each metallic connector lead has a cross sectional geometry that is rectangular at 0.018 inches by 0.012 inches. When using traditional PWB fabrication, the manufacturer suggests drilling holes with 0.04 inches in diameter. With the printing process, the printed holes can be rectangular at approximately 0.025 inches by 0.020 inches.

### Component Alignment.

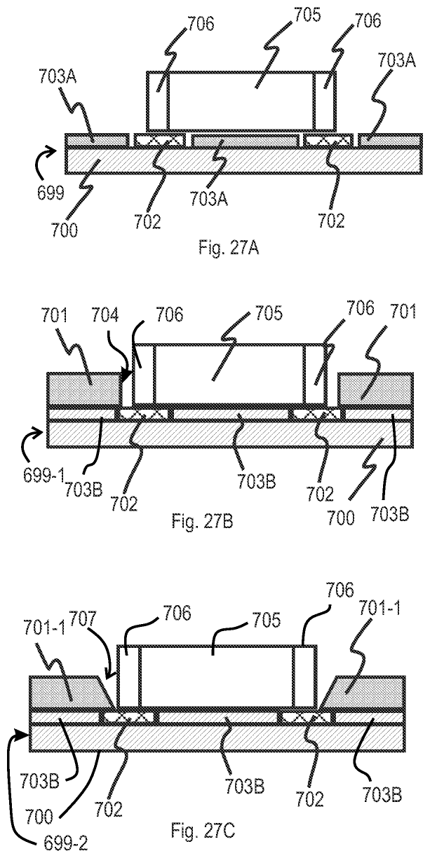

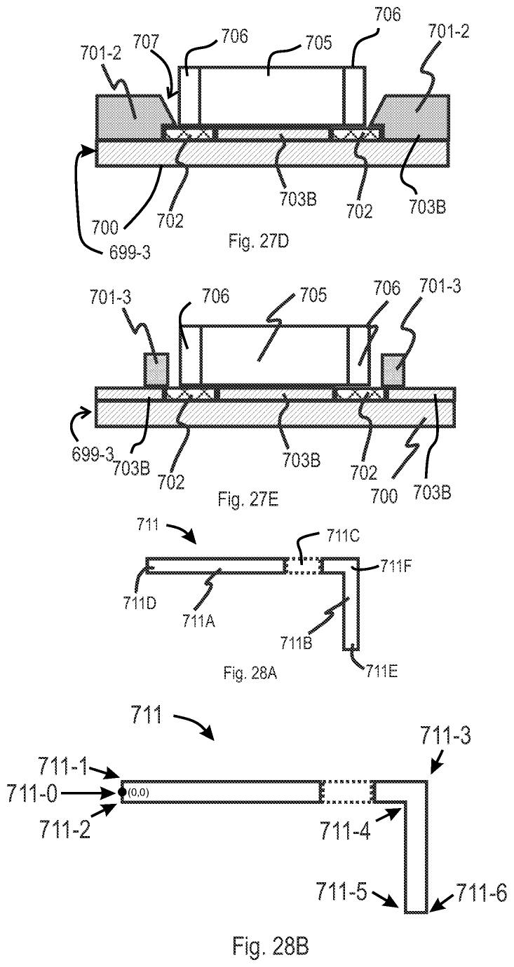

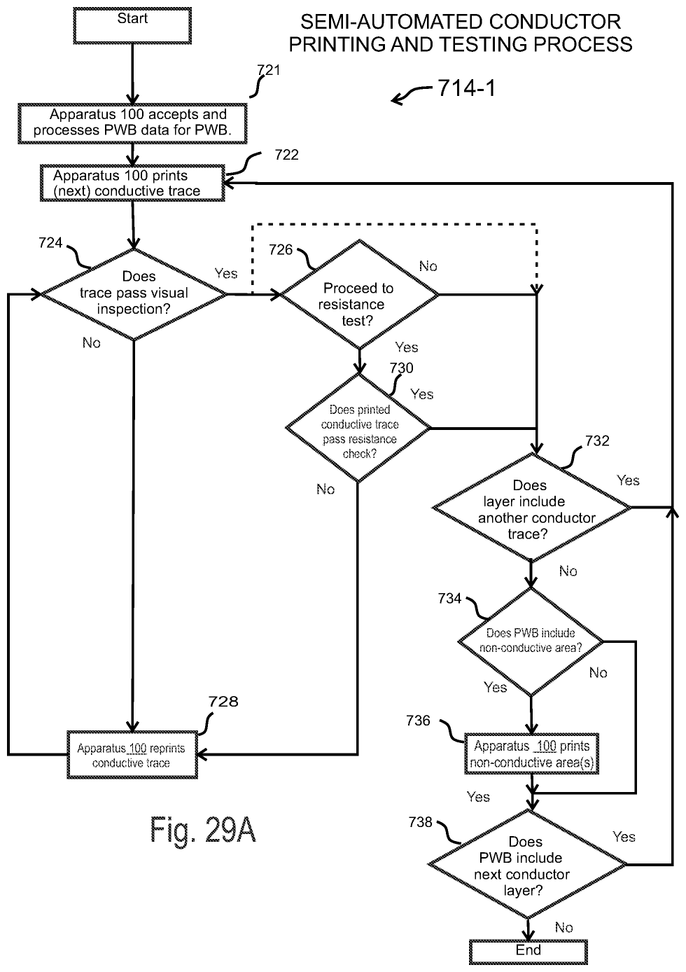

Traditionally, solder masks are used to protect the conductive lines from oxidation and isolate closely-spaced conductive lines during the process of soldering components, and their associated electrical terminals, to the conductive traces. The traditional solder mask exposes the conductive traces in the areas of solder attachment. The traditional solder mask is generally very thin in height to prevent component tomb stoning during solder reflow operation. Referring to FIG. 27A, a cross section of a traditional printed wiring board (PWB) 699 is shown having a non-conductive substrate 700, first conductive pads 702 and a solder mask 703A. An electrical component 705 has electrical terminals 706 positioned in order to align the electrical terminals 706 with portions of the first conductive pads 702. It is expected that a thin layer of conductive material, such as conductive epoxy or solder paste, is placed between the electrical terminals 706 and the first conductive pads 702 in order to create a secure electrical connection. The solder mask 703A has a thickness that is typically 0.003-inch to 0.008-inch in height. When using a CAD/CAM tool, such as Eagle, KiCAD, OrCAD or Altium, a geometry for an opening in the solder mask 703A is automatically generated based on a geometry of the first conductive pads 702. For example, CAD/CAM tool Eagle defines the solder mask as a layer named TSTOP and automatically produces solder mask openings that are 4 mils larger than the associated conductive pad geometry. The operator can modified the default opening size. The CAD/CAM produces a separate file associated with the solder mask geometries for use in fabrication.*

When printing a PWB with conductive and non-conductive inks using apparatus 100, a non-conductive guide layer may be printed on top of the PWB for the purpose of assisting the placement of electrical component onto the PWB. For example, FIG. 27B shows a cross section of a PWB 699-1 having the non-conductive substrate 700 with a non-conductive layer 703B printed adjacent the first conductive pads 702 which are printed on top of portions of the non-conductive substrate 700. The electrical component 705 is positioned in order to align the electrical terminals 706 with portions of the first conductive pads 702. A thin layer of conductive material, such as conductive epoxy or solder paste, is placed between the electrical terminals 706 and the first conductive pads 702 in order to create a secure electrical connection. In order to improve alignment between the electrical component 705 and the first conductive pads 702, a non-conductive guide layer 701 is printed on a portion ofthe non-conductive layer 703B. A first edge 704 of the non-conductive guide layer 701 serves as a locating guide when the pick and place mechanism of apparatus 100 is positioning electrical component 705 onto PWB 699-1. The first edge 704 is optionally printed to overlap the first conductive pads 702 bringing the first edge 704 closer to electrical terminals 706.*

The overlap of the first edge 704 can be determined by the geometry of the first conductive pads 702. For example, if the first conductive pads 702 have a geometry of 0.020-inch wide and using an overlap factor of a 10%, then the first edge 704 will overlap the first conductive pads 702 by 0.002-inch. Another option is printing the first edge 704 with a recess relative to the second non-conductive layer 703B thus placing the first edge 704 further away from electrical terminals 706. In this case, the electronic CAD/CAM file associated with the mask layer maintains a recess which by default is 0.002-inch using the Eagle tool.*

To aid in the placement of electrical component 705, the non-conductive guide layer 701 should have a height of at least 20% of the height of electrical component 705. More preferably, the height of non-conductive guide layer 701 should be at least 50% of the height of electrical component 705. For example, a 0602 SMT resistor with a height of 0.018-inch would result in a height of at least 0.0035-inch or more preferably, 0.0088-inch.

As shown in FIG. 27B, the non-conductive guide layer 701 can be printed with the first edge 704 perpendicular relative to PWB 699-1 or, as shown in FIG. 27C, a non-conductive guide layer 701-1 can be printed with a second edge 707 being tapered relative to PWB 699-2.*

Alternatively, non-conductive guide layer 701 or non-conductive guide layer 701-1 and non-conductive layer 703B can be printed together from one type of non-conductive material. FIG. 27D shows the configuration for printing as a contiguous nonconductive guide layer 701-2. The geometry of non-conductive guide layer 701-2 may follow the combined geometries of the individual layers.

The non-conductive guide layers, 701 and 701-1, can be printed using piezoelectric printing methods, syringe printing or any printing technique that can provide an edge for locating electrical component 705 with the electrical terminals 706 in alignment with portions of the first conductive pads 702. In some cases, the location, size and/or edge type of the holes in the non-conductive guide layers, 701 and 701-1, is determined by the LTM 152 based on coordinates of the first conductive pads 702, or a solder mask file. Alternately a CAD tool, such as Eagle, KiCAD, or Altium, would create a Gerber file, or other electronic file, that contains the location, size and/or edge type of the geometry in the non-conductive guide layers, 701 and 701-1.??

In some cases, non-conductive guide layer 701, non-conductive guide layer 701-1 or non-conductive guide layer 701.2 may cover large portions of the PWB 699, PWB 699-1, PWB 699-2 or PWB 699-3 respectively. Alternatively a non-conductive guide layer 701-3 may cover only a portion of the PWB 699-4 as shown in FIG. 27E. The dimensions of non-conductive guide layer 701-3 are such to perform the function of properly positioning electrical component 705 onto PWB 699-4. For example, the non-conductive guide layer 701-3 may form a wall around the perimeter of the electrical component 705. Alternative, the non-conductive guide layer 701-3 may take the form of bosses in the form of L-shaped guides at some or all corners of the electrical component 705. For circular shaped component the non-conductive guide layer 701-3 the bosses may take the form of crescents positioned to align the circular electrical component. Still further the non-conductive guide layer 701-3 take the form of bosses shaped as dots that are positioned about the perimeter of a rectangular, circular, or irregularly shaped electrical component at a sufficient number of locations to maintain the electrical component properly aligned.

### Manual Trace Correction.

During printing of conductive traces using apparatus 100, it may be possible that good electrical connection may not be achieved throughout the entire printed trace. For example, FIG. 28A shows a top view of a single printed conductive trace 711 which includes a first break 711C between first trace portion 711 A and second trace portion 711B. First break 711C reduces or disables the electrical connection between first trace portion 711A and second trace portion 711B.

It is possible to direct apparatus 100 to overprint conductive trace 711 once the location of first break 711C is identified by the operator. It is important to note that manually testing the conductive trace immediately following the printing provides an advantage over traditional methods as conductive traces open to the environment immediately begin to oxidize and create a resistance between the conductive trace and the probe tips. The accuracy of the resistance measurement improves when the conductive traces are measured as close to fabrication as possible. Also, important to note, when measuring the electrical performance of a traditional etched multilayer PWB, if a fault is detected along a conductive trace that is embedded within the multilayered stack, repair is impossible as the PWB layers are all laminated together before electrical testing begins. Using Apparatus 100, it is possible to electrically test the performance of each conductive trace before the next layer is printed on top. This process will greatly improve the yield of functional multilayered boards.

The operator may be able to identify the location by visual inspection of conductive trace 711 or the operator may require an instrument that is capable of measuring electrical conductivity between first trace portion 711A and second trace portion 711B. One example of an instrument is an ohmmeter that is capable of measuring the resistance between two test points. In this case, the operator would place one ohmmeter lead on top of first trace portion 711A and a second ohmmeter lead on top of second trace portion 711B. The ohmmeter would report the electrical resistance between the two test points. If the electrical resistance is measured to be higher than expected across the first break 711C, the operator would identify the location using a computer interface to LTM 150. LTM 150 would then return to the location of break 711C and print another layer of conductive ink across the break establishing an adequate electrical connection. The operator would then have the option to retest the electrical connection and repeat the process if necessary.

Referring to the IPC-9252 Guidelines and Requirements for Electrical Testing of Unpopulated Printed Circuit Boards (hereby incorporated by reference), Section 4.4, states that “one hundred percent continuity and isolation electrical test is the confirmation that the actual electrical interconnect of conductive nodes matches a proven reference source, including but not limited to CAD/CAM digital data, master pattern artwork, or released drawings”. An electrical feature that is a continual conductive line may have several features including a variety of lines, pads and via holes. Together, all of these features are defined by a “net” and the information is typically stored in an electronic file such as a Gerber file. The “end of net” is a feature that is a termination point along a conductive net. In order to meet the guidelines contained in IPC-9252 for optimized net list testing.

Traditional test systems measure continuity between pairs of “end of net” features and are operated upon traditionally printed circuit boards following etching and laminating processes. For the example shown in FIG. 28A, the terminations are shown as first conductive termination 711D and second conductive termination 711E. Identifying these locations is typically achieved by examining the electronic data file associated with the PWB layout. The traditional etched and laminated (for multilayer boards) circuit board is operated upon by test instrumentation when removed from manufacturing equipment.

For example, single printed conductive trace 711 contains a segment that is 0.15″ across moving from first conductive termination 711D to the right angle bend 711F and also contains a segment that is 0.10″ from right angle bend 711F to second conductive termination 711E, The associated Gerber data contained in an electronic Gerber file would be as follows:

### % FSLAX25Y25*%

### % MOIN*%

### % IPPOS*%

### % ADD10R, 0.025X0.025*%

### % LPD*%

### X0Y0D2*

### D10*

### G1X15000Y-10000D2*

### Y0D1*

### X0*

### M02*

With this format, the line “X0Y0D2*” identifies first conductive termination 711D and line “G1X1 5000Y-10000D2*” identifies second conductive termination 711E. These two X-Y locations can be used for positioning test probes for measuring the electrical performance of the entire line following IPC-9252. The Gerber file presented above, the width of the conductive trace is identified by the size of the line aperture using “% ADD10R, 0.025X0.025*%”. In this case, the line width, and associated aperture is rectangular with dimension 0.025″ by 0.025″.

It is possible that CAD/CAM tools may produce a GERBER file that identifies the outside geometry of the conductive trace. For example, FIG. 28B is the same conductive trace as described above but the GERBER file details the individual vertices, namely first vertex 711-1, second vertex 711-2, third vertex 711-3, fourth vertex 711-4, fifth vertex 711-5 and sixth vertex 711-6. First vertex 711-1 and second vertex 711-2 are used to identify the location for placing the test probe. Fifth vertex 711-5 and sixth vertex 711-6 identify the location for placing the other test probe. The following Gerber data identifies second vertex 711-2 with “G01X0Y-125D02*”, fourth vertex 711-4 with “G01X1375D01*”, fifth vertex 711-5 with “G01Y-1000D01*”, sixth vertex 711-6 with “G01X1625D01*”, third vertex 711-3 with “G01Y125D01*” and first vertex 711-1 with “G01X0D01*”.

### % FSLAX24Y24*%

### % MOIN*%

### % SFA1.0000B1.0000*%

### % OFA0.0B0.0*%

### % ADD10C, 0.000025*%

### % LNcond*%

### % IPPOS*%

### % LPD*%

### G75*

### G36*

### G01X0Y-125D02*

### G01X1375D01*

### G01Y-1000D01*

### G01X1625D01*

### G01Y125D01*

### G01X0D01*

### G01Y-125D01*

### G37*

### M02*

The numeric values extracted from the Gerber commands are listed as absolute coordinates relative to the origin vertex 711-0 with units of “inches”. For example, second vertex 711-2 has a command line resulting in the vertex of X=0 inch and Y=−0.125 inch (0 inch, −0.125 inch). The points are determined by following the Gerber format described in the Ucamco document “The Gerber Format Specification” (hereby incorporated by reference). The following table shows the vertices and their associated x-y coordinates.

| Vertex | (X, Y) [inch, inch] |
|---|---|
| 711-1 | (0, 0.0125) |
| 711-2 | (0, −0.0125) |
| 711-3 | (0.1625, 0.0125) |
| 711-4 | (0.1375, −0.0125) |
| 711-5 | (0.1375, −0.1000) |
| 711-6 | (0.1625, −0.1000) |

Identifying endpoints can be performed with several techniques such as taking differences between coordinates that have one coordinate the same. For example, first vertex 711-1 and second vertex 711-2 have the same x coordinate, and the difference in the y coordinate is 0.0250 inch which is the width of conductive trace 711 and could be recognized as an endpoint to the line. Third vertex 711-3 and sixth vertex 711-6 have the same x coordinate and the different in the y coordinate is 0.1125 inch which is larger than the line width so this can be assume to be a length of conductive trace. Another example with the same y coordinate is fifth vertex 711-5 and sixth vertex 711-6 has a difference in the x coordinate of 0.025 inch which could be an endpoint.

Optionally, using predetermined parameters regarding line widths, the endpoints are identified. Alternatively, the operator may input line widths. Yet another option is that the differences are examined and the line width is determined based on length to width ratios of conductors. Test probes would be placed a distance from the endpoint at least the radius of the test probe. For example, if the test probe has a conductive tip of diameter equal to 0.020 inches, then locating the test probe on top of conductive trace 711 at a distance of 0.010 inch from the endpoint associated with first vertex 711-1 and second vertex 711-2.

### Semi-Automated Conductor Testing.

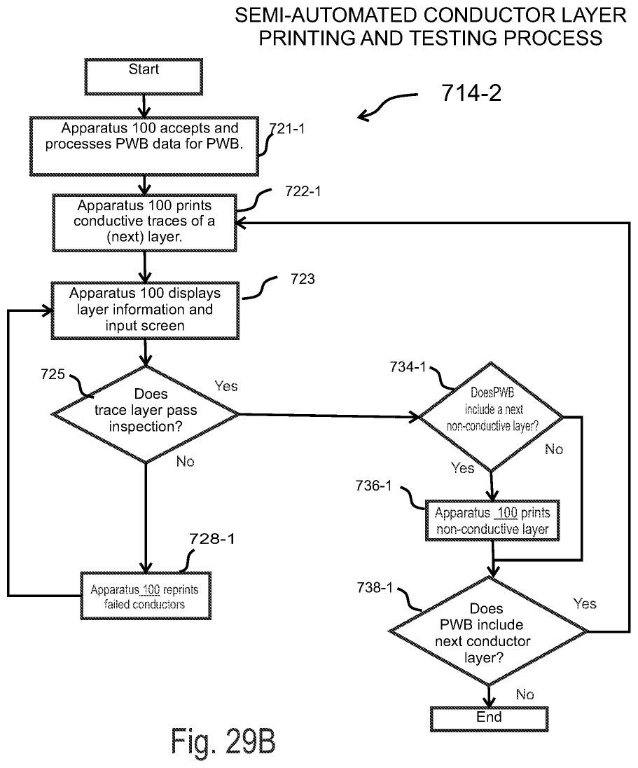

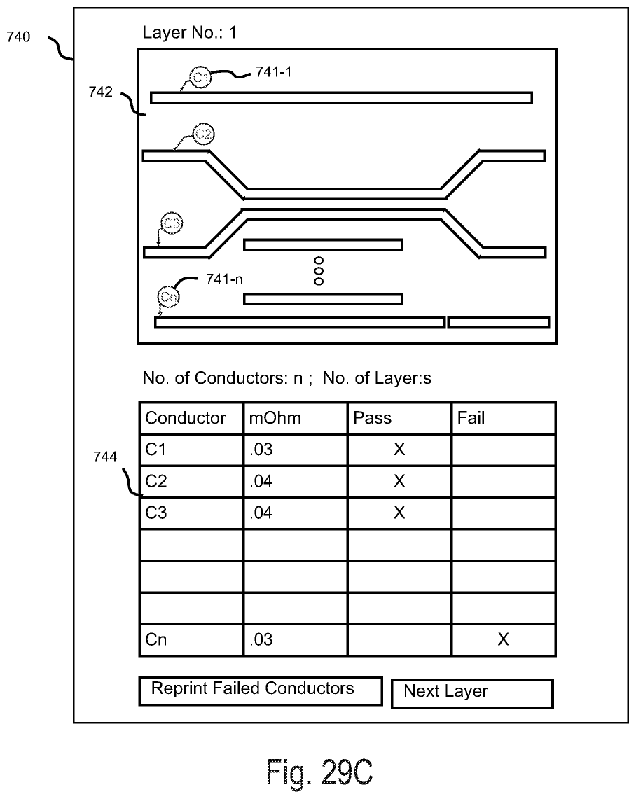

Referring to FIG. 29A, an optional first semi-automated testing process 714-1 for printing a conductive trace, measuring conductive trace resistance, and correcting a faulty trace is shown. The process begins in operation 721 by the LTM 150 of the apparatus 100 accepting geometry data for a PWB including one or more layers of printed conductive traces and optionally layers of nonconductive material to be printed. The geometry data may be obtained from files prepared by a CAD program, such as a Gerber file for example and not limitation. Alternatively, the geometry data may be generated by the LTM150 based on such CAD files translated by the LTM 150 to data for printing conductive traces and nonconductive areas as discussed previously in this specification. Still further, another option allows data otherwise input to the apparatus 100 by the operator.

Preferably, although not required, the LTM 150 organizes the conductive traces in lists corresponding to layers followed by nonconductive area layers to printed as required by either the input file data or the translated data produced by the LTM to facilitate producing the PWB by printing conductive and nonconductive material. That is, a group of conductive traces is printed and tested followed by the printing of nonconductive areas, with this printing sequence being repeated as necessary to complete the PWB. The term “list” is used figuratively in sense that conductive traces are designated for printing in a manner required for functionality of a resultant PWB

In operation 722 the apparatus 100 prints a conductive trace based on the geometry data processed which preferably arranged in a list of conductive traces to be printed during a sequence of conductive printings to be implemented. The conductive trace is printed using conductive ink on a non-conductive substrate or, on a non-conductive area previously printed by apparatus 100 using a non-conductive ink.

In operation 724, the apparatus pauses for the operator to visually inspect the printed conductive trace for breaks or other anomalies. The LTM 150 initiates display of information that the system is paused and questions whether the conductive trace passes visual inspection. The display of information may be on the display 106 which is either integral to the apparatus 100, or external to the apparatus 100 and connected directly or via a computer used to control or interface with the apparatus 100 as previously discussed. In operation 724 apparatus 100 accepts the operator input in the form of a continue command or a reprint command respectively corresponding to the conductive trace passing or failing visual inspection.

When the operator visually detects a flaw in the conductive trace the operator inputs the reprint command in decision operation 724 which directs the apparatus 100 to recall printing data for the last printed conductive trace and again print the conductive trace in operation 728. The process then moves back to operation 724 for visual inspection.

If the operator's visual inspection is acceptable the operator inputs continue in operation 724. It is advantageous to measure the electrical properties of printed conductive traces especially when traces are narrow and defects may not be visually apparent. Other times traces are relatively wide and visual inspection will suffice. The apparatus 100 is optionally set to either proceed to prompt for a resistance pass/fail input, prompt the operator for input as to whether the conductive traces is to be tested, or proceed directly to bypass the resistance test and move on to operation 732. When the apparatus 100 is previously set to perform the resistance testing, operation 726 directs flow to operation 730 based on the setting. Alternatively, the apparatus 100 may be set to prompt the operator as to whether each conductive trace is to be resistance tested in operation 726. A positive operator response directs flow to operation 730 while a negative operator response directs flow to operation 732. When the apparatus 100 is previously set to not perform the resistance testing, operation 726 directs flow to operation 730 based on the setting. It is further an option that the apparatus 100 is configured only for accepting visual confirmation of the conductive traces in which case a positive response in operation 724 results in flow proceeding directly to operation 732 as shown by the dashed flow line.

In operation 730 the apparatus 100 optionally displays an expected value of the resistance of the conductive trace to compare against the operator's measurement. The expected resistance may be calculated by LTM 150 having knowledge of the trace geometry and the conductivity of the conductive ink. The expected resistance may also be located in a database which is retrieved by LTM 150. The apparatus 100 pauses for the operator to manually measure the properties of the trace. The operator may use a basic ohmmeter to measure the resistance of the printed conductive trace. The apparatus 100 awaits confirmation of an acceptable resistance measurement.

Returning to FIG. 28A, LTM 150 could identify the expected resistance for the complete conductive trace 711. For example, if the specification for resistance of a printed conductive line is 40 mOhm/square, then a printed conductive line that is 1-inch long with a width of 0.020-inch would be expected to have resistance of 2-ohms. In this case, LTM 150 would report this expected resistance to the operator and the operator would then compare the total expected resistance to the measured resistance. In order to measure the resistance of the entire conductive trace 711, the operator would place one ohmmeter lead on top of conductive trace 711 at location 711D and a second ohmmeter lead on top of conductive trace 711 at location 711E. If the measured resistance is higher than expected, apparatus 100 is directed to reprint the entire conductive trace 711. As discussed, the operator would then have the option to retest the electrical connection and repeat the process if necessary.

As an alternative to displaying an expected resistance, the apparatus 100 may simply await confirmation of an acceptable resistance measurement. An nominal value of resistance may simply be assumed for a conductive trace or traces as may be the case where circuitry has high impedance inputs and little current is used, or other situation where a low resistance connection is not required.

If the measured resistance is unacceptable, the operator provides a negative input in operation 730 and flow proceeds to operation 728 wherein that conductive trace is reprinted and flow then proceed to another inspection of the trace. If the operator determines that a reprint is not required, i.e., the resistance measurement is acceptable, flow proceeds to operation 732 wherein the apparatus 100 determines whether there are further conductive traces to be printed in the given group prior to printing of nonconductive material. As noted above, the LTM 150 optionally processes the PWB data to assemble groupings of conductive traces to be printed sequentially prior to a grouping of nonconductive areas to be sequentially printed, with the printing of sequences of conductive traces and sequences of nonconductive areas being repeated until the PWB is complete. If there remain further conductive traces in a grouping, or layer, to be printed, flow returns to operation 722 and a next conductive traces in a sequence is printed.

If the sequence, or layer, of conductive traces to be printed has been completed, operation 732 yields a negative outcome and flow proceeds to operation 734 wherein it is determined whether the processed PWB data next requires printing of nonconductive areas. If so, flow proceeds to operation 736 wherein the LTM 150 moves on to printing non-conductive areas as required. Printing non-conductive areas may be performed automatically after the resistance measurement or LTM 150 may request an input from the operator in order to continue processing the PWB. In a multi-layered PWB, LTM 150 proceeds to the next layer of conductive and non-conductive geometries based on operation 732-738, with operation continuing until the PWB is complete.

It should be noted that measuring electrical connection between two locations on a printed conductive trace can be measured using a variety of techniques. The ohmmeter is a standard measurement technique. Other techniques include applying a voltage and/or current at one location along the printed conductive trace and measuring the voltage and/or current at another location along the trace. The resistance can be determined by using the Ohm's law equation. The operator may also use other instrumentation to measure the electrical performance of the trace including capacitance, inductance, insertion loss, return loss, time domain reflectometry (TDR) or any other measurement technique that can verify that the printed conductive trace is capable of performing the intended function. Thus, while resistance is referenced above, other parameters may be substituted.

### Semi-Automated Conductor Layer Testing.

When a multilayer PWB is to be printed there may be numerous conductive traces on a single layer and there may be multiple layers. In such situation it may be advantageous to effect conductor testing in groups, or layers, rather than one at a time. Referring to FIG. 29B, a second semi-automated testing process 714-2 is shown which is directed to situations wherein numerous conductive traces are printed on a given layer and is similar to the first semi-automated testing process except as noted herein. This testing process provides for a group of conductive traces to be printed and tested followed by the printing of nonconductive areas if required, with this printing sequence being repeated as necessary to complete the PWB.

The process begins in operation 721-1 by the LTM 150 of the apparatus 100 accepting geometry data for a PWB including one or more layers of printed conductive traces and optionally layers of nonconductive material to be printed as discussed above with reference to operation 721. In the case where a multilayer PWB is to be produced the conductors to be printed are grouped in layers as are the nonconductive areas. The LTM 150 organizes the conductive traces in layers followed by nonconductive layers as required by either the input file data or the translated data produced by the LTM to facilitate producing the PWB by printing conductive and nonconductive material.

In operation 722-1 the apparatus 100 prints conductive traces of a layer, or a next layer, based on the geometry data. The conductive trace or traces are printed using conductive ink on a non-conductive substrate or, on a non-conductive area previously printed by apparatus 100 using a non-conductive ink or material. In operation 723 the apparatus displays a layer information on the display 106. Referring to FIG. 29C, an optional configuration of layer information is depicted as layer information screen 740. A printed layer depiction 742 is in the upper half of the display wherein conductors are optionally given call out labels 741-1 through 741-n which correspond to rows in a conductor data table 744 in a lower half of the display. Other information related to the PWB being fabricated is optionally displayed such as, for example and not limitation, a layer number of the layer depicted, a total number of layers in the PWB, a number of conductors in the depicted layer. A conductor table 744 optionally displays an expected resistance for conductors of the depicted layer and include columns for the operator to mark whether a give conductor passes or fails review. Input may be via, for example and not limitation, touch screen, keypad or key board, a mouse or other pointing device. Applying callouts labeling the conductors is optional and other methods of coordinating information displayed and input to the conductors may be employed. For example, the operator may highlight a given conductor to obtain information and/or input testing status for the conductor. Input buttons for reprinting the failed conductors or proceeding to the next layer for printing are optionally provided at the screen bottom section. Alternatively, simply “Continue” input may be used wherein the apparatus proceeds to reprint failed conductors or proceeds to print a next layer if no failures are found.

Referring again to FIG. 29B, in operation 725 the apparatus awaits the operator input indicating whether the printed layer passes inspection. The operator may visually and/or electrically inspect each of the conductors and input using the layer information screen 740 which conductors do not pass inspection. By selecting the “Reprint Failed Conductors” button the operator directs the apparatus 100 to reprint conductors for which a failed input is made. It is not necessary to have a “passed” input field but such a field may be helpful in keeping track of tested conductors. A further alternative is for the operator to activate a “Continue” input which the apparatus interprets as requesting a reprint of all failed conductors and alternatively instruction to proceed to a next layer if no conductors are failed.

When the operator detects flawed traces and initiates a reprint in operation 725, flow proceeds to operation 728-1 wherein the LTM150 recalls the geometry data for the failed traces and operates the apparatus 100 to gain print the failed traces. Flow the proceeds back to operation 723 wherein the layer information screen 740 is again displayed. As an option, the display may only display rows for the previously failed conductors in the conductor data table 744. Alternatively, failed conductor rows may be highlighted for soliciting operator input. Still further the full table may be displayed but all conductors not previously indicated as failed may be displayed with the “Pass” indication being affirmative. Other methods may be adopted to simplify subsequent verification operations. As an alternative to displaying an expected resistance in the conductor data table 744, the apparatus 100 may simply await confirmation of an acceptable conductor review.

If the operator determines that a reprint is not required, i.e., the all conductors of the layer are acceptable, flow proceeds to operation 734-1 wherein the apparatus 100 determines whether there is a subsequent layer of nonconductive areas to be printed. If so, flow proceeds to operation 736-1 wherein the LTM 150 moves on to printing a layer of non-conductive areas as required. Alternatively, flow proceeds to operation 738-1 wherein it is determined whether there is further conductive layer to be printed. If so, flow proceeds back to operation 722-1 and another layer of conductors is printed. Similarly, following operation 736-1 printing a nonconductive layer, operation proceeds to operation 738-1.

When further conductive layers remain flow proceeds back to operation 722-1 wherein another layer of conductive traces is printed. Alternatively, no conductive trace layers remain to be printed, the PWB is complete and the process ends.

### Automatic Trace Correction.

One type of traditional test system for testing the electrical continuity and electrical isolation of conductive traces is known as a Universal Grid system. These test systems use a single, double or quad-density grid pattern of test points assembled into a fixture and placed in contact with a fabricated PWB. For example, a single-density grid pattern has spacing of 0.1-inch by 0.1-inch resulting in a 100 points/inch-squared density. A quad-density grid has a density of 400 points/inch-squared. These systems are stand-alone and separate from the PWB fabrication equipment and assembly equipment. The universal grid system may make use of a test-file, such as an IPC-D-356 CAD/CAM file, for identifying the location of via holes and pads. These files identify if the feature is located at the top or the bottom of a chemically etched PWB. For a multi-layer PWB, the universal grid system may not be able to identify conductive line problems embedded within the stack-up and does not allow the operator the option to repair the conductive trace as the PWB as the PWB was previously laminated together during PWB fabrication. In this case, when a PWB conductive trace is found faulty, the entire PWB is typically discarded unless a jumper wire is attached external to the PWB. Another type of traditional test system is the Flying Probe-Type system. A flying probe system use robotic probes that are moved across the board for making contact with the conductive traces. Here again, the flying probe may not be able to identify conductive line problems within the multilayered stack-up or does not allow the operator the option to repair the conductive trace as the PWB was previous laminated together and no longer repairable.

Using apparatus 100 for printing a single layered, or multilayered PWB, it is possible to automatically test the electrical performance of a printed conductive trace and automatically correct the printed conductive trace which may include a break or undesired high resistance. Referring to FIG. 4, a block diagram of apparatus 100 shows an optional electrical measurement unit 760. Electrical measurement unit 760 includes a probe holder mechanism 762 for probing the surface of a printed conductive trace and electrical test instrument 761 to measure a characteristic of a printed conductive trace. The probe mechanism 762 optionally provides a holder for a single probe tip for contacting the surface of the printed conductive trace. Alternatively, the probe mechanism 762 may alternatively include a holder for two, or more, probe tips configured for positioning probes to contact a surface of a printed conductive trace at two, or more, points along the trace. The probe mechanism 762 also is optionally configured to position a probe tip or tips for a non-contact type measurement which would make electrical connection(s) to the printed conductive trace though capacitive coupling. A non-contact probe will not mar the surface of the printed conductive trace.

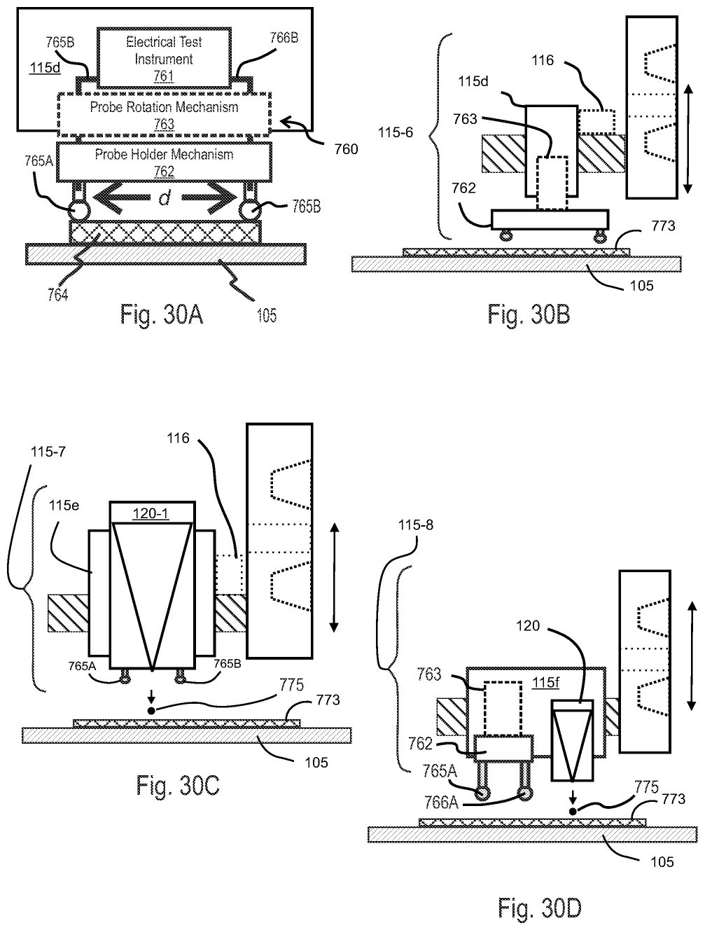

Referring to FIGS. 30A and 30B the electrical measurement unit 760 is contained in a measurement function head module 115d which mounts to apparatus 100 at head mount 110 (shown in FIGS. 5a and 5b) via a function head 115-6. The head mount 110 provides for three-axis movement of the function head 115-6. Probe holder mechanism 762, being attached to head mount 110, may be rotated relative to the PWB using either the table rotator 139, shown in FIG. 5B, or the rotation motor 116 for rotating the measurement function head module 115d. Alternatively, optionally provided is a probe rotation mechanism 763 which rotates the probe holder relative to the measurement function head module 115d. The electrical measurement unit 760 is schematically represented in FIG. 30A and is shown including the optional probe rotation mechanism 763 for rotating probe holder mechanism 762 absent rotation of the table 104 or the function head unit 115d. Hence, the probe rotation mechanism 163 may be omitted if other modes of rotation are to be used. Alternatively, the function head 115-6 for carrying the probe holder mechanism 162 may be configured absent the rotation motor 116 if probe rotation mechanism 163 is present.

As shown in FIG. 30A, the electrical test instrument 761 is connected to first test probe 765A using first probe wire 765B. Electrical test instrument 761 is connected to second test probe 765B using second probe wire 766B. First test probe 765A and/or second test probe 765B may be of a contact-type, having physical contact with the printed conductive line 764 or may be of a contactless-type not having physical contact with the printed conductive line 764. Printed conductive trace 764 is printed on a non-conductive material substrate 105.

The functional portions of the electrical measurement unit 760 may be split with the probe rotation mechanism 763 and probe holder mechanism 762 being mounted to head mount 110 via the function head 115-6 while the electrical test instrument 761 is situated otherwise on the apparatus 100. First probe wire 765B would connect electrical test instrument 761 to first probe tip 765A. First probe wire 765B may include a connector to temporarily disconnect electrical test instrument 761 from first probe tip 765A. Probe holder mechanism 762 may also be temporarily mounted to function head 115 as a separate mechanism. If required, probe rotation mechanism 763 may also be temporarily mounted to function head 115 as a separate mechanism.

A further configuration includes measurement probes 765A and 765B being incorporated into the ink printing mechanism 120 since, as related below, the ink printing mechanism 120 need not make contact with the substrate 105 so the probes may protrude below the ink printing mechanism 120 and selectively make contact with printed conductors by means of vertical movement of the head mount 110. Rather than incorporate into the ink printing mechanism, the probe holder mechanism 762 may be mounted to the ink printing mechanism 120. If required, the probe rotation mechanism 763 may be mounted to ink printing mechanism 120.

Electrical test instrument 761 include types of two-wire and four-wire test systems for measuring the electrical performance of the printed conductive trace. Four-wire test systems are more accurate but require measurement of current and voltage separately. Electrical test instrument 761 also includes measurement types that are capable of measuring the electrical performance of the printed conductive trace which include capacitance, inductance, insertion loss, return loss, time domain reflectometry (TDR) or any other measurement technique that can verify that the printed conductive trace is capable of performing the intended function. For a basic resistance test between two test points, as shown in FIG. 30A, the first test probe 765A and the second continuity test probe 765B are placed in temporary contact with printed conductive trace 764. The first test probe 765A and the second test probe 765B may be configured as spring-loaded pins, also known as pogo-pins, with a tip-shape that will not damage the printed conductive trace 764. Spring probes typically present approximately 75 grams to 130 grams of force when compressed. Another option is to have first test probe 765A and second test probe 765B supported via function head 115-6 by the head mount 110 which has the capability of movement in the vertical axis and can be used to lower first test probe 765A and second test probe 765B to touch the surface of printed conductive trace 764 without causing damage to the printed conductive trace 764. Another technique for determining the electrical continuity of printed conductive trace 764 include applying a voltage across first test probe 765A and second test probe 765B and measuring the current passing through conductive trace 764 and the resistance can be calculated using the Ohm's law equation, specifically, resistance equals voltage divided by current. Another technique for determining the electrical continuity of printed conductive trace 764 include passing a current through the test probes and conductive trace and measuring the associated voltage.

Referring to FIG. 30A, a schematic representation of a probe holder mechanism 762 illustrate that the first test probe 765A and the second test probe 765B are separated by a distance d. The distance d may be predetermined and associated with the smallest line length for the printed conductive trace 764 and the operator would manually adjust the spacing between first test probe 765A and second test probe 765B to this predetermined distance. Another variation would have LTM 150 automatically adjust the spacing, d, between first test probe 765A and second test probe 765B to a predetermined distance. Another variation includes LTM 150 reporting the optimized spacing between first test probe 765A and second test probe 765B based on the geometry of printed conductive trace 764 to be tested and then direct the operator to manually adjust the spacing between first test probe 765A and second test probe 765B, or, LTM 150 would automatically adjust the spacing between first test probe 765A and second test probe 765B.

In the situation that the probe holder mechanism 762 has a probe separation d that is less than the length of a printed conductive trace, two or more electrical measurements are optionally effected as the first test probe 765A and the second test probe 765B are moved along the printed conductive trace in order to completely measure the electrical properties of the entire printed conductive trace. This technique can also be used to overprint a conductive trace until a desired trace resistance is measured using electrical test unit 760. Overprinting may be required for printed conductive traces that are expected to carry a large current during the PWB intended operation.

In an embodiment of the ink printing mechanism 120, the process for printing conductive traces using thermal and piezoelectric technologies results in a droplet of conductive ink being ejected from an electronically-controlled printing element. In both cases, the printing element does not need to be in contact with the surface of the substrate and has a spacing that is typically between 1-2 mm. This spacing allows the test probes to be located at a closer distance to the substrate which then can be lowered to make contact with the printed conductive ink for continuity testing. Referring to FIG. 30C, this distancing of the printhead from the substrate allows for the test probes, 765A and 765B, to be incorporated directly into a print-test head 120-1 which is symbolically shown. (In FIGS. 6a-6e, printing mechanisms, 120 and 130, are shown as triangles for purposes of simplicity) The print-test head 120-1 mounts in print-test function module 115e which is carried in a print-test head mount 115-7. When testing is not effected, and printing is in progress, the print-test head 120-1 is positioned above the substrate 105 and ink droplets 775 are ejected to form the conductive trace 773. Hence a printhead utilizing piezoelectric, thermal, or other ejection technology has probes directly incorporated in a bottom of and probe leads making connection along with the usual control contacts of a printhead. When testing commences, ink ejection ceases and the print-test head 120-1 is raised and lowered by the head mount 110 to test portions of conductors.

Referring to FIG. 30D, there is shown a side-view of a dual function head module 115f configured to carry the probe holder mechanism 162 and the conductive ink printing mechanism 120. The dual function head module 115f is carried in dual function head 115-8 which mounts to the head mount 110 shown in FIG. 5B. Optionally, the probe rotation mechanism 763 is also included. First test probe 765A and second test probe 765B are mounted to probe holder mechanism 762 and positioned below conductive ink printing element 120 such that first test probe 765A and second test probe 765B can be lowered by apparatus 100 in order to make temporary electrical contact with the conductor 773 and also prevent physical contact of the conductive ink printing element 120 with the substrate 105. Typically, the first test probe 765A and the second test probe 765B can be positioned about 0.5 mm below conductive ink printing element 731.

The LTM 150 controls the position any of the ink printing mechanism, 120 or 120-1, in the vertical direction to provide an appropriate spacing required for printing onto substrate 105. Then conductive ink printing mechanism 120 ejects ink droplet 775 onto the substrate 105. The process continues as the head mount, either the dual function head 115-8 or the print-test head mount 115-7, is moved across the substrate 105 until a series of contiguous droplets create conductive trace 773. Testing the electrical performance is achieved with the probes holder mechanism 762 in the dual function head module 115e or the print-test head 120-1.

Reprinting a conductive trace results in printing over the original trace with the same or similar geometry. LTM 150 may automatically reprint the conductive trace if the measured resistance is above an operator-entered or calculated value. The calculated value for trace resistance can be automatically determined by LTM 150 knowing the printed trace geometry and the sheet resistivity of the printed conductive ink. When the apparatus 100 is configured for automated testing and correction it may carry either the dual function head 115-8 or the print-test head 115-7. This allows printing and testing to be done without reconfiguring the function head. Alternatively, the apparatus 100 may effect printing the conductive traces using the function head 115-1 (shown in FIG. 6a) carrying the ink printing mechanism 120, and automatically exchange the function head module 115a for the measurement function head module 115d.

Various configurations have been depicted in this description and accompanying drawing for carrying and mounting a printhead, syringe dispenser, extruder, measurement device, and combinations thereof to a head mount 110. These configurations are to be considered examples and are not intended to limit the scope of this disclosure or appended claims. Other configurations for mounting devices effecting any of the functionalities disclosed herein may be adapted to the actualization of apparatus 100 and processes described herein. In the following processes wherein the apparatus 100 alternates between printing conductive traces and effecting measurement of the trace it will be accepted that any of the above noted configurations for effecting the functions of printing and measuring may be employed. For purposes of clarity, discussion of effecting exchanges of the printing function head module 115a for the measurement function head module 115e will be omitted and statement of the effected function is presumed to include such exchange if required by the configuration of the apparatus 100.

Processes are next described wherein the apparatus effects printing conductive traces and correcting flawed traces. The processes shown starts after a substrate 105 is loaded onto the table 104 or is formed on the table 104 by the apparatus 100 printing the substrate using nonconductive material or extruding nonconductive material to form a substrate. In these processes it is assumed that the probe separation d does not always permit and entire conductive trace to be tested in one measurement. However, it is possible that the probe holder mechanism 762 is adjustable with sufficient range for testing entire conductors. This depends on the PWB size and the range of the probe holder mechanism. Hence, it is understood that given sufficient range, operations to test entire conductors need only adjust the probe separation d to accommodate endpoints of the conductor. Thus it is implicit in the processes describe that if such range is available, each measurement operation constitutes adjusting the range and testing the entire conductor. Subsequent operations directed to testing the entire conductor in segments, or portions, are therefore obviated.

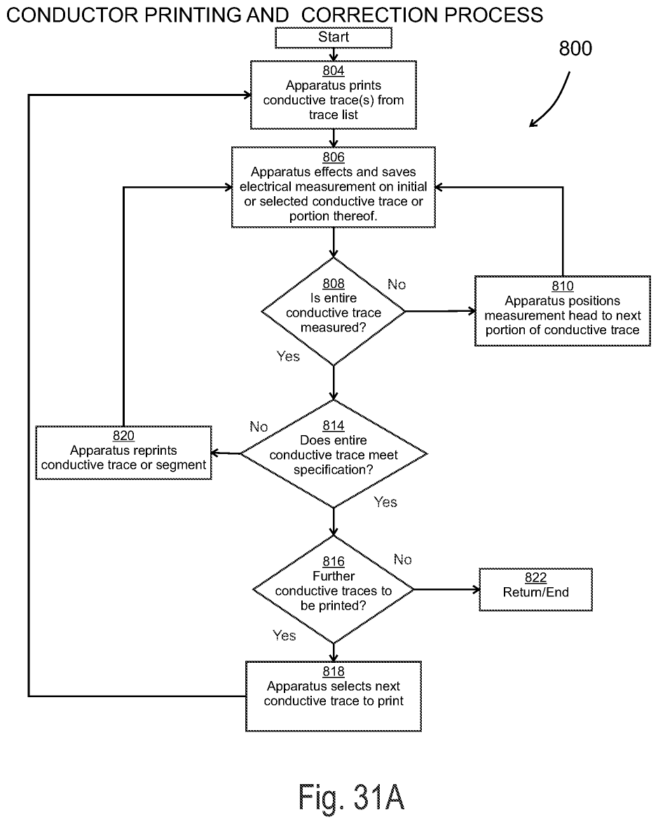

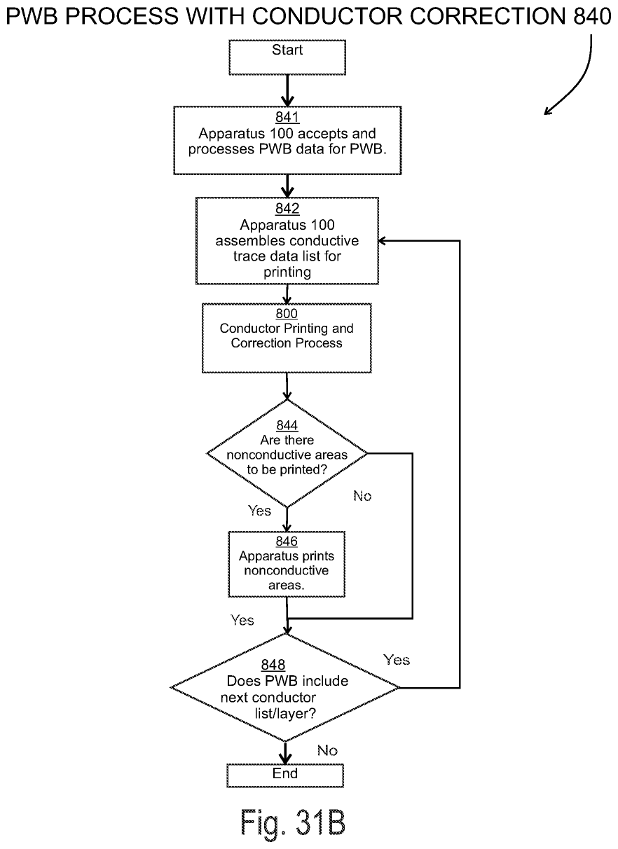

Referring to FIG. 31A, a sub-process flowchart is shown wherein apparatus 100 effects a conductor printing and correction process 800 which prints conductive traces, tests the printed traces, reprints conductive traces that fail to pass a measurement test. In operation 804 the sub-process begins accepting conductive trace geometry data which includes data for conductive traces segments which together comprise data for entire conductive traces. The apparatus 100 processes the data and prints a conductive trace or all conductive traces of a layer. In the next operation the LTM 150 directs apparatus 100 to measures the electrical performance for the printed conductive trace(s) using any of the aforesaid measurement configurations. As previously related, depending on probe space d either an entire trace is measured or a segment, or portion, of the traces is measured. The measurement(s) is/are saved. In operation 808 it is determined whether the test probe spacing d provided measurement over the entire conductive trace. If the result is negative flow proceeds to operation 810 wherein the probe holder mechanism is repositioned over a different, and contiguous, portion of the selected conductive line. Flow then proceeds to operation 806 wherein a further electrical measurement is made and saved with flow again proceeding to operation 808. When operation 808 yields a positive result, flow proceeds to operation 814 wherein the saved electrical measurements for the conductive trace are evaluated and it is determined whether the conductive trace meets specification. If the result is negative, flow proceeds to operation 820 wherein the conductive trace is reprinted, either in whole or in part. For example, a failed segment of the conductive trace may be reprinted or the entire trace may be reprinted. Flow then proceeds back to operation 806 wherein the measurement operations are again effected.

When operation 814 yields a positive result flow proceeds to operation 816 wherein it is determined whether further conductive traces exist in the trace list to be printed. An affirmative result directs flow back to operation 804 and the next conductive trace is printed. A negative result ends the sub-process with all the traces described in the trace list having been printed, tested, and corrected if necessary.

Referring to FIG. 31B, a process flowchart is shown for a PWB process with conductor correction 840 which incorporates the conductor printing and correction process 800 detailed above. In operation 841 the LTM 150 of the apparatus 100 accepts geometry data for a PWB including one or more layers of printed conductive traces and optionally layers of nonconductive material to be printed, as discussed above with reference to operation 721. In the case where a multilayer PWB is to be produced the conductors to be printed are grouped in layers as are the nonconductive areas. In operation 842 the LTM 150 organizes the conductive traces in lists corresponding to layers followed by nonconductive layers as required by either the input file data or the translated data produced by the LTM to facilitate producing the PWB by printing conductive and nonconductive material. The term “list” is used figuratively in sense that conductive traces are designated for printing.

Once the printing data is prepared flow proceeds to the conductor printing and correction process 800 detailed above. As discussed this operation prints and test conductors as they are printed. A conductor is printed, then tested, and corrected if necessary. Each conductor of the list of conductive traces is thus printed and verified by measurement. After completion, flow proceeds to operation 844 wherein it is determined if nonconductive areas are to be printed next and operation 848 is effected to print the nonconductive areas if necessary. Alternatively, flow proceeds to operation 848 wherein it determined if there is another conductor layer or conductors in a further list to be printed. It is possible that a list does not comprise a complete layer, as portions of layers may be printed as a group. If further printing is required flow proceeds back to operation 842 wherein a next list of conductors is prepared for printing. If operation 848 yields a negative result, then all the conductive and nonconductive areas have been printed and the PWB is now ready to accept populating with components.

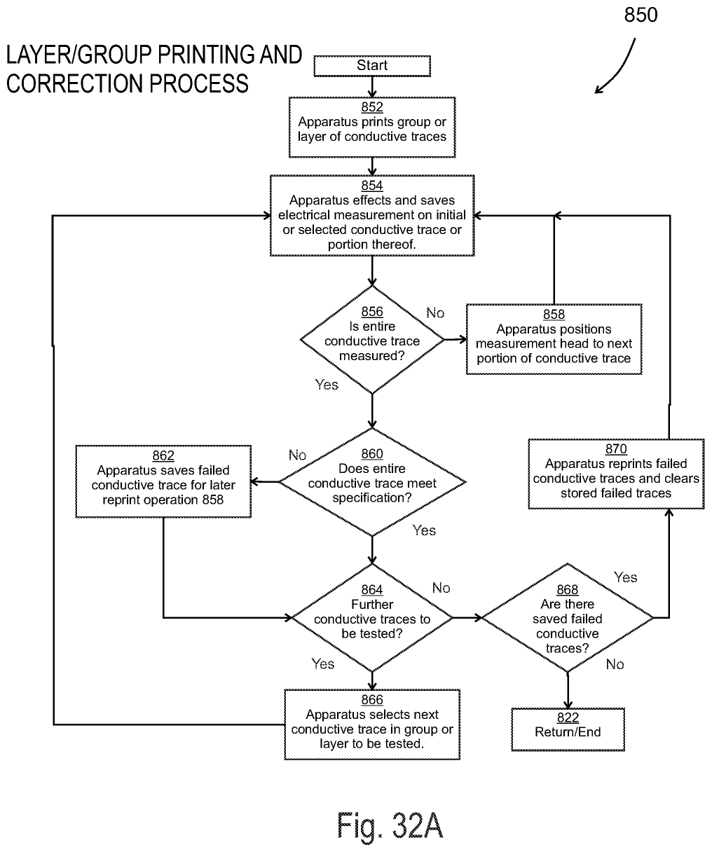

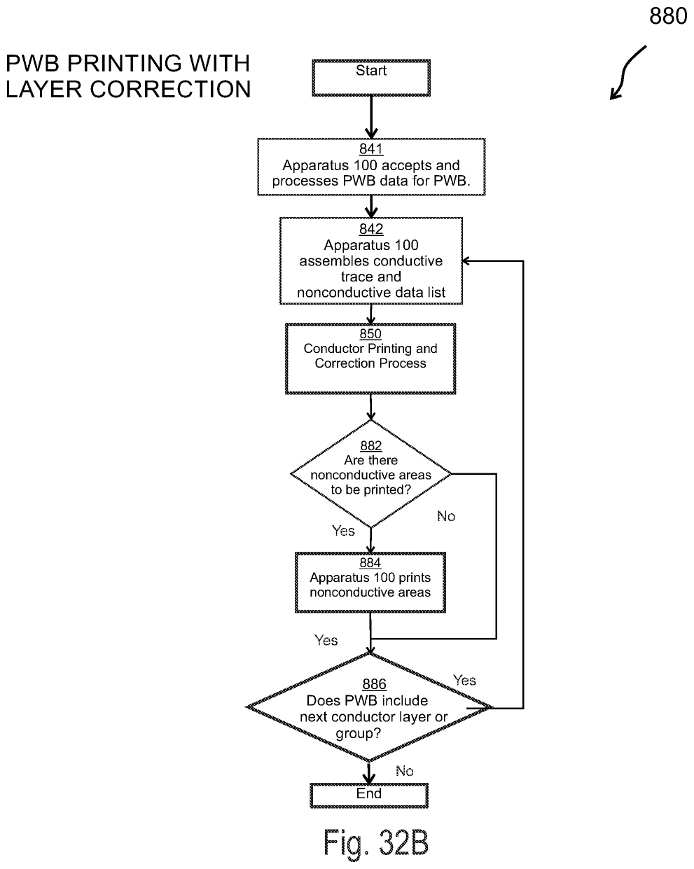

Referring to FIG. 32A, another a sub-process flowchart is shown wherein apparatus 100 effects a conductor layer printing and correction process 850 which prints conductive traces of a layer or group, then tests the printed traces while saving failure data, and then reprints conductive traces that fail to pass a measurement test. In operation 852 the LTM 150 directs apparatus 100 to sequentially print conductive traces from a prepared list for a group or a layer. In operation 854 the apparatus 100 proceeds measure a conductive trace or segment thereof from the list and saves the test result. In operation 856 it is determined if the entire conductive trace has been tested, if not flow proceeds to operation 858 wherein the measurement head is move to place the probes on a next portion, or segment, of the conductive trace, followed by flow proceeding back to operation 854 where a further measurement is effected. Alternatively, flow proceeds to operation 860 wherein the saved measurements are examined and it is determined if the entire trace meets specification. If the result is negative, flow proceeds to operation 862 wherein indication of the failed trace is saved for later reprinting. If the result is positive operation 864 is effected wherein it is determined if there are further traces in the list to be tested, a positive response results in operation 866 wherein a next trace to be tested is selected from the list of the group or layer.

When all printed traces of the layer or group are tested, operation 864 directs flow to operation 868 wherein a determination is made as to whether there are failed conductive traces. As positive result directs flow to operation 870 wherein the apparatus proceeds to reprint the failed conductive traces. Where the conductive traces are tested in segments, reprinting may be limited to reprinting only the failed segments. Once the reprinting is complete flow proceeds back to operation 854 wherein testing is again conducted. If no failures have been detected the sub-process is complete, all conductors of the group or layer have been successfully printed, and flow returns to a process calling the sub-process.

Referring to FIG. 32B, a PWB printing with layer correction process 880 is shown which utilizes the conductor layer printing and correction process 850. In the operation 841, discussed above, the LTM 150 of the apparatus 100 accepts geometry data for a PWB including one or more layers of printed conductive traces and optionally layers of nonconductive material to be printed, and processes the data as required for printing the PWB. In operation 842, discussed above, the LTM organizes the conductive traces in lists corresponding to layers followed by nonconductive layers as required by either the input file data or the translated data produced by the LTM to facilitate producing the PWB by printing conductive and nonconductive material. The flow then proceeds to call the sub-process of FIG. 32A, i.e., the conductor layer printing and correction process 850. This sub-process proceeds to print, test, and correct all conductors of a given layer or group.

After all conductors of a layer or group from the list have been successfully printed, flow proceeds to operation 882 wherein it is determined whether there are nonconductive areas to be printed after the last group or layer of conductive traces has been printed. If there are flow proceeds to operation 884 wherein the apparatus 100 prints the nonconductive areas as required by the processed PWB data. When no nonconductive areas are to be printed, or all nonconductive areas are printed, flow proceeds to operation 886 wherein it is determined whether there are further conductor layers or groups to be printed, and if so flow proceeds back to operation 842 and a next list is prepared to be operated upon by the conductor layer printing and correction process 850.

### Selective Board Stiffness.

Printing conductive and non-conductive inks on a flexible substrate provides a means for positioning the final PCB assembly into a non-planar configuration. Over-flexing the substrate can cause damage to the printed conductive lines, printed non-conductive lines, electrical circuit components and a component attachment point to the printed conductive lines. Traditional methods for providing localized stiffness to a flexible substrate include a separate process of bonding rigid materials, such as glass/epoxy board or polyimide film, to one side on the PWB substrate. For this disclosure, the process for creating localized rigidity involves printing conductive and/or non-conductive materials during the fabrication of the PWB.

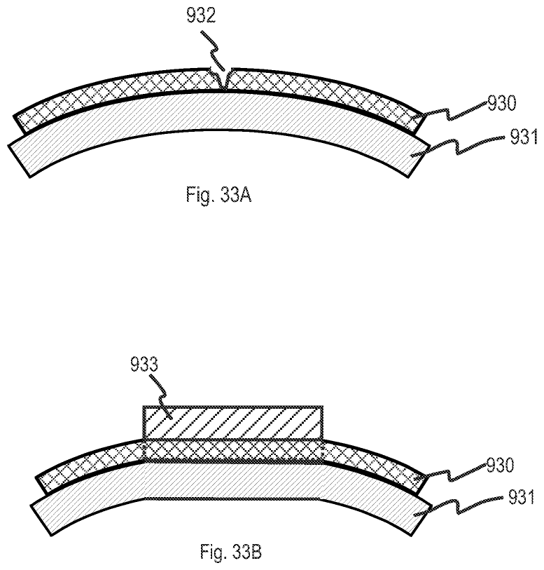

FIG. 33A shows a side view section of a portion of flexible substrate 831 with printed conductive trace 830 arranged with a shape in a curve. If the bend radius of the curve is smaller than the limit required to maintain electrical continuity across the length of printed conductive trace 830, then printed conductive trace 830 may result in fracture 832 and a circuit failure may result.

At locations where substrate flexing would cause damage to the PWB and associated epoxy and/or solder connections, printing a non-conducting material, such as non-conductive ink or thermoplastic, would increase the rigidity of the flexible substrate and prevent potential damage. For example, FIG. 33B shows a side view of flexible substrate 831 with printed conductive trace 830 arranged with a printed support 833 printed adjacent to a portion the printed conductive trace 830. Printed support 833 will increase the rigidity over the portion of the PWB which the support is printed. Printed support 833 can be printed with a thick layer of the same non-conductive ink used for insulating different layers of printed conductors. Printed support 833 can be printed using another type of conductive or non-conductive ink processed with piezoelectric printing or syringe printing. Printed support 833 may also be printed using a traditional thermoplastic such as a those materials used in Fused Filament Fabrication (FFF) 3D printers. While the example in FIG. 33B shows a side view of printed support 833 having a linear arrangement of uniform thickness, the support can be arranged in a variety of shapes and thicknesses to produce a PWB with unique rigidity over the surface. The LTM 150 is configured to accept data identifying areas requiring stiffening and generate stiffening structure data which is used to direct printing of the nonconductive material to form a stiffening support.

### Predicting and Optimizing Print Quality.

A multitude of parameters are involved in printing a PWB. The parameters affect the quality of the PWB printed. In order to maximize the quality of a printed PWB controlling the parameters is desirable. Measuring environmental parameters before and/or during the printing and curing of conductive and non-conductive materials is useful to determining how the environment affects the manufacturing process and how environmental factors interact with the conductive and/or nonconductive materials before, during, and/or after the printing process. Additionally, differing printed materials have different characteristics which dictate printing parameters best suited for the given material. Furthermore, PWB designs have varying specifications and targets which also impact printing parameters best suited to the PWB. An embodiment of the present invention is directed to controlling at least some of the parameters affecting quality and also automating the control of at least some of the parameters.

### Environmental and Electrical Sensors.

The apparatus 100 is optionally equipped to measure printed quality of conductive materials and optimize the print quality of conductive and non-conductive materials based on one or more environmental factors. Referring to FIG. 4, the apparatus 100 characterizes electrical properties of a printed conductive traces using the optional electrical measurement unit 760 as discussed above. In order to assess environmental factors the apparatus 100 includes the temperature sensor 118t and optionally includes environmental sensors, comprising but not limited to, a humidity sensor 118h and a pressure sensor 118p. The temperature sensor 118t measures the temperature of a PWB on which the conductive material is printed. The temperature sensor 118t is attached to the table 104 in close proximity to the PWB. In this location the temperature sensor 118t may be any type of contact sensors. Other locations for the temperature sensor 118t are optionally on the function head 115, the head mount 110, or supported by other means as long as the temperature of the PWB can be directly measured or inferred. The locations of the temperature sensor 118t are not exclusive and a pair of the temperature sensor 118t are optionally used with one at each of the locations. Such temperature sensors may be non-contact sensors, such as but not limited to IR type sensors. The temperature of the PWB is used to optimize the quality of the printed conductive traces including electrical resistance and current carrying capability. The temperature of the PWB is optionally useful optimizing qualities of printed non-conductive geometries including, but limited to, insulation characteristics and surface flatness.

The humidity sensor 118h is optionally attached to any of the positioner 90, the electrical measurement unit 760, or any convenient location on, in or near the apparatus 100 in order to measure humidity levels surrounding the PWB. In some applications, the apparatus 100 is placed inside a closed chamber and in this case, the humidity sensor 118h is placed inside the closed chamber in order to measure the humidity levels surrounding the PWB.

### Environmental Print Parameter Database and Printing Parameter Adjustment Module.

Referring to FIG. 7, in an embodiment of the apparatus a environmental printing parameter database (PPD) 935d stores data of correlations between printed quality of conductive and nonconductive material and environmental factors such as one or more of temperature, pressure, or humidity, and optionally other parameters including one or more of, but not limited to, printing material age, printing material installation time, or printing apparatus age. The term “environmental,” as used with relation to adjustments and parameters, is intended to further encompass a configuration of the apparatus 100 effecting printing. Furthermore, the controller 95 is optionally configured to accept the environment database 935d as an add-on feature which is either provided populated with data or configured ready to accept data provided by an operator.

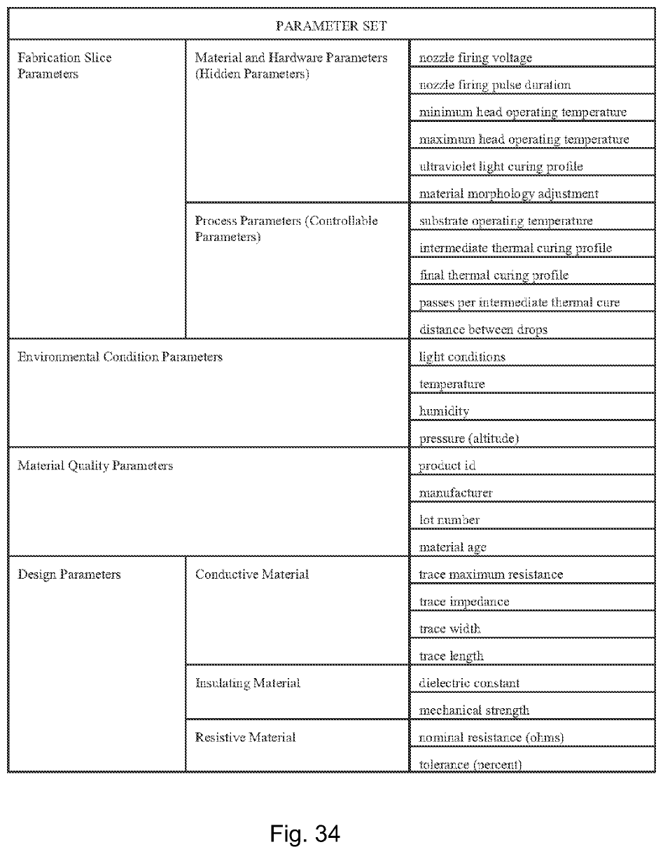

Further optionally provided to the controller 95 is a print parameter adjustment module (PPAM) 935m which is software or firmware implementing an operator printing parameter adjustment interface and adjustments to be made to printing parameters used to print a PWB. For simplicity, the term “PWB” will be used to refer to printing either a circuit on a pre-existing board, or printing both a substrate (board for supporting printed conductive traces) and a circuit on the substrate. The PPAM 935m effects processes taking data from one or more of the temperature sensor 118t, humidity sensor 118h, and/or the pressure sensor 118p, and data representing a configuration and or environment of the apparatus 100, and further referencing “parameter set” data from the PPD 935d and parameters included in PWB file data or operator inputted data to provide prediction of performance of printed features and optionally optimization and implementation printing parameters for printing of a PWB. In the following discussion the term “prediction” means predicting a performance of a “printed feature” (i.e., conductive trace, insulator, substrate or other items previously discussed that are printed using apparatus 100) built using a given parameter set for the printed feature. The term “optimization” means finding parameters based on processing of stored data points and selecting and processing parameters of the store data points to achieve a desired result as is dictated by design parameters. The term “data point” refers to a set of some or all parameters and measured results that are stored in the PPD 935d and associated with a given printed feature (conductive trace, insulative layer, or other printed structure) or material. The term “parameter set” is used herein to refer to the following parameters categories: fabrication slice parameters; environmental conditions parameters; material quality parameters and design target parameters. These parameters are described below and shown in a “Parameter Set” of FIG. 34. The parameter set presented herein is an exemplary embodiment, including further parameters or excluding parameters is deemed to be within the scope of the present invention.

The PPD 935d and the PPAM 935m are shown included in the controller 95, however it is to be understood that one or both of the PPAM 935m and PPD 935d are optionally implemented outside the controller 95 by another computer and optionally another storage device interconnected to the controller 95 directly or by any means of data communication including one or more of, but not limited to, wireless communication, a local network, or a wide area network (WAN) which may or may not include the internet. In such a configuration calculated printing parameters are sent to the controller 95 for use in printing a PWB. Operation of PPAM 935m, in conjunction with the PPD 935d, is discussed below.

### Printing Mechanism Configurations.

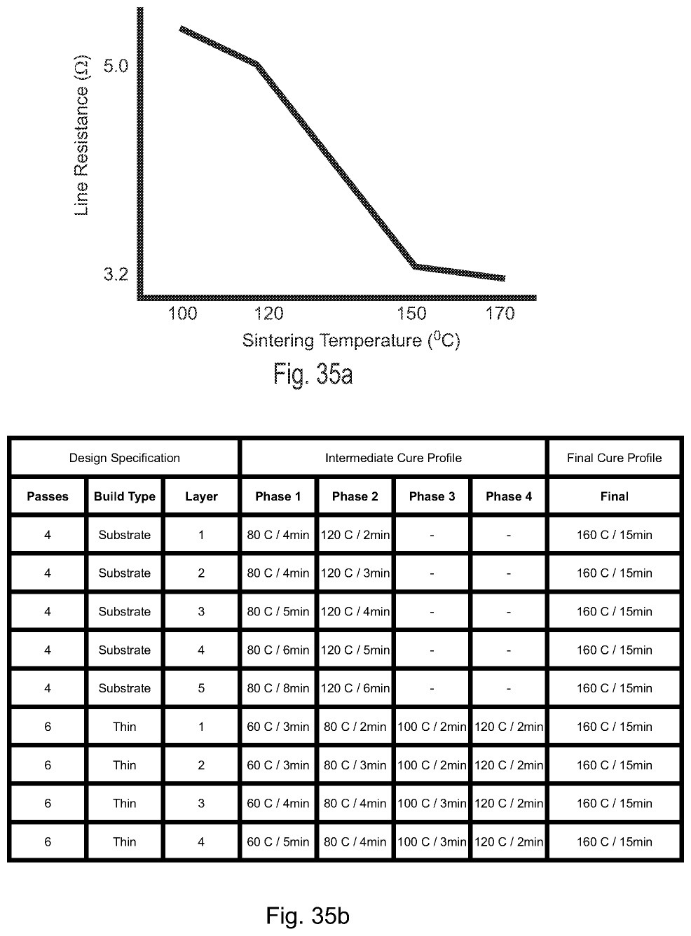

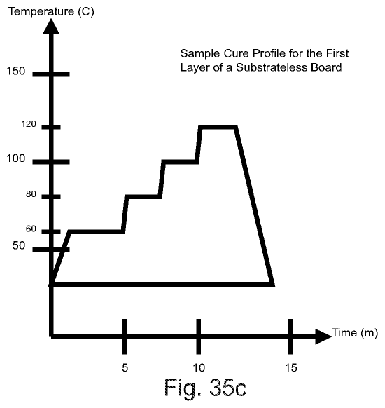

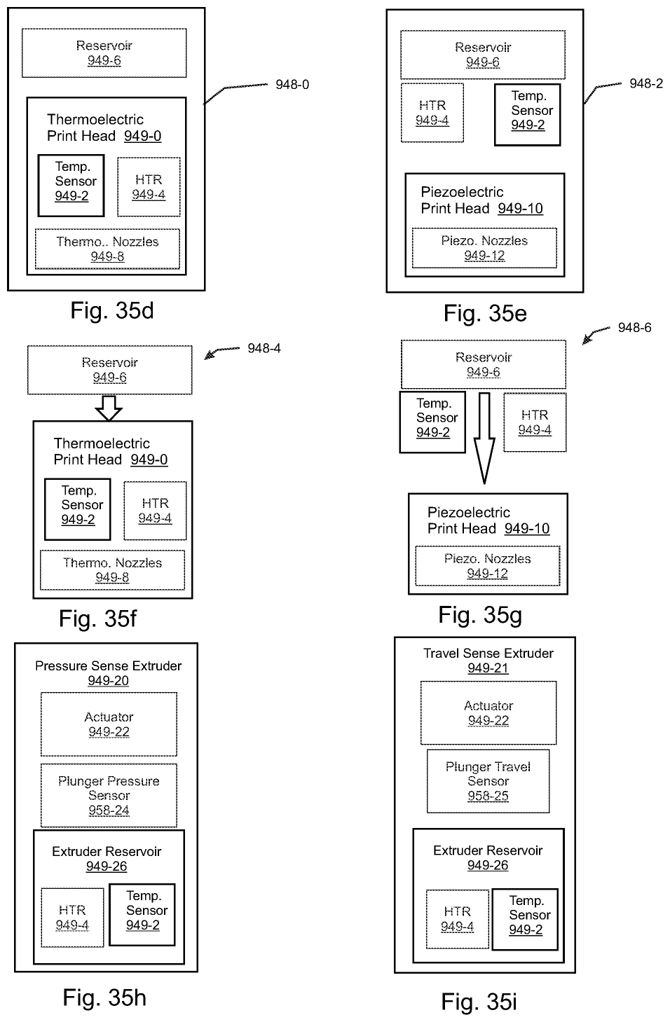

Referring to FIGS. 35d-35i, embodiments of the printing mechanisms employed by the apparatus 100 shown have varying configurations which determine parameters associated with the printing mechanisms. The printing mechanisms for conductive and nonconductive printing include the ink-printing-mechanism 120, the insulator-printing mechanism 120′, and the epoxy-printing mechanism 130 which, in the interest simplicity, are generally shown in prior FIGS. 6a-6e. The apparatus 100 is configured to optionally accept various configurations of the aforesaid printing mechanisms which have varying attributes. Parameters of the various printing mechanisms are stored in the PPD 935d for use by the PPAM 935m in making adjustments to optimize printing.

The ink-printing-mechanism (conductive) 120 and the insulator-printing mechanism 120′ are inkjet print heads which may be supplied with either conductive or nonconductive inks held in an ink reservoir which supplies a print head. Integrated printing mechanism have the print head integrated with the reservoir as a single unit. Referring to FIGS. 35d an integrated thermoelectric print head 948-0 is shown having a thermoelectric print head 949-0, with thermoelectric nozzles 949-8, which is integrated with a reservoir 949-6. Referring to FIG. 35e, an integrated piezoelectric print head 948-2 is shown having a piezoelectric print head 949-10, with piezoelectric nozzles 949-12, which is integrated with a reservoir 949-6. Both have a temperature sensor 949-2 and a heater 949-4.

An ink management system has the reservoir and the print head separate but functionally connected. In other words, the reservoir may be interchanged in the ink management system configuration. Referring to FIGS. 35f and 35g, an ink management system 948-4 for a thermoelectric electric print head 949-0 and an ink management system 948-6 for a piezoelectric print head 949-10 are respectively shown.

The propellent device in the above configurations is optionally a thermoelectric print head (nozzles use heat to eject ink) 949-0 or a piezoelectric print head (nozzles have a piezoelectric element that changes size when voltage is applied to push ink out) 949-10. For reference and not limitation, the inkjet systems typically are used for materials having viscosities under around 20 centipoids (cps), but optional configurations may be used for materials having viscosities in the range of about 100-1000 cps.

The epoxy-printing mechanism 130 (epoxy is a non-limiting example) is not limited to epoxy but may generally be used for printing materials with viscosities not suited for inkjet print heads. Henceforth, to better convey the subject matter the term “extruder” is used in place of epoxy-printing mechanism. It is to be understood that extruder configurations related herein may be used apply, for example and not limitation, any of epoxy, conductive ink or other conductive material, nonconductive ink or other nonconductive material, or solder paste. Referring to FIG. 35h, a pressure sense extruder 949-20 and a plunger pressure sensor 958-24 that senses pressure applied to a plunger to extrude material onto a PWB, Referring to FIG. 35i, a travel sense extruder 949-21 and a plunger travel sensor 958-25 that senses a distance a plunger has traveled to extrude material onto a PWB. Both extruders have an actuator 949-22 and an extruder reservoir (syringe body) equipped with a heater 949-4 and a temperature sensor 949-2. For the sake of simplicity all heaters and temperature sensors in the above printing mechanisms are identified by like references designators, however it will be appreciated by those skilled in the art that embodiments of these device will vary between the differing applications.

The extruders, 949-20 and 949-21, each comprises a plunger (not shown) that applies pressure to the material in the extruder reservoir 949-26 using the actuator 949-22 to extrude material onto the PWB. The extruders, 949-20 and 949-21, are designed to easily swap materials. In the pressure sense extruder 949-20, the plunger pressure sensor 958-24 is incorporated therein to measure the pressure being applied to the material to thereby providing pressure feedback. Monitoring the pressure over time provides means to determined material flow rate and amount. Optionally provided is the travel sense extruder 949-22 configuration without pressure feedback which instead measures advancement or retraction of a the plunger using the plunger travel sensor. The travel distance over time provides a mean to determine flow rate and amount. The extruders, 949-20 and 949-21, are used for materials with viscosities up to about 1000000 cps (1000 Kcps or 1 Mcps).

All print heads and extruders clog and the varying types have attributes suited for different applications. The thermoelectric print heads 949-0 are less expensive and easy to replace, but are not suited for as wide a range of materials as the piezoelectric print heads 949-10. The piezoelectric print heads 949-10 are expensive but are suited for a wider range of materials. Integrated inkjet printheads, 948-0 and 948-2, are easier to use for small prints, less expensive, and less complicated than the ink management system configurations 948-4 and 948-6. The ink management systems, 948-4 and 948-6, are better for huge prints or lots of printing but are more expensive and complicated than the integrated inkjet print heads 948-0 and 948-2. As used herein the term “print head,” unless further specified, for purposes of simplicity in this description is intended to generically refer to any of the printing mechanisms shown FIGS. 35d-35i or any other printing device which may be used in place of the aforesaid printing mechanism.

### Printing Mechanism Parameters.

Depending on whether a thermoelectric or a piezoelectric printing mechanism employed, different parameters apply. Each type has a “firing waveform”—the electrical signal (voltage vs time) that is used to push one or more droplets of ink out of a single nozzle. The parameters are presented below as examples and not limitations. These parameters are measured and/or controlled during the printing operation and are also optionally stored in the PPD 935d in correlation with other printing parameters for use as future references when adjusting the printing parameters.

### Thermoelectric Print Head Parameters.

For the thermoelectric print head 949-0 a “firing waveform,” is typically defined by a firing voltage (˜8-15V) and a firing pulse duration (nano to micro seconds). The material operating temperature while in the print head is in a rage of about ˜30-70 C. This temperature is measured by the temperature sensor 949-2 in the silicon of the print head and can be controlled by either: (a) the heater 949-4 which is embedded in the silicon or (b) firing the thermoelectric nozzles 949-8 or (c) running current through firing elements of the thermoelectric nozzles 949-8 such that they heat up but do not fire. There is a minimum temperature because some materials might not jet below the minimum, and there is a maximum because heat from firing the nozzles leaks into the material and some materials will breakdown above a certain temperature.

### Piezoelectric Print Head Parameters.

For the piezoelectric print head 949-10, a firing waveform is typically more complicated than that of the thermoelectric print head 949-0 and can have several pulses at different durations and voltages and can produce multiple drops as a result. For example and not limitation, a waveform with 2 pulses might produce a single 8 pL drop, but a waveform with 3 pulses might produce an 8 pL drop and a 4 pL drop that combine to produce an effective 12 pL drop. The material operating temperature is typically in a range of about 30 to 90 C and is measure by a temperature sensor 949-2 at the print head 949-10. The temperature is not influenced too much by the piezoelectric print head 949-10 and is more controlled by the heater 949-4 disposed external at the reservoir 949-6 along with the temperature sensor 949-2 sensor which monitors and controls the material temperature at the reservoir 949-6.

### Syringe Extrusion Head Parameters.

For the pressure sense extruder 949-20 a “working pressure” provides pressure feedback which is a pressure measurement parameter used for controlling material distribution. For the travel sense extruder 949-21 a “pre-extrusion amount” and a “retraction amount” is optionally used as a parameter instead of working pressure using the plunger travel sensor 958-25 to senses a travel distance of the plunger and thus displacement. Another parameter for the syringe extrusion head is “Flow Speed,” which is how fast material is flowing out of the head when it is flowing. The flow speed is inferred from either pressure feedback sensing or the plunger travel distance and a time period.

### CAD File Parameters.

A starting point for fabricating a PWB using apparatus 100 is a PWB CAD file. A designer uses a CAD tool to design a PCB (printed circuit board) which produces the PWB CAD. As discussed previously, various CAD tools exist. For the sake of simplicity, a GERBER format file is referred to in this specification but this is not a limitation as the present invention may be adapted to other formats using methods known to those skilled in the art. The printed circuit board is composed of one or more “layers” of conductive traces. CAD tools currently only deal with the conductive layers and use drill files to specify interconnects between layers. These will be referred to herein as “CAD Layers” and “Drill Files.” As explained previously, the layout translation module 152 imports the “CAD Layers” and “Drill Files” to create a series of “Fabrication Layers.”

In order to best convey the process involved, a hypothetical PWB example is next described. Each of the fabrication layers contains all the information about conductive, insulating and/or other material needed to build that layer. For a typical “4-layer board” (what a traditional PCB manufacturer would call a 4-layer board) there are the following files:
4 conductive layers (bottom, inner-1, inner-2, and top);
1 to 4 drill files (top-bottom, top-2, 2-1, 1-bottom);
potentially 2 solder masker layers (top, bottom);
potentially 2 silkscreen layers (top, bottom).

### Translated Fabrication Layers.

The layout translation module 152 imports all of those files and converts them into 4 or more “fabrication layers”, shown below chronologically in build order but physically upside down:
bottom silkscreen
bottom solder mask
bottom copper
via-1
inner-1
via-2
inner-2
via-3
top copper
top solder mask
top silkscreen

### Fabrication Slices.

Each “fabrication layer” is divided into one or more “fabrication slices.” A “fabrication slice” is the design information needed to build something with a specific material, e.g., inter alia, conductive ink, nonconductive ink, or epoxy. Continuing with the previous example of the “4 layer board,” the following fabrication slices are produced:
bottom silkscreen white mark
bottom solder mask insulation
bottom solder mask conductive
bottom copper insulation
bottom copper conductive
via-1 insulation
via-1 conductive
inner-1 insulation
inner-1 conductive
via-2 insulation
via-2 conductive
inner-2 insulation
inner-2 conductive
via-3 insulation
via-3 conductive
top copper insulation
top copper conductive
top solder mask insulation
top solder mask conductive
top silkscreen white mark

### Parameter Types.

The PPD 935d stores numerous parameters and the PPAM 935m performs processes utilizing the stored parameters and parameters measured in process. These parameters are collectively referred to as “the parameter set.” Referring to FIG. 34, a table provides an overview of the parameter set which includes four (4) categories of parameters given the following titles:

1. Fabrication Slice Parameters;

2. Environmental Condition Parameters;

3. Material Quality Parameters; and

4. Design Target Parameters.

In an embodiment the apparatus 100 including the PPAM 935m and PPD 935d, the PPAM 935m optionally adjusts one or more fabrication slice parameters, optionally measures one or more of the environmental condition parameters, optionally reads or receives one or more material quality parameters, and performs adjustments to meet the design target parameters.

### (1) Fabrication Slice Parameters.

Each fabrication slice has a fabrication slice parameter set comprised of 2 categories of parameters: (1) material and hardware parameters; and 2) process parameters. For a given slice, the fabrication slice parameter set is comprised of the following:
Material and Hardware Parameters (Hidden Parameters):
   nozzle firing voltage (˜8 to ˜15V)
   nozzle firing pulse duration (˜nano to micro seconds)
   minimum head operating temperature (˜30 C)
   maximum head operating temperature (˜70 C)
   ultraviolet light curing profile
   material morphology adjustment (to take into account material expansion/contraction)
Process Parameters (Controllable Parameters):
   substrate operating temperature (˜30-50 C)
   intermediate thermal curing profile
   final thermal curing profile
   passes per intermediate thermal cure
   number of passes (˜4-100 passes)
   distance between drops (˜10-100 microns)
      In an embodiment of the invention the process parameters are “controllable parameters” which the operator may adjust manually but this is not a requirement as the degree of automation may be varied by one skilled in the art. In the embodiment the material and hardware parameters are “hidden parameters” which are hidden from the operator in the interest of simplifying operation. This is similar to the manner in which the Windows Operating System hides various folders from operators unless they are advanced operators and chose to access the hidden folders. Thus, the hidden parameters may optionally made available for operator or PPAM 935m adjustment. Again, the degree of automation may be varied by one skilled in the art yet remain within the scope of the present invention. The above listing of fabrication slice parameters is not exhaustive and varying embodiments of the invention optionally include further parameters or omit some parameters as may be dictated by material and design factors.

### (2) Environmental Parameters:

“Environmental Condition Parameters” are parameters which define the conditions of the surroundings of the apparatus 100 and comprise the following:
light conditions
temperature
humidity
pressure (altitude)

### (3) Material Quality Parameters:

The material quality parameters characterize the individual materials printed by the apparatus 100 to fabricate the PWB and comprise:
product id
manufacturer
lot number
age
   Further optionally included is any one or more of a nominal resistivity, nominal dielectric constant, or nominal mechanical strength.

### (4) Design Parameters.

Still further design parameters are used in the fabrication of a PWB and comprise what are optionally termed the “Design Targets” or “Design Specification” or “Design Tolerances” and vary depending on the layer and/or type of material being printed and the printed feature to be printed. Examples of these parameters are shown below in relation to the material involved.
Conductive Material:
   trace maximum resistance
   trace impedance
   trace width
Insulating Material:
   dielectric constant
   mechanical strength
Resistive Material:
   nominal resistance (ohms)
   tolerance (percent)
      Although not specified above, it is to be understood that the design parameters also include data defining physical shape and location of printed features.

While a given collection of parameters comprising the parameter set is detailed above, it is to be understood by those skilled in that the present invention does not require that each of the above parameters be included in processes detailed herein. Likewise, the above collection of parameters is not to be considered closed ended, as the present invention optionally includes further parameters characterizing any one or more of fabrication parameters, environmental conditions, material qualities, or design parameters. As used herein the term “nonconductive material,” unless further contextually qualified, will be used to refer insulating materials whether configured as an ink, epoxy or other hardening substance. For purposes of simplicity herein, the term “printing material,” unless further contextually qualified, will be used to refer to any of conductive or resistive material, insulating or nonconductive material. For purposes of simplicity herein, the term “conductive material,” unless contextually qualified, will be used to refer to any of conductive or resistive material wherein “resistive material” is intended to refer to materials having a resistivity suited for printing resistive features.

### Prediction and Optimization Processes.

### Material Characterization:

Testing procedures are used to determine various material and hardware parameters. In an embodiment of the invention the testing procedures include printing a test swath of printing material and determining its quality. The test swath is created by firing all nozzles of a print head in rapid succession to create a printed “block.” In the following description the term “material agnostic” is used to mean that a process applies to any material and the term “material specific” is used to mean that the process is directed to measurements, observations, and qualities that are specific to the material being tested.

### Nozzle Firing Voltage and Timing.

A test swath is printed to preferably have the following material agnostic characteristics;
has mostly straight lines
has consistent or no spacing between the lines
has minimal droplets outside of the printed section
has no fading at the start/end of a line
has no gap within a single line
   The nozzle firing voltage and timing (material agnostic) parameters are investigated by printing a test swath using varying parameters. The reservoir of a print head is filled with a set amount of ink material (typically ˜30 g or 40 mL, but will vary based on material and cartridge) and test swaths are printed firing all nozzles of a print head for a set distance, which each printing done at a test parameter value. A set of test swaths are printed for each of a set of test firing voltages. Each test swath of the set of test swaths is printed using different test pulse widths (timing). The resultant test swaths are evaluated for the above material agnostic characteristics.

### Minimum and Maximum Operating Temperature.

Minimum and maximum operating temperature parameters (material agnostic) are typically supplied by a material manufacturer. However, these parameters may be determined by testing preferably using best nozzle firing voltage and timing for the material. The temperature on the print head is measured and test swaths are printed using increasing temperature until the material under test begins to be deposited. This is the minimum temperature. Temperature is continued to be increased until material is no longer being deposited and that temperature is the maximum temperature.

### Substrate Operating Temperature.

Substrate operating temperature (material agnostic) is determined by printing swathes at different temperatures and evaluating the swaths. If the material is “beading up” (forming small droplets) then the temperature should increase (or you put down less material).

### Distance Between Drops Profile.

A distance between drops (material agnostic) is evaluated by printing swaths at different temperatures and varying the drop distance at each of the temperatures. The swaths at each temperature are evaluated to see if the material is “beading up” (forming small droplets). If this occurs then the distance should be increased. If there are visible gaps between the material then the distance should decrease.

### UV Curing Profile.

A UV curing profile (material specific) is usually supplied by the material manufacturer. When it is not test swaths are printed using optimal parameters determined as discussed above. For nonconductive ink, i.e., dielectric (insulating) ink, the test swaths are printed using sets of test curing profiles and are examined for a smooth, consistent result. There should not be ridges on top (minor ridges are ok, deep trenches are not), the material should not be wet when touched, and a specific thickness is achieved.

### Final Curing Profile.

The final thermal curing profile (material specific) which may not be manufacturer supplied, is determined by using a set of test final thermal curing profiles on test swaths which preferably produced using an optimal intermediate curing profile. For conductive ink resistance is measured as heating is increased. The measured resistance should decrease slowly and then reach a point, an optimal final curing profile, where there is no significant gain by further heating. The material should not be wet when touched (if so, it needs more heat or more time). The material should not crack when curing (if so, it needs less heat or more time at a lower temperature).

### Intermediate Curing Profile.

An intermediate curing profile (material specific) is generally not be supplied by the material manufacturer. As layers of ink are stacked, improper cures on a lower layer cause issues inside the board. For conductive inks, multiple layers are printed with multiple types of ink stacked on top of each other. A set of intermediate test profiles are used. Testing begins a high temperature and short time. If the layers crack and/or bubble the temperature is reduced and time increased until layers stop cracking/bubbling and the material reaches appropriate levels of conductivity.

### Number of “Passes” Parameter.

The term “pass” used herein refers to one pass of a print head applying a material. Multiple passes of the print head may be required to achieve acceptable results. An optimal number of passes (material specific) for conductive ink is determined by measuring the resistance of a specific trace, and if too low increase the number of passes until it does not improve significantly.

For determining an optimal number of passes for insulating ink, the configuration of insulating ink printed (i.e., printed by varying test number of passes) is sandwiched between printings of conductive ink. A bottom conductive trace is first printed followed printing test numbers of passes of insulating ink and a final printing of a top conductive trace on top of the printed pass(es) of insulating ink. Resistance between the top and bottom conductive traces is then measure. If the resistance is too low, the number passes is increased to an optimal number whereat a sufficient level of insulation is achieved and increasing the number of passes produces no necessary improvement.

It is to be further understood that the above procedure is optionally used to measure a dielectric constant of the insulative material. The electrical measurement unit 760 is optionally equipped to apply signals testing a resultant capacitance of the test structure printed above and calculate a dielectric constant based on a measured capacitance and physical dimensions of the test structure. Various insulative materials may be chosen based on their dielectric constant.

### Material Morphology Adjustment.

A description of tests used to obtain parameters of materials used in the fabrication of a PWB is provided above. The tests use the best parameters so far determined for a material to run subsequent test. The above described tests can be run iteratively and (technically) in any order. A preferable order is presented above. However, one skilled in the art may vary the order after obtaining an adequate initial set of parameters.

In a further embodiment of the present invention the above test processes are automatically performed by the apparatus using processes optionally incorporated into the PPAM 936 along with operator input regarding evaluation characteristics not automatically obtainable. For example, the operator may need to input data such as material type, lot number, etc. if it is not automatically available. The machine stores the parameters. Automation of the tests permits timely incorporation of parameters for new materials. The environmental conditions used default to “standard office environment conditions.” For the purposes of this disclosure the “Standard Office Environment” is taken to be: Temperature: 18-23 C; Relative Humidity: 30-50%; Pressure: 1013.25 milliBar (plus or minus 10 milliBar); Lighting: 300-500 lux (from an artificial light source). Alternatively, the apparatus stores specific environmental parameters such as temperature, pressure and/or humidity using available sensors. Alternatively, the operator may enter the environmental parameters.

For performance prediction, specific test circuits are fabricated and measured by the machine. The resulting measurements are stored in a flexible but detailed format so they can be applied to other things. For each “conductive fabrication slice” there is a set of conductive traces. Each conductive trace is broken into conductive segments for measurement. Each of those segments is measured and the result is stored. This produces a large collection of data points. Each data point has a measured width, measured resistance, specified x,y coordinate and is stored in three of the four parameter groups (Fabrication Slice Parameters, Environmental Conditions, Material Quality; which is everything except the Design Targets). The the system uses the data to predict performance based on the past data.

### Summary of Material Characterization.

The tests presented above are for storing parameters for characterizing various materials used in the fabrication of a PWB. The stored parameters are used to optimize parameters used in the fabrication of a PWB using specific materials of the materials characterized. In summary, the above characterization tests accomplish the following:
Find the nozzle firing voltage and timing
Find the minimum and maximum operating temperature
Find the best substrate operating temperature
Find the best distance between drops
Find the best UV curing profile
Find the best final thermal curing profile
Find the best intermediate curing profile
Find the best number of passes
Find the material morphology adjustment

### Printing Parameter Adjustment/Optimization.

The PPAM 935m effects an optional operator selected function that optimizes printing parameters when printing a PWB with a known material that has been characterized by the tests described above. For example, the temperature sensor 118t and the humidity sensor 118h provide data to the PPAM 935m which determines that the printing parameter values permit proper curing of the conductive and/or non-conductive printed materials. It is known in the industry that when printing conductive materials, such as silver nano-particle inks, cure temperatures below 120° C. often result in poor electrical conductivity. FIG. 35a shows a typical relationship between a printed conductive line resistance and the sintering temperature. For certain printed conductive materials, it is advantageous to do an initial low temperature cure to slowly evaporate an ink solvent. After the solvent is evaporated, a second higher temperature cure will sinter the remaining material resulting in a higher conductivity. One example for curing conductive ink has the starting low temperature cure at 70° C. followed by a high temperature cure at 150° C.

In multilayer printing applications requiring the printing of conductive and non-conductive materials, cure temperatures over 120° C. can cause warping or other deformation of the PWB. In this case, lowering the temperature during the sintering process for a conductive trace will improve the flatness of the multilayer board with an associated decrease in the electrical conductivity of the conductive traces. Moderating the temperature through the cure process has a huge impact on an overall performance of a multilayer build.

Referring to FIG. 35b, a table representative of a cure profile for a PWB is shown. A PWB as previously discussed is constructed in layers. The table of FIG. 35b illustrates a build of a PWB wherein both the conductive traces (thin) and the substrate are printed by the apparatus 100. The table shows that the substrate is built in 5 layers. Each of the layers requires four passes of the print head depositing nonconductive material of the substrate. For each pass the cure profile has two phases (1 and 2) to effect a proper curing of the nonconductive material. Next, the conductive traces are printed, each requiring six passes and four phases (1, 2, 3, 4) of curing for each pass. After the phases 1, 2 etc of curing a final cure profile is applied for each of the layers. FIG. 35c shows a cure profile for the first layer (Thin) of conductive printing detailed in the table of FIG. 35b.

Optimizing Print Quality with Material and Hardware Aging.

Conductive and non-conductive materials degrade with age. Typically, these materials are given a shelf life specification as a benchmark for the operator to know when the materials need to be replaced. Often the specified shelf life is assuming that the material was properly stored, for example, in a refrigerated environment. If the material is not properly stored, the shelf life will be decreased but absent actual use there is no way of knowing if the material is still useable in printed PWB.

In a further embodiment of the apparatus 100, configurations utilizing the PPAM 935m are optionally provided to ascertain the age of the conductive material and/or the nonconductive material that is being used. In one configuration a manufacture date and optionally other meta-data is stored inside a memory chip on or within a print cartridge. This allows the apparatus to read the date automatically without operator intervention. An interface between the chip and the apparatus may be implemented by any of direct electrical contact, or wirelessly via Bluetooth, optical means such as an IR interface, or an RFID.

In another configuration wherein a cartridge does not have a memory chip, there is provided a QR code, a barcode, text, or another optically scannable message on the cartridge. Referring to FIG. 4, the apparatus 100 is optionally provided with a compatible optical interface device (OID) 118o positioned on the function head 115 or the head mount 110 to optically scan the message of the cartridge. Alternatively, the OID 118o may be positioned elsewhere on the apparatus 100 such that an operator may manually position the cartridge within a readable distance of the OID 1180. The 118 may be a camera or a laser scanner dependent upon the encoding of the information used. Thus, the PPAM 935m operates the OID 118o to read in the manufacture date and optionally other metadata which may include further information such as, for example and not limitation, a lot number. The PPAM 935m optically scans the encoded information when the cartridge is installed, or prior to installation when read in by the operator placing the cartridge within a scanning range of the OID 118o, to determine the age of the material contained in the cartridge.

There are situations where a cartridge is not provided with a means of indicating its manufacture date or age since manufacture. Thus, in still another optional configuration, the apparatus is configured to accept manual entry of one or more indicia including but not limited to a manufacture date, lot number, product code, or other indicia permitting access to data containing an indication of a manufacture date. Where the manufacture date is not directly provided, the PPAM 935m is optionally configured to access a manufacturer's database either through a local network or a wide area network including the internet whereby a manufacture date may be access via use of any of the aforesaid indicia on the cartridge.

Still further, there exists the situation where a cartridge manufacture date is unknown and means are not provided with the cartridge to ascertain the manufacture date. For such a situation in the case of the cartridge containing conductive ink, the PPAM 935m is configured to conduct measurement of a printed test trace to provide information on an expected shelf life under current conditions. In one embodiment, the apparatus 100 provided with the electrical measurement unit 760 and the PPAM 935m, prints a test trace on a test trace coupon and measures the characteristics of a printed test coupon. The PPAM 935m then compares measured print characteristic to characteristics for a like material stored in the PPD 935d and determines an estimate of the manufacture date and/or remaining lifetime of the material. The apparatus 100 then displays the estimated manufacture date and/or an indication of the quality of the material before proceeding with a PWB fabrication.

In another embodiment, the PPAM 935m operates the electrical measurement unit 760 to record over time a measured performance, such as resistance or conductance, of an installed conductive material being used to produce a set of PWBs and creates, in the PPD 118d, an installed material history database (IMHD) containing electrical performance over time data for the installed material. Optionally, the dielectric constant of nonconductive material is also tested as described further herein. Test are optionally periodically made of nonconductive material over the material life span to store data indicating its aging behavior. The PPAM 935m then uses the IMHD to estimate the remaining lifetime of the installed material and displays indicia indicating a remaining lifetime and/or quality of the installed material. In the embodiment of the apparatus 100 containing the PPAM 935m, the PPD 935d, and the electrical measurement unit 760, the IMHD is optionally automatically created without requiring operator intervention when testing PWB builds. If the conductive material in use is degraded to the point where continuing use is unacceptable, the PPAM 935m alerts the operator. This process permits significant time and cost savings in comparison to current systems where a processed PWB would be moved to a separate test system in order to check the quality of the PWB.

### Ink Deposition Amount Adjustment.

In a further embodiment, PPAM 935 uses the IMHD to automatically adjust the printing parameters to take into account the installed material's age and degradation level. If the material falls below a certain performance threshold the operator is presented with a warning where the operator can choose one of several options, including but not limited to, replacing the old installed material with new materials, initiating automatic adjustment of the printing parameters, or manually adjusting the print parameters to compensate for the degraded installed print materials.

For example, when apparatus 100 is configured with function head 115 having printing mechanisms 120 or 130 respectively containing an inkjet cartridge which releases conductive or non-conductive ink, ink droplets released will have an expected volume, or mass, of material that is deposited with each drop. There are several factors in the performance of the ink deposition that degrades over time. As stated above, the conductive or nonconductive ink inside a cartridge has a limited shelf life and the quality of the printed ink will decrease over time. Additionally, as inkjet cartridges and print heads age the amount of ink deposited may decrease over time. For example, a new thermoelectric print cartridge filled with new silver nanoparticle ink can output one gram of ink using approximately 20 million drops of ink. An older cartridge containing older ink will deposit less material per drop and it can take 35 million drops of ink to the achieve the one gram of ink. This degradation can be directly measured as weight, or indirectly, using apparatus 100 with electrical measurement unit 760, and the PPAM 935m taking a measurement of the resistance of a printed trace.

In one embodiment, the PPD 935d includes the IMHD having a database containing resistance measurements as a function of the age of the print cartridge and associated ink and the PPAM 935m optimizes print parameters in accordance with the database. For example, the PPAM 935m predicts the performance of a printed trace based on the calculations from the database. The PPAM 935m automatically adjust a number of print layers required to achieve a certain level of performance in the PWB. Alternatively, the PPAM 935m may also display a warning to the operator that the PWB performance may be degraded and allow the operator to continue the current printing process, adjust the number of printed layers or replace the print head and/or ink.

### Cure Time Adjustment.

When printing non-conductive inks, photo-initiator-based or UV-curable inks can significantly degrade over time. Fresh UV-curable inks can reach a satisfactory level of solidification within seconds if they are fresh and handled properly. Old UV-curable inks can take up to 10 times longer to cure. In one embodiment, the PPD 118d includes the IMHD having a cure time database containing cure time as a function of the age of a print cartridge of nonconductive ink. The PPAM 935m periodically checks the age of the non-conductive ink and optimizes the curing parameters. Apparatus 100 can automatically adjust the curing time of the UV-curable inks required to achieve a certain level of performance in the PWB. Apparatus 100 may also display a warning to the operator that the PWB curing time will increase and allow the operator to either continue the current printing process, adjust the curing time or replace the print head and/or ink.

### Hardware Degradation.

Several hardware components contained in apparatus 100 can also degrade over time and require periodic maintenance or replacement. For example, heater 118 for heat sensitive curing will slowly degrade until they can no longer reach temperatures high enough to cure the printed material. Temperature sensor 118t can used to sense the achievable heater temperature and adjust the power delivered to the heating element. Apparatus 100 can create a database of the measured temperature as a function of age of the heater 118t. The database may also include the required power to drive heater 118t. Apparatus 100 may also use the database to extrapolate the time to when the heater 118t will need to be replaced. Under a maintenance option, apparatus 100 can display the current state of the heater and may also include the expected lifetime of the heater 118t before replacement is needed.

Another component contained in apparatus 100 is the UV heater 118a required to cure the UV-curable inks UV heater 118a is typically a series of UV LEDs that activate the curing process of non-conductive inks UV heater 118a will also degrade over time resulting in a lower amount of UV energy being emitted from the element. Apparatus 100 can compensate for the reduction of emitted energy by increasing the amount of power delivered to the element. Apparatus 100 may use a database of the required power delivered to the UV heater 118a as a function of time to compensate for the age of the heater. Apparatus 100 may use the database to extrapolate the expected lifetime of UV heater 118a. Under a maintenance option, apparatus 100 can display the current state of the UV heater 118a and may also include the expected lifetime of the UV heater 118a before replacement is needed.

Apparatus 100 also contains a positioning system which includes x-axis motor 101a, y-axis motor 102b and z-axis motor 103c. The axis motors, and associated hardware, position the function head 115 and table 105 relative to one another for printing the PWB. The positioning system components degrade over time and quality of the printing calibration will also degrade. For example, a new calibrated positioning system will properly print a 200 um wide conductive trace, However, with age degradation the positioning system will begin to print that same trace to a width of 400 um. Apparatus 100 optionally uses a database of the printed line width degradation as a function of time to compensate for the expected increase in line width. Apparatus 100 optionally automatically adjusts the printed line width based on the database information or apparatus 100 may display that the line width will be outside a previously set threshold.

### Operational Flow.

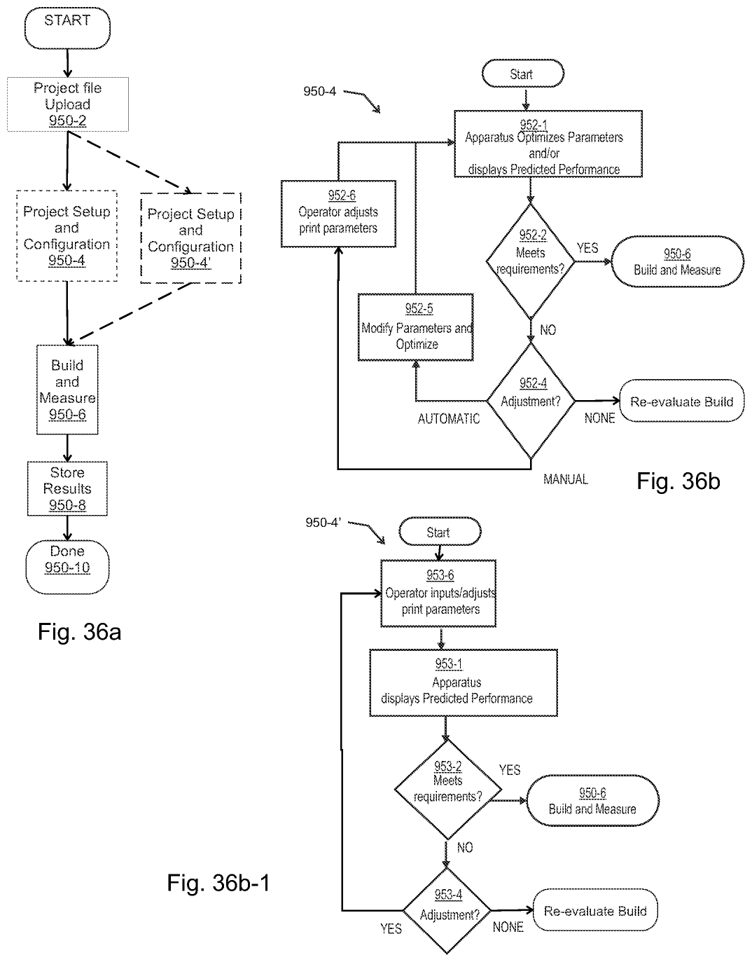

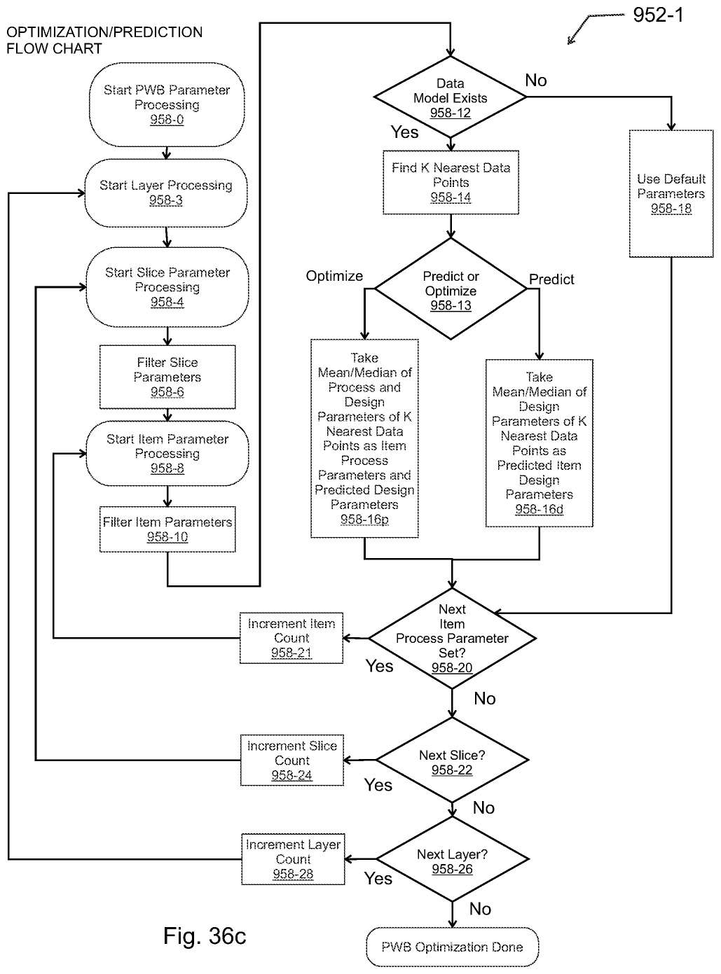

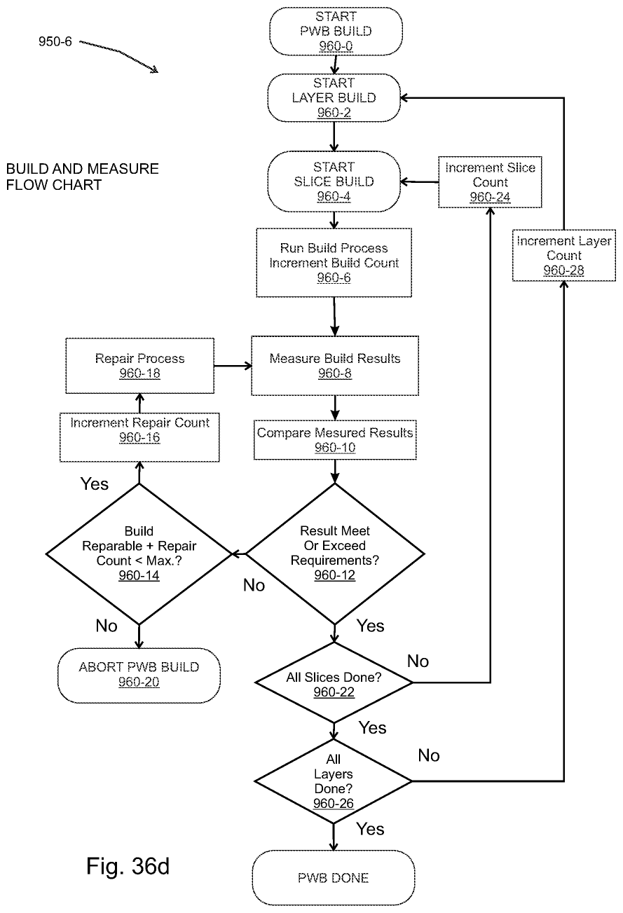

Referring to FIG. 36a, a flowchart illustrates an embodiment of an operational procedure of the apparatus 100 equipped with the PPAM 935m, the PPD 935d, and the electrical measurement unit 760. The PPAM 935m implements the process which begins with operation 950-2 wherein a display prompts the operator to upload a project file to the apparatus 100. The project file is a CAD file detailing the construction of a PWB optionally including details such as individual traces parameters indicating required resistance or conductance, and also parameters indicating possibly matching resistance, conductance or impedance of selected traces.

In operation 950-4 the apparatus 100 displays a performance prediction display. Details of operation 950-4 are shown in further provided in the flowchart of FIG. 36b, with the display of the predicted performance occurring in operation 952-1 and parameter optimization occurring in operation 952-1. Further details of the setup and configuration operation are described below and shown in FIG. 36b.

In another optional embodiment of the invention, operation is limited to prediction of design parameters without optimization of fabrication slice parameters. In that embodiment operation 950-4′ replaces operation 950-4 and is detailed in a flow chart of FIG. 36b-1. In that embodiment predicted design parameters are calculated based on upload and/or inputted parameters including one or more of fabrication slice parameters, environmental condition parameters, or material quality parameters, which are used to extract parameter set data points from the PPD 935d representative of measured results from tests and/or prior PWB builds.

Once the operator has completed the setup and configuration operation, including selecting one of automated optimization or manual adjustment of one or more of fabrication slice parameters, environmental condition parameters, or material quality parameters, the flow proceeds to a build and measure operation 950-6. During the operations the apparatus is optionally controlled by the PPAM 935m which runs via the PCM 128 a build of the PWB in accordance with the parameters either automatically or manually determined in the project setup and configuration operation 950-4 or 950-4′. The build and measure operation 950-6 is further detailed in the flowchart of FIG. 36d and described below.

Upon completion of the build and measure operation 950-8 flow proceeds to a store results operation 950-10. In this operation the PPAM 935m takes the measurement results from the build and measure operation 950-6, and the parameters set in the project setup and configuration operation 950-4 and stores the parameters used and measurements taken in the PPD 935d for future reference as data points in PWB fabrications employing like materials and parameters.

In an embodiment of the present invention, the apparatus 100 is optionally set to a full automation mode wherein the operations described herein are automatically implemented without the need for operator intervention unless predicted design parameters do not satisfy design parameters uploaded or previously input by the operator. In such operation displays of parameter set data, including predicted design parameters and optimized design parameters, are optionally omitted. In other words, the PWB build and measure operation 950-6 is performed without the need for the operator to accept predicted design parameters and/or optimized parameters or initiate the build and measure operation 950-6 during the project setup and configuration operations of flow charts of FIG. 36b, 36b-1, or 36c. It may be that productions of PWB's using the apparatus 100 have shown that the optimizations effected are reliable obviating the need for operator intervention. The reliability of predictions and optimizations is enhanced with an accumulation of data points in the PPD acquired from past builds, and from test measurements described herein regarding material characterization. It is to be understood that the build and measure operation 950-6 is configured to add to data points stored in the PPD 935d with each PWB done by the apparatus. In an alternative embodiment, wherein the electrical measurement unit is not provided, the apparatus 100 is optionally configured to accept an upload or input of data points that are previously collected and perform prediction or optimization base on the uploaded or inputted of data points.

### Project Setup and Configuration Operation.

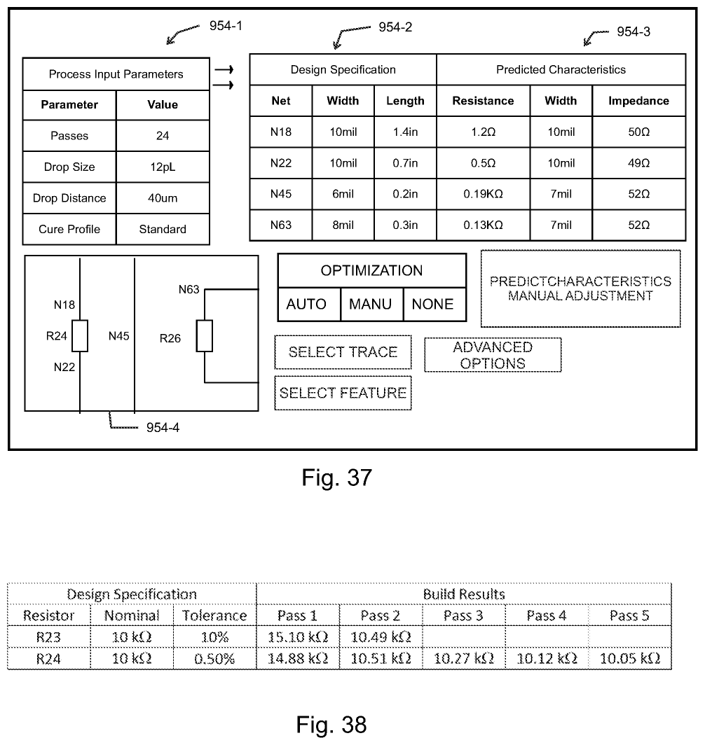

Referring to FIG. 36b, a flow chart of operation 950-4 is of FIG. 36a is shown. In operation 952-1 the PPAM 935m optimizes parameters for a PWB build and provides a display for the operator to evaluate a predicted performance of the PWB build. An example display, for purposes of illustration and not limitation, of a predicted performance is shown in FIG. 37. The display provides a parameter table 954-1 showing data indicating printing parameters based upon data from the PPD 935d and processing by the PPAM 935m which takes into account the previously discussed parameter set data.

In an embodiment of the present invention the PPAM 935m performs optimization of process parameters to provide a set of initial process parameters and an initial prediction of performance results. This process is shown in the flow chart of FIG. 36c. It is optional that the optimization be limited to the process parameters and it is within the scope of the present invention to optimize other parameters including, but not limited to, material and hardware parameters. The initial process parameters are optimized to provide efficient production of the PWB. A portion of requirements of the CAD file are shown in the design specification table 954-2 and a portion of the predicted trace characteristics are shown predicted characteristics table 954-3. These are reviewed by the operator to determine the performance of the materials in satisfying requirements. In the example, the apparatus 100 displays a trace characteristics of several conductive traces shown in a display window 954-4. The example display is simplified for purposes of clarity, however, in practice, the display shows an expandable list of design specifications and predicted characteristics for operator review. Similarly the circuit portion shown may be expanded and/or different portions may be selected based on selected traces.

Options are provided to the operator permitting examination of selected features of the CAD file. For example, the operator is able select other specific traces contained in the CAD file such as, for example and not limitation, one or more of matched traces, high conductance traces, or nonconductive features using the “SELECT TRACE” button. The PPAM 935m calculates the trace or feature characteristics, displays same, and presents the operator with options for adjusting printing parameters. As stated above the display shown in FIG. 37 is a simplified example and that further data, features, or options are optionally presented in more detailed displays in accordance with operator input. Such options are also available to an operator via the “ADVANCED OPTIONS” button.

Referring again to FIG. 36b, after reviewing the predicted performance information the operator determines, in operation 952-2, whether to proceed with a build to be effected in operation 950-6 if requirements are met or within a realm of acceptability. If the predicted performance is unacceptable the operator can proceed to effect adjustments to parameters. In operation 952-4 the operator selects whether to effect an automatic optimization of print parameters by the PPAM 935m, manual adjustment of print parameters, or to halt the build and re-evaluate requirements and/or material selection. In the embodiment of the present invention wherein a fully automated mode of operation is selected, the decision in operation 952-2 is automatically made and flow proceeds to the build and measure operation 950-6 when requirements are met.

When determining the initial performance prediction, the PPAM 935m automatically performs optimization and arrives at an initial set of operation parameters. This process is detailed in FIG. 36c and described below. The PPAM 935m optimizes the process parameters including, at least some of but not limited to, substrate operating temperature, trace thickness (passes per intermediate thermal cure), trace width, PWB substrate operating temperature, intermediate temperature curing profile, distance between drops, and/or final temperature curing profile. Predicted characteristics are based on measurement of environmental conditions such as one or more of temperature, humidity, or pressure, and some or all of other aforementioned factors such as the material printed (product ID, manufacture, lot number, material age), and print head condition. The optimization includes adjustments such as overprinting (i.e. additional printing passes) a conductive trace to meet resistance requirements. The adjustments improve the electrical performance of the printed conductive trace(s). The electrical performance is optimized for lower resistance (higher conductivity) and/or current capacity, and selected traces may be optimized to match one another in resistance. The selected traces may also be resistive traces printed using resistive material so as to achieve a design parameter resistance.

Optimization further optionally includes minimizing production time while meeting the design parameters. Reducing production time is primarily controlled by the fabrication slice parameters, such as curing profiles and the number passes required to meet the design parameters. In minimizing production time data points the K nearest data points are ordered and selected based on minimizing production time.

When further automatic optimization is selected, the flow proceeds to operation 952-5 wherein the operator is given the option to modify at least one of filtering criteria to better correlate to the current build, build material selection (material quality parameters), or design parameters including but not limited to resistance values, and/or tolerances. The operator is also optionally allowed to modify design parameters which may have been overly stringent. The flow return to the operation 952-1 wherein optimization procedure is then run again with the modifications made by the operator held constant during the optimization.

The operator may select manual adjustment which proceeds with operator manually adjusting at least process parameters 952-6. This is done by further displays and the operator manually entering parameters. The flow return to the operation 952-1 wherein optimization procedure is then run again with the modifications made by the operator held constant during the optimization and the optimization being limited to providing predicted results with process parameters held constant. Alternatively, the operator may decide that the predicted results do not sufficiently meet requirements and that the build should be re-evaluated.

In an optional embodiment of the invention, the PPAM 935m is configured to only effect prediction of design parameters based on previously entered fabrication slice parameters, and environmental condition parameters and material quality parameters. In this embodiment the flow chart of FIG. 36b-1 show a flow chart of an alternative prediction operation. At operation 953-6 the operator enters or uploads a parameter set for a build and makes any desired adjustments. In operation 953-1 the PPAM 935m performs the operations shown in the flow chart of FIG. 36c and the decision in operation 958-13 results in operation 958-16d being executed wherein the item design parameters are predicted and process parameters are not modified. In the prediction only embodiment of the invention, operations 958-13 and 958-16p of FIG. 36c may be omitted from the configuration of the PPAM 935m and flow from operation 958-14 proceeds directly to operation 958-16d. In operation 953-1 predicted performance results, i.e. predicted design parameters, are shown in the display of FIG. 36c. In the prediction only embodiment the optimization option in the display is omitted or disabled. In operation 953-2 the operator reviews the predicted design parameters and decides whether to proceed with the build and measure of the PWB. If the build and measure option is not selected flow proceeds to operation 953-4 wherein the operator can decide whether to make manual adjustments returning to operation 953-6 or to end the process to re-evaluate the build. In the fully automated mode of operation

In the embodiment of the apparatus 100 wherein a fully automated mode is implemented, the decision presented in operation 953-2 is automated such that if the predicted design parameters meet requirements, flow automatically proceeds to the build and measure operation 950-6. If the requirements are not met, the operator is alerted, failed requirements are optionally displayed, and the operator can elect to effect adjustment or abort the build.

### Parameter Optimization.

Parameter optimization for conductive traces is directed to minimizing resistance to meet a target parameter. The resistance formula for a traces is expressed as follows:

Resistance=effective_resistivity*length/(width*depth)

Length is controlled by the design parameter and other effects from various parts of the process are negligible. Width is controlled by the design parameter. At small scales (near the resolution limit of the print head) the width can be affected by the process parameters:
number of passes (to some extent)
substrate operating temperature (to some extent)
distance between drops (to some extent)
nozzle firing voltage (to a small extent)
nozzle firing pulse duration (to a small extent)
and material quality to a lesser extent
   Depth is heavily impacted by:
number of passes
material quality
   Effective resistivity is mostly impacted by:
curing profile
environmental conditions
material quality
   The following trends exist:
increasing the effective resistivity or length increases the resistance
increasing the width or depth decreases the resistance
   In most cases, with the exception of a design target specific resistance (for example a 10 Kohm resistance), the optimization goal is maximize conductance (minimize resistance). Length is a design parameter (not controllable, unless a redesign of the PWB is desired, i.e., a new CAD file) so it is not changed by optimization. Width is also a design parameter so the goal is not to affect it too adversely in the optimization process. Overpinting can affect the width of a trace. Therefore, increasing depth (number of passes or overprints) and decreasing effective resistivity (material and curing profile) are the primary targets used for improving print conductance. Thus, in the parameter optimization process:
depth is increased by increasing the number of passes and/or changing the material; and
effective_resistivity is increased by changing the cure profile (typically by using a higher temperature or longer duration but there are exceptions), or changing the material
   Those general principles apply for most conductive materials so the simplest optimization procedures are:
print more passes until the traces become too wide for the design;
cure hotter until the temperature is too high for the other materials; and
cure longer until the duration is too long to make the build reasonably fast.

### Performance Prediction.

An embodiment of performance prediction is preferably done utilizing the statistics of subject matter, but an alternative is to use a single predicted value. Statistical distributions are refined for various scenarios. The primary parameter predicted is trace resistance. Trace resistance prediction uses the same equation used for optimization:

Resistance=effective_resistivity*length/(width*depth)

In practice, it is preferable that every printed segment is stored in the PPD 935d with all of the parameters that were used to build it and the resultant measured resistance. Every stored segment has an effective resistivity. In predicting resistances, a portion or all of the past measured conductive traces are used to predict the distribution of predicted resistance. A median of the distribution is the expected value for the prediction.

### Filtering.

As the apparatus is used for many builds of PWB's, the PPD 935d grows to include a large number of data points, i.e., printed trace parameters and measured resistances. In an embodiment, the PPAM 935m further refines the prediction by filtering out unrelated samples. For example, without filtering all the conductive materials will be included in the prediction which is not ideal since most of the conductive materials will not be the same as the material being used in the build. Thus, filtering is used to remove samples made from materials from a different manufacturer or samples made from a different material.

A process is optionally used wherein filtering is based on material and age which permits evaluation of performance changes for a material over time. The process for example optionally includes, filtering first to obtain all data points for a given material type “X” from manufacturer “Y.” Then filtering is done for varying age ranges of the filtered results to determine performance changes of the material with time, for example effective resistivity or preferred curing profiles. Filtering is also optionally done for the given material “X” at a certain age while varying the filtering for the manufacture to evaluate how performance changes from one manufacturer to another.

An additional level of filtering is optionally done by looking at quantitative features and removing samples having a parameter beyond a certain amount. For example, only look at samples that have the same number of passes (plus or minus some percent). Or samples having a length that is within a given percentage of the design trace length or design resistance.

### Filtering for Material Quality.

When performing an optimization, filtering for material quality is optionally effected. Data points for any material that is from a different manufacturer than being used in the current build are removed. Similarly, data points for any material that is a different product is removed. Typically, data points in the filtered results for materials of a different age or lot number are retained. However, if there is a sharp change in performance of the materials at specific ages then filtering will be done to group data points by age and keep only those groups within a desired range of the age of the material being used in the build. Similarly, filtering is optionally done if a particular lot number shows a very different performance than other lots. In that case, filtering is used to group data points by lot number and keep only those within the same lot number group.

In view of the above, the present invention provides filtering optionally performed at varying levels such that data points for “Product A” should not be used to predict how “Product B” will perform. Additionally, materials from different manufacturers are also distinct and do not predict how the others will perform. Still further, material (product) of a given lot number (or batch of material that this sample is part of) should perform similarly to the same material (product) of different lot numbers, but there may be slightly different results. If results are significantly different (beyond a pre-determined percentage), filtering based on lot number may be optionally implemented. The PPAM 935m is optionally configured to periodically filter based on the lot numbers to determine when such optionally filtering is to be effected.

### Filtering for Environmental Conditions.

The apparatus 100 is typically in a lab environment (i.e. “Standard office conditions”) which has relatively stable lighting, temperature, humidity, and pressure conditions so filtering on environmental conditions is optional. However, there are scenarios in which the apparatus 100 is used in different environments. For those scenarios conditions can vary a lot and filtering based on environmental conditions is invoked. This is optionally done automatically based on results from environmental sensors of the apparatus 100. In those scenarios, each of the environmental conditions are compared against performance (i.e. Temperature vs Effective Resistivity). If there is a significant change (an operator selectable predetermined amount) in performance (for example, a 50% increase in effective resistivity at temperatures below 20 C, but “regular” performance at temperatures above 20 C) then those threshold values are used to filter groups and the current environmental measurements are used to filter groups of data points to use for prediction. For example and not limitation, there would be a “<20 C” filtered group and a “>=20 C” filtered group; if the current temperature is 25 C then the “>=20 C” filtered group is used in the prediction and the other groups are ignored.

### Filtering for Fabrication Slice Parameters.

Most fabrication slice parameters are handled like the environmental conditions; they are compared against performance and any location where there is a significant change in performance is used as a group threshold. Things in the same group as the current setup are used in the prediction.

### Prediction Processing Model:

In an embodiment of the present invention, a prediction model is used wherein it is optionally targeted to have around 100 data points from the stored parameter set. The number of targeted data points may be varied within the scope of the present invention. If there are more than 100 data points, the data is filtered so that it includes more relevant data. Filtering is preferably done in the following order: Material Quality first, Environmental Conditions second, and Fabrication Slice Parameters last. This order may also be varied within the scope of the invention. If the filtering process produces a number of data points that falls too low then the filtering process is set less strict. Once the data points are filtered, the resultant filtered data points are used to compute a performance criteria of a given feature. For example, an average resistance as a function of trace segment width and trace segment length.

The processing to predict characteristics includes about 20 parameters. All of the data points are put in a N dimensional space (20 dimensional space). To predict a performance point the point is put into the N-dimensional space and nearest K data points, hence neighbors, are found. As used herein “data points” refer to data sets in general, and “neighbor” is used to refer to data points having a relative location to a reference point. A median or mean is then found for the nearest K neighbors to compute a predicted value.

Finding neighbors in an N-dimensional space is a process known to those skilled in the art. In the interest of an understanding of the present disclosure, a non-limiting simplified hypothetical explanation is presented. Every point on a two-dimensional map can be represented as a pair of numbers: an x,y coordinate. The x value represents the distance of the point from the origin horizontally. The y value represents the distance of the point from the origin vertically. To compute the distance between point A (at xa, ya) and point B at (xb, yb) we use: distance=sqrt((xa−xb)**2+(ya−yb)**2) [NOTE: ( )*2 means “to square” or multiply the thing by itself, i.e. x**2 x*x; sqrt means to take the square root]. If we move from a 2-dimensional map to a 3-dimensional space with x, y,z coordinates then the distance formula becomes: distance=sqrt((xa−xb)**2+(ya−yb)**2+(za−ab)**2). When dealing with multidimensional space this extends to an arbitrary number of dimensions. So to compute the distance from a point in N-dimensional space to another point in N-dimensional space we first compute the difference between the selected point and the other point in each dimension, then square that number, then add all the squared numbers, then take the square root of the sum.

In the embodiment of the present invention discussed herein there are several values which have specific numeric values but there are also some values that do not. For non-numeric values we must convert them to a number or remove them from the analysis. The filtering operations previously mentioned help with this by providing evaluations which can be given a number. After we have a data set with only numeric values we then “normalize” the numbers so that they are all between 0 and 1. For each dimension: find the minimum and maximum values along that dimension; then divide each number by that range. This helps ensure that everything is considered equally. Once normalized the data points are ready to be searched.

The PPAM 935m searches for the K-nearest neighbors around a current data set of input parameters ((Fabrication Slice Parameters, Environmental Conditions, Material Quality), basically what is near the operating point that the operator has selected. The cleaned and normalized saved data (as described in the previous paragraph) is used and a distance from the current data set operating point to every other point in that set is computed. This will result in a list of {distance, data point} pairs. That list is then sorted by distance so the smallest distance is first. Then the first K elements of that list are taken as the K nearest neighbors.

The above example is simplified and non-limiting as those skilled in the art of statistics/software/machine learning will realize there are more optimized ways to perform the computation. Therefore, it is to be understood that such optimizations are considered to be within the scope of the present invention.

### Localized Optimization.

Predicting the performance of the printed PWB based on environmental factors allows an operator to chose for either open or closed loop fabrication. Apparatus 100 optionally provides the operator with the option to automatically optimize the print parameters across the complete board or select the option to only adjust certain printed traces for higher or lower electrical performance. This option is provided via the “ADVANCED OPTIONS” button shown in FIG. 37. Localized adjustment achieves a balance of performance/cost/speed. For example, two conductive traces may require precisely controlled matched impedances while the rest of the design does not need that level of control. In this case, apparatus 100 will spend more time printing the two matched traces and print the other lines with faster efficiency.

Referring to FIG. 38, if a PWB requires two printed resistors with one having a 10% resistance tolerance and the second having a 0.5% resistance tolerance, apparatus 100 will typically print and measure the 10% resistor in one or two passes while apparatus 100 may require multiple iterations of print-and-measure in order to achieve the required 0.5% tolerance. The table in FIG. 38 is optionally displayed during the build and measure operation 950-6 shown in FIG. 36a to keep the operator apprised of progress completing selected localized optimizations. After printing a first pass of each resistor, apparatus 100 measures the resistance. Typical values of the resistance measurements are listed under the Pass 1 column on in FIG. 38. In this example, both resistors are not within the specified tolerance and apparatus 100 will print a second pass on top of the first. After printing the second pass of each resistor, apparatus 100 measures the resulting resistance. Typical values of the resistance measurements are listed under the Pass 2 column on FIG. 37. In this case, the R23 resistor is within the specified tolerance and apparatus 100 will not continue optimizing this resistor. After Pass 2, resistor R24 is not within the specified tolerance and apparatus 100 will continue to print and measure until the measured resistance is within the 0.50% tolerance. FIG. 38 shows that five layers are required for the R24 resistor to meet the specified tolerance.

PWB Parameter Prediction and/or Optimization.

Referring to FIG. 36c, a flow chart is shown of a embodiment of a prediction and/or optimization process performed by the PPAM 935m and referenced in operation 952-1 of FIG. 36b or operation 953-6 of FIG. 36b-1. In operation 958-0, a parameter set for the PWB build is selected for processing. The parameter set includes all applicable parameters for each slice, and or each item, of the build. The term “item” is used herein to refer any printed feature produced by the apparatus 100 such as, but not limited to: conductive traces, resistive traces, insulation material deposition including insulative areas and 3-dimensional structures previously related in this disclosure as may be required by the build. The parameter set may also include operator modified parameter settings provided in either of operations 952-5 or 952-6. In the case of operation 952-5 the modified parameters are held constant while optimization is performed on other process parameters. In the case of operation 952-6, the modified and process parameters are held constant and the process predicts performance of the item.

The concept of “layer” is a result of the translation of traditional PCB CAD files which are organized in layers. The LTM 152 converts these files to “slices” as related above. Hence, when printing a PWB the apparatus 100 operates on a slice basis and the “layer” terminology is vestigial from the traditional PCB CAD files. However, it is retained here for purposes of reference. Thus, a number of slices per layer may optionally be used in the processing, and the slices are organized according to a PCB CAD layer they were derived from. Optionally, reference to layers may be omitted and slices merely arranged in continuous order from bottom up.

In operation 958-3 layer parameter processing begins and a number of layers present in the parameter set is stored. Operation 958-4 begins slice parameter processing and a number of slices in the instant layer is stored. Operation 958-6 performs filtering on the data points for slice parameters. As noted previously, the slice is a term given to printing a single material to produce items represented in the slice. Hence, all printing done for a slice with be one of conductive material, nonconductive material, or resistive material. Thus, filtering at this stage is based on the selected material. Operation 958-8 begins item processing for producing individual items of the slice, with the number of items of the slice being stored. Breaking down processing to include item level processing is optional. Since a given slice is produced using a single material, processing parameter selection for use across all items of the slice may be sufficient. However, a greater level of prediction and/or optimization may be achieved by processing item by item because significant differences may exist in the design parameters between items in a single slice. For example, high conductance traces may exist for power handling along side traces carrying signal which do not require high conductance. In the interest of more selective processing for more directed results, filtering is optionally conducted on an item by item basis in operation 958-10 using the design parameters of the items.

In operation 958-12 it is determined whether data point models exist for the item. As a result of the filtering in operation 958-10 and an unusual item design parameters no data points may exist. In such case a default set of parameters is applied in operation 958-18. However, once it is verified that sufficient data points exist, the K nearest data points in the previously described multi-dimensional space are found in operation 958-14. If fewer than K data points exist, optionally the operator is prompted to reduce the number K and the actual number of available data points may be shown.

Optionally provided is a selection of a mode of operation. Operation 958-13 examines whether optimization or prediction is the selected mode of operation. If optimization is the selection then flow proceeds to operation 958-16p wherein process parameters are optimized. Alternatively, if prediction is the selected mode, then flow proceeds to operation 958-16d wherein resultant design parameters (one or more of conductance, resistance, dielectric constant, mechanical strength, or nominal resistance) are predicted based on existing fabrication slice parameters, environmental condition parameters and material quality parameters and test results stored in the PPD 935d.

In operation 958-16p either a mean or median is taken of process parameters of the K nearest data points and used as optimized process parameters for the item. Hence the process parameters for the item are optimized because the data points used for the process parameters are also those that are the nearest neighbors of the data point of the desired design parameters. Using the K nearest data points, predicted design parameters are determined by taking the mean or median of the stored design parameters of the K nearest data point which have been found from actual measurements previously discussed. Optionally, optimization may extend further to other parameters of the parameter set that maybe modified such as the aforementioned hidden parameters.

It will be understood that the above optimization procedure is optionally modified to a purely prediction procedure in the case of manually entered parameters in operation 952-6 of FIG. 36b or operation 953-6 FIG. 36b-1. For prediction, the operation 958-16d does not vary or optimize the fabrication slice parameters (hidden and controllable). In other words, a mean or median is not taken of those parameters and the previously entered fabrication slice parameters are used. A mean or median of resultant previously stored measured design parameters of the K nearest neighbors, measured in tests and/or builds done using the materials of the present build, is taken as a predicted value for the respective ones of those parameters. Furthermore, the apparatus 100 and PPAM 935m may optionally be limited to prediction operation without optimization. In such a case the flow chart of FIG. 36b-1 is substituted for the flow chart of FIG. 36b, and operations 958-13 and 958-16p are eliminated from the flow chart of FIG. 36c with flow proceeding directly from operation 958-14 to 958-16d.

Processing continues to operation 958-20 where it is determined if all items of the slice have been optimized and if not the item count is incremented in operation 958-21 and flow proceeds back to operation 958-8. If all items of the slice are optimized, or have predicted design parameters calculated, flow proceeds to operation 958-22 wherein it is determined if all slices of the layer have been operated on and if not the slice count is incremented in operation 958-24 and flow proceeds back to operation 958-4. If all slices of the layer are operated on flow proceeds to operation 958-26 wherein it is determined if all layers of the PWB build have been operated on and if not the layer count is incremented in operation 958-28 and flow proceeds back to operation 958-3. Once all layers are operated on the PWB optimization or design parameter prediction is complete.

### Build and Measure.

Referring to FIG. 36d, a flowchart of an embodiment of the build and measure operation 950-6 of FIG. 36a is shown. Operation 960-0 begins the operation with the parameter sets for the current build being selected. Operation 960-2 selects the parameter sets for a given layer and a number of layers in the build. Operation 960-4 selects the parameter sets for a given slice and a number of slices in the layer. As previously noted, sequencing operations by layer and slices is optional and processing based on a total of slices of the PWB build may be done in the alternative.

In operation 960-6 the PCM 128 prints the items of the given slice in accordance with the parameter sets of the respective items which also includes effecting the intermediate and final curing profiles. As noted previously, optionally a parameter set may apply to an entire slices with all items of the slice being printed using the parameter set of the slice. Following curing, in operation 960-8 the apparatus 100 operates using the electrical measurement unit 760 to measure items printed and store measurement results along with the associated parameter set in the PPD 935d. In operation 960-10 the measurement results are compared with the design parameters and variation from design parameters are examined in operation 960-12. If the measured results do not meet the design parameters the operator is optionally notified and a repair process is initiated, with or without operator intervention, wherein operation proceeds to the decision operation 960-14.

A repair count is kept and incremented each time a repair process for an item is initiated. The apparatus is optionally equipped with optical interface device 118o which scans the PWB build to determine if the build is repairable. Known video processing procedures are used to determine if certain criteria are met, such as, for example and not limitation, warping or other deformation, or printing inconsistent with normal operation. If operation 960-14 determines the criteria are met the build is aborted and flow proceeds to operation 960-20 wherein the operator is notified. In an embodiment the operator is optionally given the opportunity to remedy the situation and initiate the repair process of operations 960-16 and 960-18 or proceed to operation 960-24 whereby another slice build is initiated.

In operation 960-14 it is examined whether the repair count has exceeded a predetermined maximum value and if so flow proceeds again to operation 960-20. If the maximum value is not exceeded flow proceeds to operation 960-16 and the repair count is incremented and flow proceeds to operation 960-18 wherein a repair is initiated. Following completion of the operation 960-18 flow proceeds to operation 960-8 wherein measurements are again taken to verify effectiveness of the repair.

In operation 960-18 parameters of the slice is reduced to include only parameters of failed traces. The repair process 960-18 then, optionally, comprises one of the following alternative embodiments:
1. In a first embodiment the traces that have failed are reprinted and cured in accordance with their original parameter set.
2. In a second embodiment parameter sets of failed traces are adjusted to increase the number of passes by a predetermined amount and then the failed traces are reprinted and cured.
3. In a third embodiment parameter sets of failed traces are adjusted to increase the curing temperatures by a predetermined amount and then the failed traces are reprinted and cured.
4. In a fourth embodiment parameter sets of failed traces are adjusted to increase the curing temperatures and cure times by a predetermined amount and then the failed traces are reprinted and cured.
5. In a fifth embodiment an operation executed is one the aforesaid first through fourth embodiments wherein the embodiment executed is based on the repair count.
   In the situation wherein the apparatus is operating in an optimization mode, optionally the parameter sets of the failed traces are again optimized with any of the aforesaid increased parameters held constant and used in finding the nearest neighbors.

Operation 960-12 verifies that measurement result meets design parameter requirements, and the results are optionally stored as a data point in the PPD 935d. Flow proceeds to operation 960-22 wherein a slice count is examined to determine if all slices have been built. If slices remain to be built flow proceeds to operation 960-24 wherein the slice count is incremented and flow returns to operation 960-4. If all slices are built flow proceeds to operation 960-26 wherein a layer count is examined to determine if all layers have been built. If layers remain to be built flow proceeds to operation 960-28 wherein the layer count is incremented and flow returns to operation 960-2. When it is determined that all layers are built in operation 960-26 the PWB build is done.

### SUMMARY

While particular embodiments of the present disclosure have been shown and described, it will be appreciated by those skilled in the art that, based upon the teachings herein, changes and modifications may be made without departing from this disclosure and its broader aspects and, therefore, the appended claims are to encompass within their scope all such changes and modifications as are within the true spirit and scope of this disclosure. The true spirit and scope is considered to encompass devices and processes, unless specifically limited to distinguish from known subject matter, which provide equivalent functions as required for interaction with other elements of the claims and the scope is not considered limited to devices and functions currently in existence where future developments may supplant usage of currently available devices and processes yet provide the functioning required for interaction with other claim elements. Furthermore, it is to be understood that the disclosure is solely defined by the appended claims. It is understood by those with skill in the art that unless a specific number of an introduced claim element is recited in the claim, such claim element is not limited to a certain number. For example, introduction of a claim element using the indefinite article “a” or “an” does not limit the claim to “one” of the element. Still further, the following appended claims can contain usage of the introductory phrases “at least one” and “one or more” to introduce claim elements. Such phrases are not considered to imply that the introduction of a claim element by the indefinite articles “a” or “an” limits any particular claim containing such introduced claim element to disclosures containing only one such element, even when the same claim includes the introductory phrases “one or more” or “at least one” and indefinite articles such as “a” or “an”; similarly, the use in the claims of definite articles does not alter the above related interpretation indefinite articles such as “a” or “an”.

What is claimed is:

1. A kit for printing a circuit to produce a printed circuit board, the kit comprising:
print heads for printing materials, said print heads comprising:
a conductive material print head containing a conductive material as a conductive material to be printed; and
a nonconductive material print head containing a nonconductive material as a nonconductive material to be printed; and
a printing apparatus comprising:
a table for supporting the substrate;
a function head configured to accept installations of said conductive material print head and said nonconductive material print head such that:
one of said nonconductive material print head or said conductive material print head is carried on said function head at a given time; or
both of said nonconductive material print head and said conductive material print head are simultaneously carried on said function head;
a positioner configured to effect a movement of said function head and said table relative to one another;
a controller configured to accept circuit board parameter data defining a printed circuit board and to operate said function head and said positioner to effect:
printing said nonconductive material when said function head has said nonconductive material print head installed to form printed conductive items;
printing said conductive material when said function head has said conductive material print head installed to form printed nonconductive items, wherein said printed nonconductive items and said printed conductive items are defined by said circuit board parameter data; and
said controller including a parameter database storing data points comprising parameter data and being further configured to:
produce a predicted performance of said printed conductive items for operator evaluation, prior to actual printing, by processing said stored parameter data based on said circuit board parameter data;
accept operator input to provide revised circuit board parameter data and produce another predicted performance of said printed conductive items; and
effect actual printing of said printed conductive items based on said revised circuit board parameter data.

2. The kit of claim 1 wherein:
said parameter data base includes stored material quality parameters and material identifying data for available print materials; and
said controller is configured to accept conductive material parameters of said conductive material to be printed including material identifying data of said conductive material to be printed.

3. The kit of claim 2 wherein:
said circuit board parameter data includes design parameters defining said printed conductive items;
said stored material quality parameters include past measured conductive parameters of past printed conductive items; and
said controller is configured to provide said predicted performance of said printed conductive items based on said past measured conductive parameters.

4. The kit of claim 3 wherein said controller is configured to filter said past measured conductive parameters using said material identifying data of said conductive material to be printed and use resultant filtered past measured conductive parameters to provide said predicted performance of said printed conductive items.

5. The kit of claim 4 wherein:
said stored material quality parameters include material age parameters of available material used to print said past printed conductive items;
said controller is configured to further filter said filtered past measured conductive parameters using said material identifying data included in said conductive material parameters of said conductive material to be printed and use resultant further filtered past measured conductive parameters to provide said predicted performance of said printed conductive items.

6. The kit of claim 1 wherein:
said parameter data of said data points comprises fabrication slice parameters, material quality parameters of conductive materials used, and past measured design parameters of past printed conductive items;
said circuit board parameters comprise design parameters and material quality parameters of said conductive material to be printed; and
said controller is configured to process said process parameter data of said data points based on said design parameters of said circuit board parameters to produce optimized fabrication slice parameters.

7. The kit of claim 6 wherein:
said material quality parameters of said data points include an material age parameter;
said material quality parameters of said conductive material to be printed include a material to be printed age parameter; and
said controller is further configured to process said process parameter data of said data points based on said design parameters of said circuit board parameters and said material to be printed age parameter to produce optimized fabrication slice parameters.

8. The kit of claim 7 further comprising:
an electrical measurement head configured to:
take electrical measurements of printed conductive items; and
be installed in said function head and operate under control of said controller;
said controller being configured to operate said electrical measurement head to take electrical measurements of said printed conductive items and store, as data points, measurement results as said past measured design parameters in said parameter data base in association with fabrication slice parameters used to produce said printed conductive items.
